(19) United States
(12) Patent Application Publication
(10) Pub. No.: US 2012/0007701 A1
(43) Pub. Date: Jan. 12, 2012

(54) COMMUNICATION CONTROL METHOD AND COMMUNICATION SYSTEM

(75) Inventor: Shunichi Kaeriyama, Tokyo (JP)

(73) Assignee: NEC CORPORATION, Tokyo (JP)

(21) Appl. No.: 13/203,739

(22) PCT Filed: Feb. 17, 2010
(86) PCT No.: PCT/JP2010/001006

§ 371 Date: Aug. 29, 2011

(30) Foreign Application Priority Data
Mar. 26, 2009 (JP) 2009-076089

(51) Int. Cl. H03H 2/00

(52) U.S. Cl. 333/24 R

(57) ABSTRACT

A communication control method according to the present invention is a communication control method for a communication system using a common AC coupling element for transmitting and receiving signals between first and second circuits, the method including: setting a first transmission circuit Tx1 to a valid state and a second reception circuit Rx2 to an invalid state; setting a second transmission circuit Tx2 to the invalid state and a first reception circuit Rx1 to the valid state; transmitting signals from the first transmission circuit Tx1 to the first reception circuit Rx1 through the AC coupling element; setting the first transmission circuit Tx2 to the invalid state and the second reception circuit Rx2 to the valid state during an interval time period after transmission of signals by the first transmission circuit Tx1; setting the second transmission circuit Tx2 to the valid state and the first reception circuit Rx1 to the invalid state during the interval time period; and transmitting signals from the second transmission circuit Tx2 to the second reception circuit Rx2 through the AC coupling element during the interval time period. This prevents a crosstalk between transmission and reception signals with a small circuit.

### TECHNICAL FIELD

The present invention relates to a communication control method and a communication control system, and more particularly, to a communication control method and a communication system which use a common AC coupling element for transmitting and receiving signals.

### BACKGROUND ART

When signals are transmitted among a plurality of semiconductor chips having different power supply voltages, direct transmission of signals through lines causes a difference in DC voltage, which may result in damage to the semiconductor chips and failure of signal transmission. Accordingly, when signals are transmitted among a plurality of semiconductor chips having different power supply voltages, the semiconductor chips are connected with an AC coupling element to transmit only AC signals. Examples of the AC coupling element include a capacitor and a transformer. Here, the transformer refers to an AC coupling element including a primary coil and a secondary coil which are magnetically coupled together. When the transformer is used as the AC coupling element, a turn ratio between the primary coil and the secondary coil of the transformer is adjusted. This allows transfer of signals with an appropriate voltage amplitude to the reception-side semiconductor chip, regardless of the voltage amplitude of a transmission signal from the transmission-side semiconductor chip. Thus, the use of the transformer in communication between the semiconductor chips, which operate at different power supply voltages, eliminates the need to adjust the voltage amplitude of the transmission signal or reception signal on the semiconductor chips. Hereinafter, the transformer formed on a semiconductor chip is referred to as an on-chip transformer, as needed. Patent Literatures 1 to 11 disclose examples of such a communication system for communication through a transformer and a capacitor.

In the communication through a transformer, however, magnetic noise incident from the outside and fluctuations in common mode voltage between two circuits occur. The noise and fluctuations in common mode voltage are propagated to another circuit through a parasitic capacitor formed between two coils constituting an on-chip transformer. Thus, the system using a transformer has a problem in that noise and the fluctuations in common mode voltage which appear as noise cause a malfunction. To prevent such a malfunction from occurring, it is desirable to have a function of checking and collating, in a transmission-side circuit, values of digital signals output from a reception-side circuit. In the case where an abnormality is detected in a circuit to be first connected to the output terminal of the reception-side circuit, it is desirable to have a function of notifying the transmission-side circuit or a control circuit, such as a microcontroller which supplies a signal to the transmission-side circuit, of the abnormality.

In this regard, Patent Literatures 2, 4, 10, and 11 disclose means for bidirectional communication through a transformer. Patent Literature 11 includes a first transformer for transmitting a signal from a first chip to a second chip, and a second transformer for transmitting a signal from the second chip to the first chip. Patent Literatures 2, 4, and 10 disclose a technique in which signal transmission from the first chip to the second chip and signal transmission from the second chip to the first chip are performed through a single transformer. In this communication system, the signal transmitted from the first chip and the signal transmitted from the second chip are separated in reception circuits, which are formed on the respective chips, to reproduce a necessary signal, thereby enabling simultaneous bidirectional communication. In addition to the simultaneous bidirectional communication, Patent Literature 2 also proposes a system for switching between a transmission mode and a reception mode in a semi-fixed manner with a signal from an external terminal.

### CITATION LIST

### Patent Literature

[Patent Literature 1] U.S. Pat. No. 4,785,345
[Patent Literature 2] U.S. Pat. No. 5,952,849
[Patent Literature 3] U.S. Pat. No. 6,262,600
[Patent Literature 4] U.S. Pat. No. 6,249,171
[Patent Literature 5] U.S. Pat. No. 6,525,566
[Patent Literature 6] U.S. Pat. No. 6,873,065
[Patent Literature 7] U.S. Pat. No. 6,903,578
[Patent Literature 8] U.S. Pat. No. 6,922,080
[Patent Literature 9] U.S. Pat. No. 7,064,442
[Patent Literature 10] U.S. Pat. No. 7,302,247
[Patent Literature 11] U.S. Pat. No. 7,075,329

### SUMMARY OF INVENTION

### Technical Problem

However, the communication system disclosed in Patent Literature 11 requires two transformers for forming a pair of communication paths, which causes a problem that the circuit area required for communication is approximately doubled. Each communication system disclosed in Patent Literatures 2, 4, and 10 has a problem of complicating the circuits for separating the signal transmitted from the first chip from the signal transmitted from the second chip in the simultaneous bidirectional communication. Each communication system disclosed in Patent Literatures 2, 4, and 10 has a problem in that the transmission signal and the reception signal cannot be fully separated, so that a malfunction is more likely to occur. The communication system disclosed in Patent Literature 2 requires a switching operation between the transmission mode and the reception mode. This necessitates generation of timings for generating a control signal to instruct the switching operation and generation of a control signal for controlling the timings in an external circuit. The communication method disclosed in Patent Literature 2 requires a technique for generating the control signal at appropriate timings. That is, each communication system disclosed in Patent Literatures described above has a problem of an increase in circuit size due to the bidirectional communication with high reliability.

In view of the problems described above, the present invention aims to reduce the circuit size in a communication system using a common AC coupling element for a transmission operation and a reception operation in bidirectional communication.

### Solution to Problem

An aspect of a communication control method according to the present invention is a communication control method for a communication system including: a first circuit including a first transmission circuit and a second reception circuit; and a second circuit including a second transmission circuit and a first reception circuit, the communication system using a common AC coupling element for transmitting and receiving signals between the first and second circuits, the communication control method including: setting the first transmission circuit to a valid state and setting the second reception circuit to an invalid state; setting the second transmission circuit to the invalid state and setting the first reception circuit to the valid state; transmitting a signal from the first transmission circuit to the first reception circuit through the AC coupling element; setting the first transmission circuit to the invalid state and setting the second reception circuit to the valid state during an interval time period after the transmission of the signal by the first transmission circuit; setting the second transmission circuit to the valid state and setting the first reception circuit to the invalid state during the interval time period; and transmitting a signal from the second transmission circuit to the second reception circuit through the AC coupling element during the interval time period.

An aspect of a communication system according to the present invention is a communication system using a common AC coupling element for transmitting and receiving signals, the communication system including a first circuit including: a first transmission circuit that outputs a pulse signal corresponding to transmission data to the AC coupling element; a second reception circuit that reproduces response data in response to the pulse signal obtained from the AC coupling element; and a first timing control circuit that switches a valid state and an invalid state of each of the first transmission circuit and the second reception circuit; and a second circuit including: a first reception circuit that reproduces reception data in response to the pulse signal obtained from the AC coupling element; a second transmission circuit that outputs a pulse signal corresponding to the response data to the AC coupling element; and a second timing control circuit that switches the valid state and the invalid state of each of the first reception circuit and the second transmission circuit. The second timing control circuit. sets the second transmission circuit to the valid state during an interval time period in which the first transmission circuit is in the invalid state.

### Advantageous Effects of Invention

According to a communication control method and a communication system of the present invention, it is possible to reduce the circuit size in a communication system using a common AC coupling element for a transmission operation and a reception operation in bidirectional communication.

### BRIEF DESCRIPTION OF DRAWINGS

FIG. 1 is a schematic view showing a mounted state of a communication system according to a first exemplary embodiment;

FIG. 2 is a schematic view showing a mounted state of the communication system according to the first exemplary embodiment;

FIG. 3 is a schematic view showing a mounted state of the communication system according to the first exemplary embodiment;

FIG. 4 is a schematic view showing a mounted state of the communication system according to the first exemplary embodiment;

FIG. 5 is a schematic view showing a mounted state of the communication system according to the first exemplary embodiment;

FIG. 6 is a schematic view showing a mounted state of the communication system according to the first exemplary embodiment;

FIG. 7 is a schematic view showing a mounted state of the communication transmission system according to the first exemplary embodiment;

FIG. 8 is a schematic view showing a mounted state of the communication system according to the first exemplary embodiment;

FIG. 9 is a schematic view showing a sectional view of a semiconductor substrate when the mounting method shown in FIG. 8 is employed;

FIG. 10 is a schematic view showing a sectional view of the semiconductor substrate when the mounting method shown in FIG. 8 is employed;

FIG. 11 is a schematic view showing a mounted state of the communication system according to the first exemplary embodiment;

FIG. 12 is a block diagram showing an application of the communication system according to the first exemplary embodiment;

FIG. 13 is a block diagram showing the communication system according to the first exemplary embodiment;

FIG. 14 is a block diagram showing a first timing control circuit in the communication system according to the first exemplary embodiment;

FIG. 15 is a timing diagram showing operation of the first timing control circuit in the communication system according to the first exemplary embodiment;

FIG. 16 is a block diagram showing a second timing control circuit in the communication system according to the first exemplary embodiment;

FIG. 17 is a timing diagram showing operation of the second timing control circuit in the communication system according to the first exemplary embodiment;

FIG. 18 is a block diagram showing a transmission circuit and a reception circuit in the communication system according to the first exemplary embodiment;

FIG. 19 is a detailed block diagram of the reception circuit in the communication system according to the first exemplary embodiment;

FIG. 20 is a graph showing input/output characteristics of the reception circuit in the communication system according to the first exemplary embodiment;

FIG. 21 is a timing diagram showing operation when the transmission circuit in the communication system according to the first exemplary embodiment is in a valid state;

FIG. 22 is a timing diagram showing operation when the transmission circuit in the communication system according to the first exemplary embodiment is in an invalid state;

FIG. 23 is a timing diagram showing operation of the communication system according to the first exemplary embodiment;

FIG. 24 is a block diagram showing another example of the transmission circuit in the communication system according to the first exemplary embodiment;

FIG. 25 is a timing diagram showing operation when the transmission circuit shown in FIG. 22 is in the valid state;

FIG. 26 is a block diagram showing another example of the communication system according to the first exemplary embodiment;

FIG. 27 is a timing diagram showing operation of an error detection circuit in the communication system shown in FIG. 26;

FIG. 28 is a timing diagram showing operation of the error detection circuit shown in FIG. 27;

FIG. 29 is a block diagram of a communication system according to a second exemplary embodiment;

FIG. 30 is a block diagram of a change detection circuit in the communication system according to the second exemplary embodiment;

FIG. 31 is a block diagram of a second timing control circuit in the communication system according to the second exemplary embodiment;

FIG. 32 is a block diagram of a second transmission circuit in the communication system according to the second exemplary embodiment;

FIG. 33 is a timing diagram showing operation of a second circuit in the communication system according to the second exemplary embodiment;

FIG. 34 is a timing diagram showing operation of the communication system according to the second exemplary embodiment;

FIG. 35 is a block diagram of a communication system according to a third exemplary embodiment;

FIG. 36 is a block diagram of a pulse detection circuit in the communication system according to the third exemplary embodiment;

FIG. 37 is a block diagram showing another example of the pulse detection circuit in the communication system according to the third exemplary embodiment;

FIG. 38 is a timing diagram showing operation of the communication system according to the third exemplary embodiment;

FIG. 39 is a block diagram of a communication system according to a fourth exemplary embodiment;

FIG. 40 is a block diagram of a transmission data detection circuit in the communication system according to the fourth exemplary embodiment;

FIG. 41 is a block diagram of a first timing control circuit in the communication system according to the fourth exemplary embodiment;

FIG. 42 is a block diagram of a first transmission circuit in the communication system according to the fourth exemplary embodiment;

FIG. 43 is a block diagram of a pattern detection circuit in the communication system according to the fourth exemplary embodiment;

FIG. 44 is a block diagram of a second timing control circuit in the communication system according to the fourth exemplary embodiment;

FIG. 45 is a timing diagram showing operation of the communication system according to the fourth exemplary embodiment;

FIG. 46 is a block diagram of a communication system according to a fifth exemplary embodiment;

FIG. 47 is a block diagram of a first transmission circuit in the communication system according to the fifth exemplary embodiment;

FIG. 48 is a block diagram of a pattern detection circuit in the communication system according to the fifth exemplary embodiment;

FIG. 49 is a timing diagram showing operation of the communication system according to the fifth exemplary embodiment;

FIG. 50 is a schematic view showing a mounted state of a communication system according to a sixth exemplary embodiment;

FIG. 51 is a schematic view showing a mounted state of the communication system according to the sixth exemplary embodiment;

FIG. 52 is a block diagram of the communication system according to the sixth exemplary embodiment;

FIG. 53 is a block diagram of a first transmission circuit in the communication system according to the sixth exemplary embodiment;

FIG. 54 is a block diagram of a pulse detection, circuit in the communication system according to the sixth exemplary embodiment;

FIG. 55 is a block diagram of a second transmission circuit in the communication system according to the sixth exemplary embodiment; and

FIG. 56 is a timing diagram showing operation of the communication system according to the sixth exemplary embodiment.

### DESCRIPTION OF EMBODIMENTS

### First Exemplary Embodiment

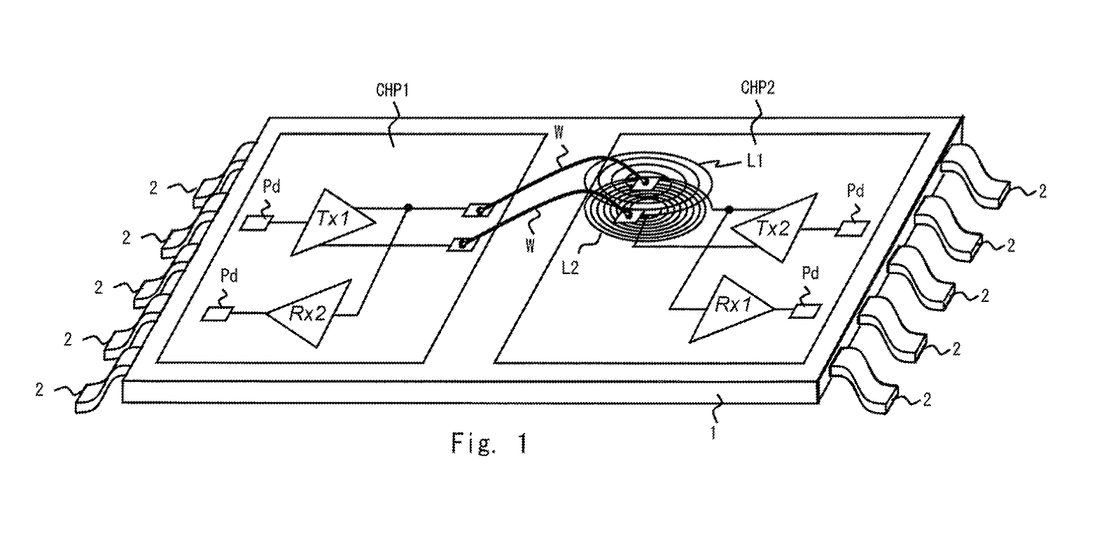

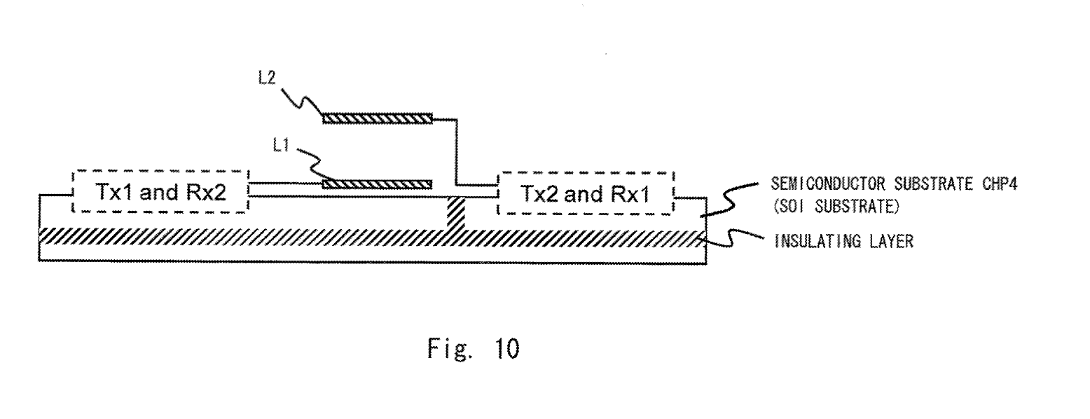

Hereinafter, exemplary embodiments of the present invention will be described with reference to the drawings. First, a method for mounting a communication system according to this exemplary embodiment will be described. In the communication system according to this exemplary embodiment, transformers or capacitors are used as AC coupling elements. In the mounting examples shown in FIGS. 1 to 10, transformers are constituted using two coils formed on one or two semiconductor chips. In other words, the two coils function as AC coupling elements magnetically coupled together. The mounting example of FIG. 11 shows an example in which capacitors are used as AC coupling elements. The transformers are connected to transmission circuits and reception circuits which are formed on semiconductor chips. FIGS. 1 to 11 illustrate the locations where the transformers or capacitors are mounted.

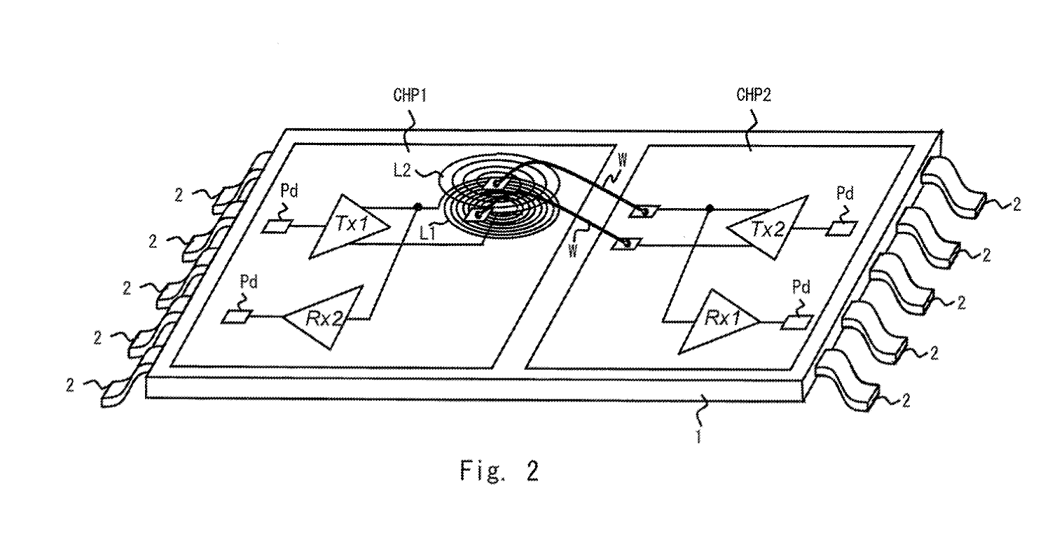

In the mounted state shown in FIG. 1, a first semiconductor chip (hereinafter referred to as “first circuit”) CHP1 and a second semiconductor chip (hereinafter referred to as “second circuit”) CHP2 are mounted in a semiconductor package 1. Each of the first circuit CHP1 and the second circuit CHP2 includes pads Pd. The pads Pd of the first circuit CHP1. and the second circuit CHP2 are connected to lead terminals 2, which are formed on the semiconductor package 1, via bonding wires. This configuration is common to the exemplary embodiments shown in FIGS. 2 to 8 and 11.

A first transmission circuit Tx1 and a second reception circuit Rx2 are formed on the first circuit CHP1. Meanwhile, a primary coil L1, a secondary coil L2, a first reception circuit Rx1, and a second transmission circuit Tx2 are formed on the second circuit CHP2. Pads respectively connected to the first transmission circuit Tx1 and the second reception circuit Rx2 are formed on the first circuit CHP1. A pad connected to the primary coil L1 is formed on the second circuit CHP2. The first transmission circuit Tx1 and the second reception circuit Rx2 are each connected to the primary coil L1, which is formed above the second circuit CHP2, through a pad and a bonding wire W.

In the mounting state shown in FIG. 2, the primary coil L1, the secondary coil L2, the first transmission circuit Tx1, and the second reception circuit Rx2 are formed on the first circuit CHP1. Meanwhile, the first reception circuit Rx1 and the second transmission circuit Tx2 are formed on the second circuit CHP2. A pad connected to the secondary coil L2 is formed on the first circuit CHP1. Pads respectively connected to the first reception circuit Rx1 and the second transmission circuit Tx2 are formed on the second circuit CHP2. The first reception circuit Rx1 and the second transmission circuit Tx2 are each connected to the secondary coil L2, which is formed above the first circuit CHP1, through the pad and the bonding wire W.

In the examples shown in FIGS. 1 and 2, the primary coil L1 and the secondary coil L2 are formed using a first wiring layer and a second wiring layer which are vertically stacked within one semiconductor chip.

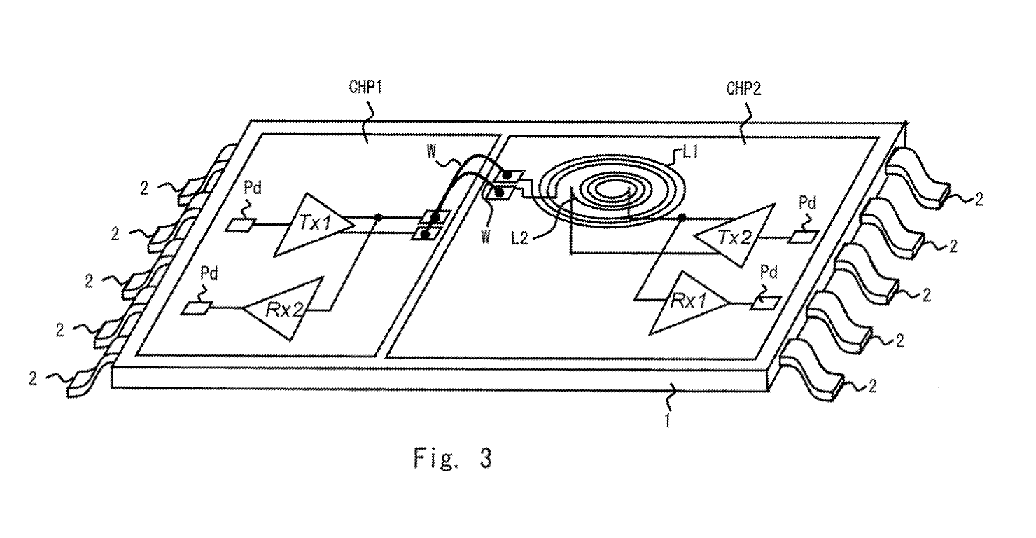

In the mounted state shown in FIG. 3, the first transmission circuit Tx1 and the second reception circuit Rx2 are formed on the first circuit CHP1. Meanwhile, the primary coil L1, the secondary coil L2, the first reception circuit Rx1, and the second transmission circuit Tx2 are formed on the second circuit CHP2. Pads respectively connected to the first transmission circuit Tx1 and the second reception circuit Rx2 are formed on the first circuit CHP1. A pad connected to the primary coil L1 is formed on the second circuit CHP2. The first transmission circuit Tx1 and the second reception circuit Rx2 are each connected to the primary coil L1, which is formed on the second circuit CHP2, through the pad and the bonding wire W.

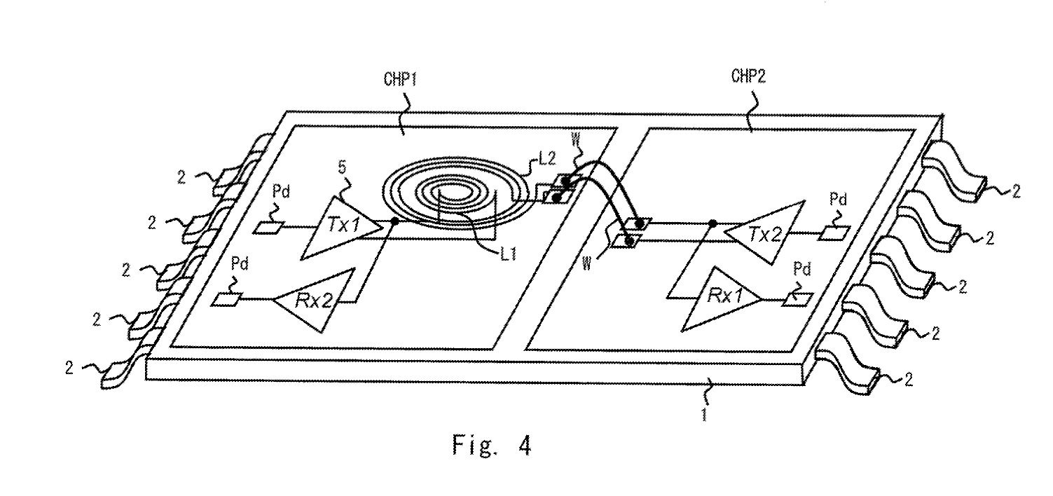

In the mounted state shown in FIG. 4, the primary coil L1, the secondary coil L2, the first transmission circuit Tx1, and the second reception circuit Rx2 are formed on the first circuit CHP1. Meanwhile, the first reception circuit Rx1 and the second transmission circuit Tx2 are formed on the second circuit CHP2. A pad connected to the secondary coil L2 is formed on the first circuit CHP1. Pads respectively connected to the first reception circuit Rx1 and the second transmission circuit Tx2 are formed on the second circuit CHP2. The first reception circuit Rx1 and the second transmission circuit Tx2 are each connected to the secondary coil L2, which is formed on the first circuit CHP1, through the pad and the bonding wire W.

In the examples shown in FIGS. 3 and 4, the primary coil L1 and the secondary coil L2 are formed in the same wiring layer on a single semiconductor chip. The primary coil L1 and the secondary coil L2 are formed as coils which have the same center position.

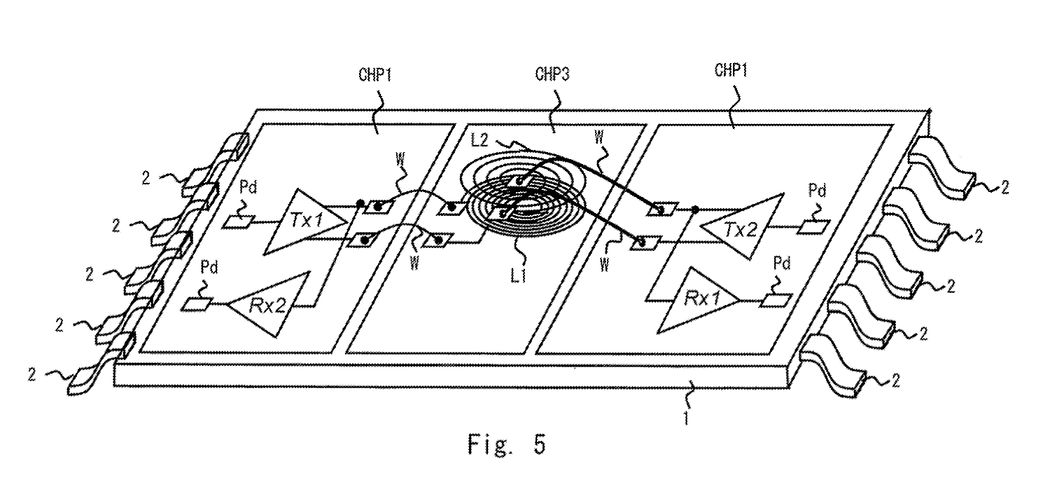

In the mounted state shown in FIG. 5, the first transmission circuit Tx1 and the second reception circuit Rx2 are formed on the first circuit CHP1, and the first reception circuit Rx1 and the second transmission circuit Tx2 are formed on the second circuit CHP2. The primary coil L1 and the secondary coil L2 are formed on a third semiconductor chip (hereinafter referred to as “third circuit”) CHP3. A pad connected to the primary coil L1 is formed on the first circuit CHP1, and a pad connected to the secondary coil L2 is formed on the second circuit CHP2. A pad connected to the primary coil L1 and a pad connected to the secondary coil L2 are formed on the third circuit CHP3. The first transmission circuit Tx1 and the second reception circuit Rx2 are each connected to the primary coil L1, which is formed on the third circuit CHP3, through the pad and the bonding wire W. The first reception circuit Rx1 and the second transmission circuit Tx2 are each connected to the secondary coil L2, which is formed above the third circuit CHP3, through the pad and the bonding wire W. In the example shown in FIG. 5, the primary coil L1 and the secondary coil L2 are formed using the first wiring layer and the second wiring layer which are vertically stacked within one semiconductor chip.

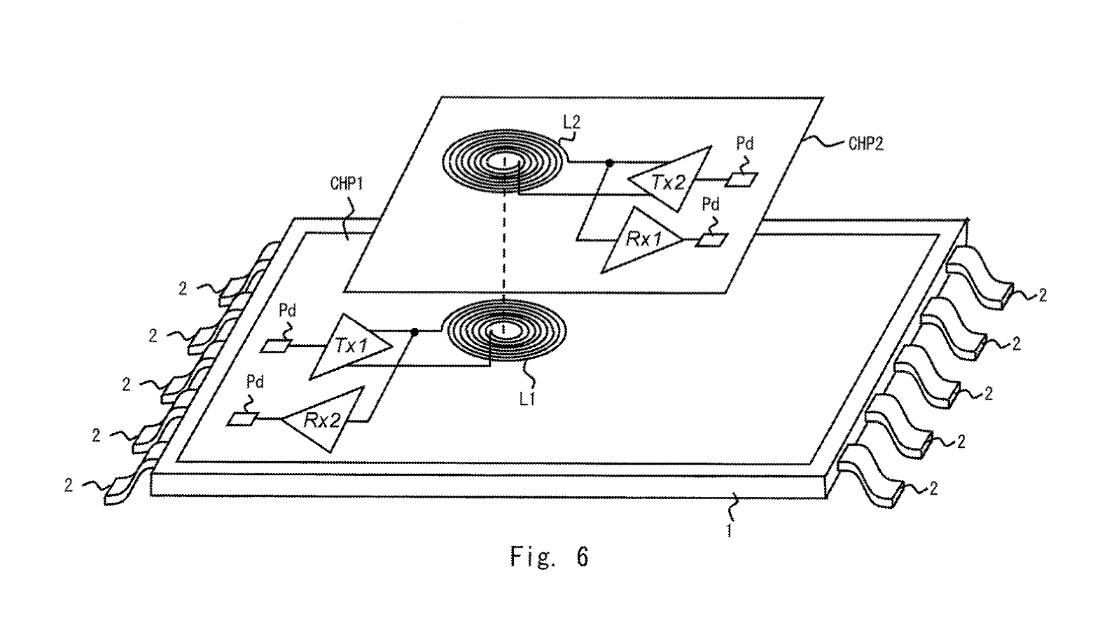

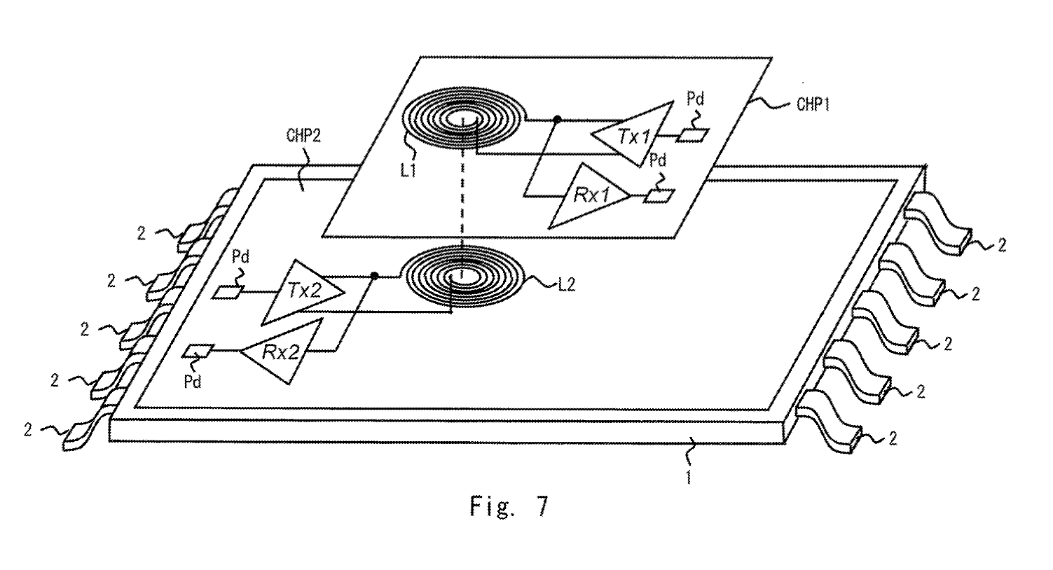

In the examples shown in FIGS. 6 and 7, the first transmission circuit Tx1, the second reception circuit Rx2, and the primary coil L1 are formed on the first circuit CHP1, and the first reception circuit Rx1, the second transmission circuit Tx2, and the secondary coil L2 are formed on the second circuit CHP2. In the examples shown in FIGS. 6 and 7, the first circuit CHP1 and the second circuit CHP2 are stacked. In the examples shown in FIGS. 6 and 7, the first circuit CHP1 and the second circuit CHP2 are arranged so that the center positions of the primary coil L1 and the secondary coil L2 are aligned in the stacked state.

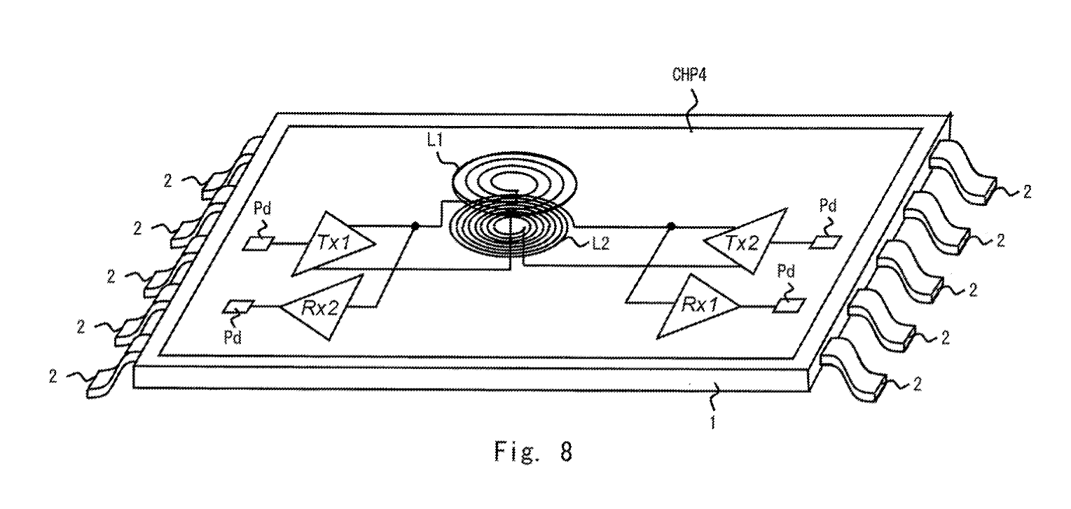

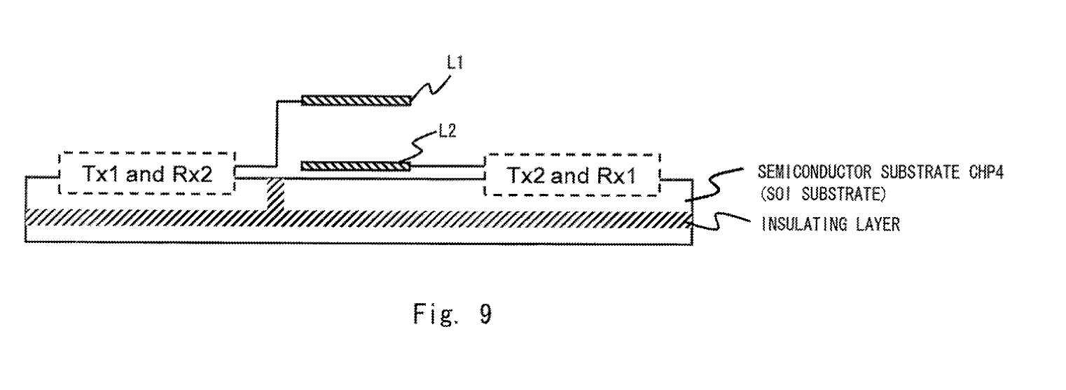

In the example shown in FIG. 8, the first transmission circuit Tx1, the second reception circuit Rx2, the first reception circuit Rx2, the second transmission circuit Tx2, the primary coil L1, and the secondary coil L2 are formed on a semiconductor substrate CHP4. In the example shown in FIG. 8, the primary coil L1 and the secondary coil L2 are formed using the first wiring layer and the second wiring layer which are vertically stacked. A region where the first transmission circuit Tx1 and the second reception circuit Rx2 are disposed and a region where the first reception circuit Rx1 and the second transmission circuit Tx2 are disposed are electrically insulated from each other by an insulating layer formed on the semiconductor substrate CHP4. FIGS. 9 and 10 each show a sectional view of the semiconductor substrate CHP4. In the example shown in FIG. 9, a region where the first transmission circuit Tx1 and the second reception circuit Rx2 are formed (this region has a function equivalent to the first circuit CHP1) and a region where the first reception circuit Rx1 and the second transmission circuit Tx2 are formed (this region has a function equivalent to the second circuit CHP2) are electrically separated by the insulating layer. The primary coil L1 and the secondary coil L2 are formed in the region where the first reception circuit Rx1 and the second transmission circuit Tx2 are formed. Meanwhile, in the example shown in FIG. 10, the region where the first transmission circuit Tx1 and the second reception circuit Rx2 are formed (this region has a function equivalent to the first circuit CHP1) and the region where the first reception circuit Rx1 and the second transmission circuit Tx2 are formed (this region has a function equivalent to the second circuit CHP2) are electrically separated by the insulating layer. The primary coil L1 and the secondary coil L2 are formed in the region where the first transmission circuit Tx1 and the second reception circuit Rx2 are formed.

In the mounting example shown in FIG. 11, the transformers in the communication system shown in FIG. 1 are replaced with capacitors. In other words, the communication system shown in FIG. 11 is an exemplary embodiment using capacitors as AC coupling elements. In the capacitors for signal transmission in this communication system, metal lines (electrodes Ce1 and Ce2 shown in FIG. 11) formed in different wiring layers are used as two electrodes for the capacitors, and an insulator (for example, an interlayer insulating film) filled between the metal lines is used as a dielectric.

As described above, the signal transmission system according to this exemplary embodiment has a configuration in which the transformers for use in communication are formed on a semiconductor chip. At this time, as long as the primary coil L1 and the secondary coil L2 are arranged so that the center positions thereof are aligned, there is no limitation on the region where the transformers are formed. Only the transmission circuit and the reception circuit are described above as the circuits formed on the semiconductor chips, but circuits other than the transmission circuit and the reception circuit may be formed on the semiconductor chips.

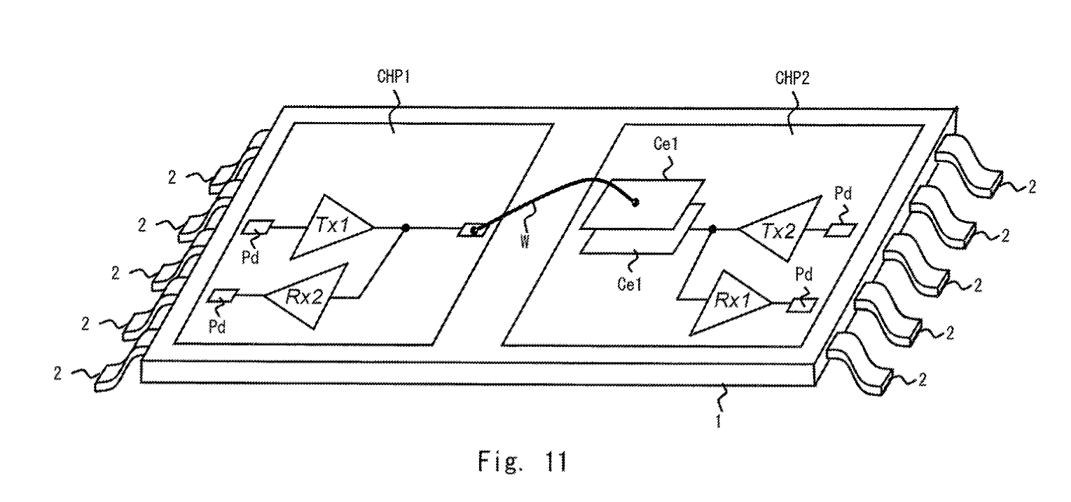

FIG. 12 shows a specific example of the application of the communication system according to the present invention as an example in which other circuits are mounted on the first circuit CHP1 and the second circuit CHP2. FIG. 12 shows an application of the communication system of the present invention to a motor drive control circuit that drives a motor. As shown in FIG. 12, this example of the application includes a semiconductor package 100, a motor 200, a motor drive circuit 201, a current detection circuit 202, and a temperature sensor 203.

A first chip 110 corresponding to the first circuit CHP1 and second chips 121 to 126 each corresponding to the second circuit CHP2 are mounted in the semiconductor package 100. The first transmission circuit Tx1, the second reception circuit Rx2, and a control circuit MCU are mounted on the first chip 110. The control circuit MCU is an arithmetic circuit, such as a microcomputer, which generates a control signal for driving a motor and performs processing for response data obtained through the second chip. A number of first transmission circuits Tx1 and second reception circuits Rx2 are prepared so as to correspond to the number of first reception circuits Rx2 and second transmission circuits Tx2 which are mounted on the second chip.

A first coil, a second coil, the first reception circuit Rx1, the second transmission circuit Tx2, a gate driver Dry, a selector (represented by “SEL” in the figure) are mounted on each of the second chips 121 to 126. Referring to FIG. 12, the description of the elements of the second chips 122 to 126 is simplified. The first coil and the second coil constitute the transformers on the first chip 110 and the second chips. The gate driver Drv drives the gate driver Drv of the motor drive circuit 201 based on reception data obtained through the first reception circuit Rx1. The selector selects one of an error signal ERR, which is output by the current detection circuit 202, a temperature detection signal TDec, which is output by the temperature sensor 203, and reception data RxD, which is output by the gate driver Drv, and outputs the selected signal to the second transmission circuit Tx2. In the application example shown in FIG. 12, a switch is provided at an output of each of the first transmission circuit Tx1 and the second transmission circuit Tx2. This switch indicates that the transmission circuit according to the present invention can switch an output terminal to a high impedance state.

The motor 200 is a control target in this application example. The motor drive circuit 201 includes a plurality of sets of power transistors which are connected in series between a high-voltage power supply HVDD and a ground power supply GND1. In the example shown in FIG. 12, the motor 200 is a three-phase drive motor. Accordingly, three sets of power transistors are prepared. The current detection circuit 202 monitors a voltage across both ends of a current detection resistor Rshunt, which is provided on the side of the ground power supply GND1 of the motor drive circuit. Upon detecting an overcurrent flowing through the motor drive circuit 201, the current detection circuit 202 outputs the error signal ERR. The temperature sensor 203 detects the temperature of the motor 200 or the motor drive circuit 201, and outputs the temperature detection signal TDec to notify the detected temperature.

In the present invention, there is provided an interval time period in which the output impedance of the first transmission circuit Tx1 is set to a high impedance after the first transmission circuit Tx1 transmits transmission data to the second chip side. In the interval time period, the second transmission circuit Tx2 transmits response data to the first chip side. That is, the application of the communication control method of the present invention to the communication between the first chip and the second chip enables the control circuit MCU to generate a control signal depending on a communication status between the first chip and the second chip or on a driving status of the motor 200. The communication control method and the communication system according to the present invention will be described in more detail below.

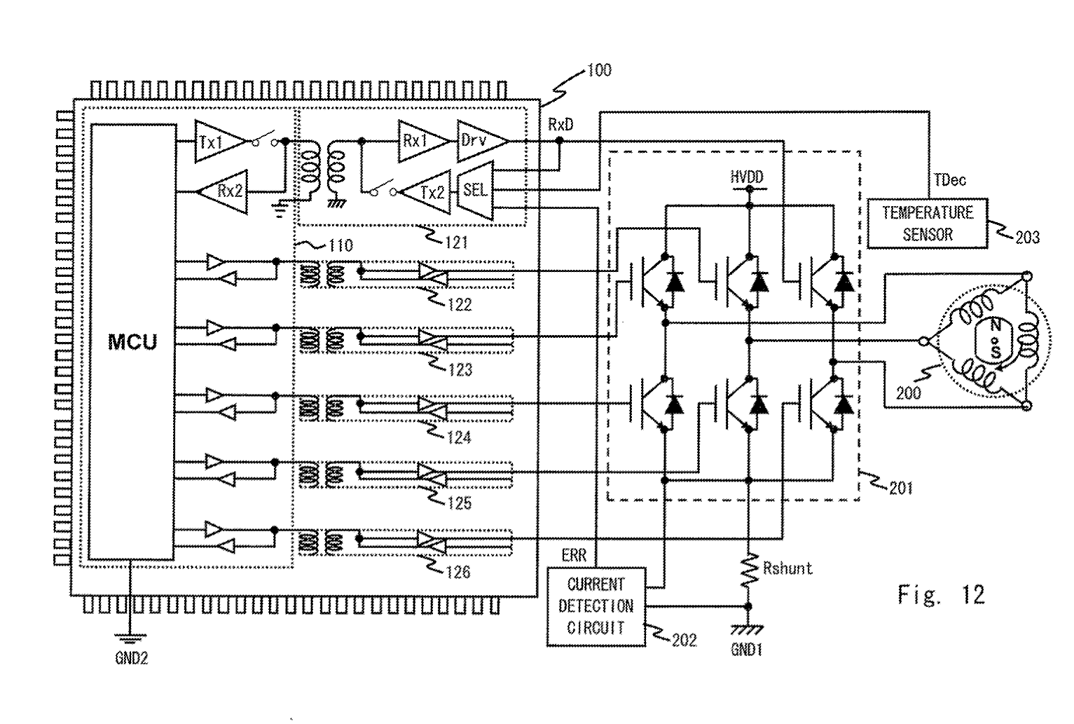

FIG. 13 shows a block diagram of the communication system according to this exemplary embodiment. As shown in FIG. 13, the communication system according to this exemplary embodiment includes the first circuit CHP1 and the second circuit CHP2. The first circuit CHP1 includes the first transmission circuit Tx1, the second reception circuit Rx2, and a first timing control circuit 10. The second circuit CHP2 includes the first coil L1, the second coil L2, the first reception circuit Rx1, and the second transmission circuit Tx2. In this exemplary embodiment, each of the first coil L1 and the second coil L2 constitutes a transformer.

The first transmission circuit Tx1 outputs a pulse signal corresponding to transmission data TxD to the transformer. The first transmission circuit Tx1 receives a first transmission enable signal Tx1_EN. The first transmission circuit Tx1 switches, to the high impedance state, an output terminal connected to a node connecting the transformer and the second reception circuit Rx2, when the first transmission enable signal Tx1_EN is switched to a value indicating an operation invalid state (for example, low level). In this exemplary embodiment, the first transmission circuit Tx1 includes two output terminals and drives the first coil L1 through the two output terminals.

The second reception circuit Rx2 reproduces response data based on a pulse signal obtained from the transformer. This response data is data output by the second transmission circuit Tx2. The second reception circuit Rx2 receives a second reception disenable signal Rx2_DIS. The second reception circuit Rx2 holds the data output at that point upon switching of the second reception disenable signal Rx2_DIS to a value indicating an operation invalid state (for example, high level), and is in a state unresponsive to inputs from the input terminal. That is, the second reception circuit Rx2 in the invalid state maintains the logic level of the output data output during the time period of the valid state immediately before shifting to the invalid state.

The first timing control circuit 10 switches the valid state and the invalid state of each of the first transmission circuit Tx1 and the second reception circuit Rx2. More specifically, the first timing control circuit 10 exclusively switches the valid state of the first transmission circuit Tx1 and the invalid state of the second reception circuit Rx2. This switching timing is set by the first transmission circuit Tx1 according to a transmission time period based on the transmission data. The first timing control circuit 10 provides an interval time period upon expiration of the transmission time period. In the interval time period, the first transmission circuit Tx1 is in the invalid state and the second reception circuit Rx2 is in the valid state. In this exemplary embodiment, the first timing control circuit 10 switches the valid state of the first transmission circuit Tx1 and the valid state of the second reception circuit Rx2 at a predetermined interval.

The valid state of the first transmission circuit Tx1 indicates a state in which the first transmission circuit Tx1 outputs a pulse signal corresponding to the transmission data. The valid state of the second reception circuit Rx2 indicates a state in which the second reception circuit Rx2 can perform operation for reproducing response data according to the pulse signal obtained through the transformer.

The first reception circuit Rx1 reproduces the reception data RxD according to the pulse signal obtained from the transformer. This pulse signal is generated in the second coil L2 when the first transmission circuit Tx1 drives the first coil L1. The reception data RxD output by the first reception circuit Rx1 corresponds to the transmission data TxD. The first reception circuit Rx1 receives a first reception disenable signal Rx1_DIS. The first reception circuit Rx1 holds the data output at that point upon switching of the first reception disenable signal Rx1_DIS to the operation invalid state (for example, high level), and is in a state unresponsive to inputs from the input terminal. That is, the first reception circuit Rx1 in the invalid state maintains the logic level of the output data output during the time period of the valid state immediately before shifting to the invalid state.

The second transmission circuit Tx2 outputs a pulse signal corresponding to the response data to the transformer. In this exemplary embodiment, the reception data RxD output by the first reception circuit Rx1 is used as the response data. The second transmission circuit Tx2 receives a second transmission enable signal Tx2_EN. The second transmission circuit Tx2 switches, to the high impedance state, an output terminal connected to a node connecting the transformer and the first reception circuit Rx1, when the second transmission enable signal Tx2_EN is switched to a value indicating the operation invalid state (for example, low level). In this exemplary embodiment, the second transmission circuit Tx2 includes two output terminals and drives the second coil L2 through the two output terminals.

The second timing control circuit 20 switches the valid state and the invalid state of each of the first reception circuit Rx1 and the second transmission circuit Tx2. More specifically, the second timing control circuit 20 exclusively switches the valid state of the first reception circuit Rx1 and the invalid state of the second transmission circuit Tx2. This switching timing is set by the first transmission circuit Tx1 according to the transmission time period based on the transmission data. The second timing control circuit 20 switches the second transmission circuit Tx1 to the valid state and switches the first reception circuit Rx1 to the invalid state during the interval time period set upon expiration of the transmission time period of the first transmission circuit Tx1. In this exemplary embodiment, the second timing control circuit 20 switches the valid state of the first transmission circuit Tx1 and the valid state of the second reception circuit Rx2 at a predetermined interval. Assume that the timing at which the second timing control circuit 20 switches the first reception disenable signal Rx1_DIS and the second transmission enable signal Tx2_EN is adjusted according to the interval time period which is preliminarily set by the first timing control circuit 10.

The valid state of the second transmission circuit Tx2 indicates a state in which the second transmission circuit Tx2 outputs a pulse signal corresponding to the transmission data. The valid state of the first reception circuit Rx1 indicates a state in which the first reception circuit Rx1 can perform operation for reproducing reception data according to the pulse signal obtained through the transformer.

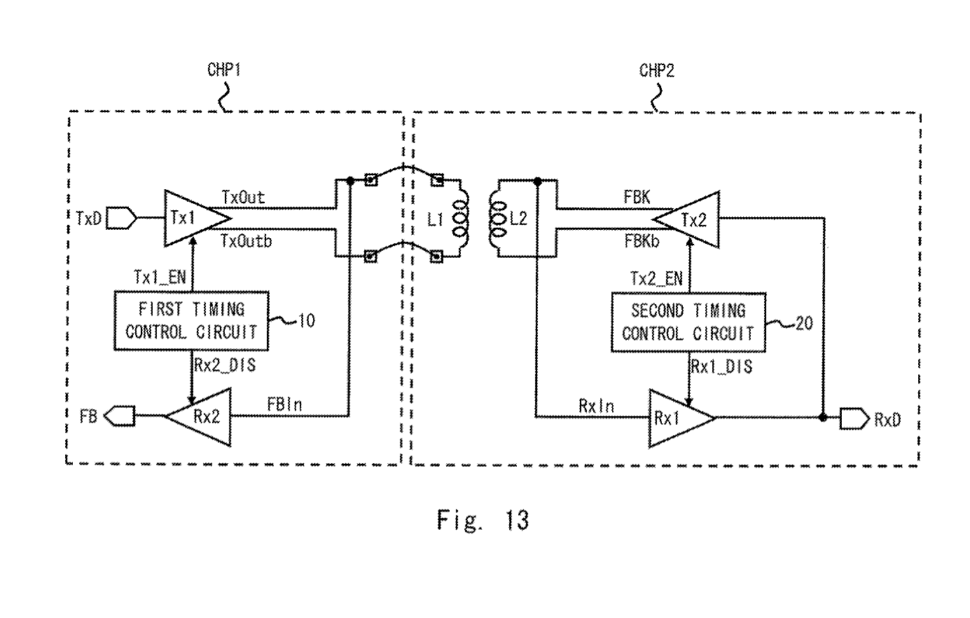

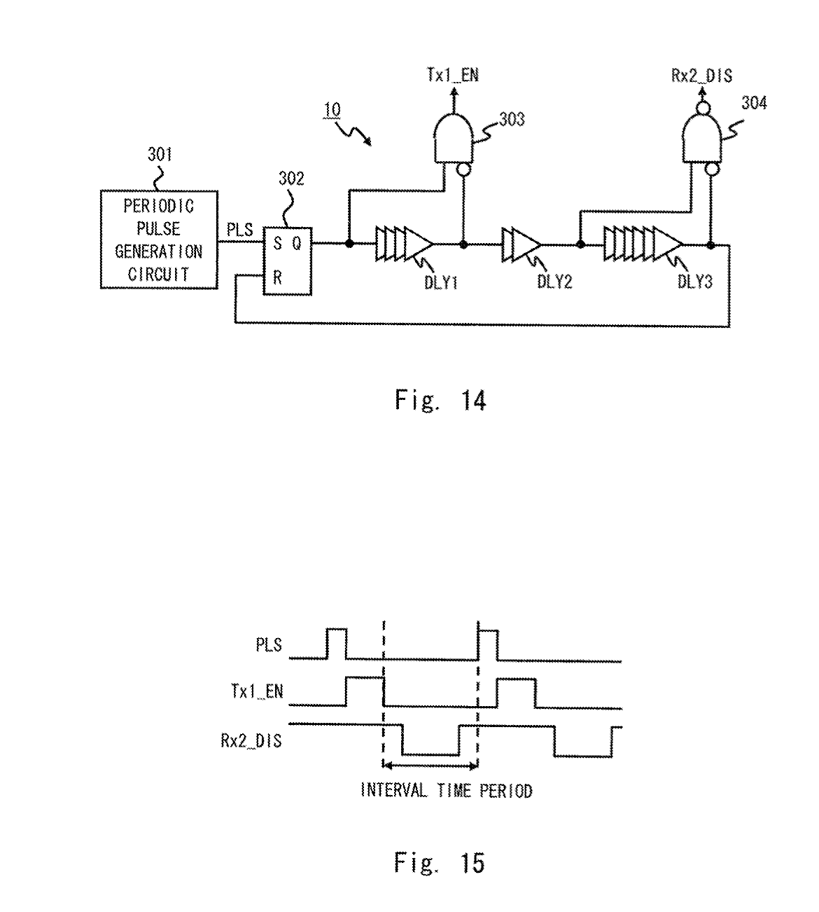

Subsequently, the elements constituting the communication system according to this exemplary embodiment will be described in detail. First, the first timing control circuit 10 of the first circuit CHP1 will be described. FIG. 14 shows a block diagram of the first timing control circuit 10. As shown in FIG. 14, the first timing control circuit 10 includes delay circuits DLY1 to DLY3, a periodic pulse generation circuit 301, a set/reset latch circuit 302, an AND circuit 303 having an inverting input, a NAND circuit 304 having an inverting input.

The delay circuits DLY1 to DLY3 are a set of delay circuits connected in series with an output of the set/reset latch circuit 302. An input of the first stage of the delay circuit DLY1 is connected to the output of the set/reset latch circuit 302. An output of the final stage of the delay circuit DLY7 is connected to a reset input terminal R of the set/reset latch circuit 302. In this exemplary embodiment, the delay circuit DLY1 sets the length of a time period in which the first transmission circuit Tx1 is in the valid state. Each of the delay circuits DLY2 and DLY3 sets the length of the interval time period in which the first transmission circuit Tx1 is in the invalid state. Further, the delay circuit DLY3 sets the length of a time period in which the second reception circuit Rx2 is in the valid state. The delay circuit DLY2 is disposed so as to prevent the first transmission enable signal Tx1_EN and the second reception disenable signal Rx2_DIS from changing simultaneously.

The periodic pulse generation circuit 301 outputs a pulse signal PLS in a predetermined cycle. In this exemplary embodiment, the predetermined cycle set in the periodic pulse generation circuit 301 corresponds to a data transmission cycle of the first transmission circuit Tx1.

The set/reset latch circuit 302 has a set input terminal S supplied with the pulse signal PLS output by the periodic pulse generation circuit 301, the reset input terminal R supplied with the output signal from the final stage of the delay circuit DLY3, and an output terminal Q connected to the input terminal of the first stage of the delay circuit DLY1. When the set input terminal S receives a rising edge, the set/reset latch circuit 302 outputs a signal of a first logic level (for example, high level) from the output terminal Q, and maintains the logic level of the output terminal Q until the reset input terminal R receives a rising edge. When the reset input terminal R receives a rising edge, the set/reset latch circuit 302 switches the output terminal Q from the first logic level to a second logic level (for example, low level).

A normal logic input terminal of the AND circuit 303 having an inverting input is connected to the input terminal of the first stage of the delay circuit DLY1. An inverting logic input terminal of the AND circuit 303 having an inverting input is connected to the output terminal of the final stage of the delay circuit DLY1. The AND circuit 303 having an inverting input outputs the result of an AND operation on an inverted logical value of a signal received at the inverting logic input terminal and a logical value of a signal received at the normal logic input terminal as the first transmission enable signal Tx1_EN.

A normal logic input terminal of the NAND circuit 304 having an inverting input is connected to the input terminal of the first stage of the delay circuit DLY3. An inverting logic input terminal of the NAND circuit 304 having an inverting input is connected to the output terminal of the final stage of the delay circuit DLY3. The NAND circuit 304 having an inverting input outputs the inverted value of the result of an AND operation on an inverted logical value of a signal received at the inverting logic input terminal and a logical value of a signal received at the normal logic input terminal as the second reception disenable signal Rx2_DIS.

Next, FIG. 15 shows a timing diagram illustrating the operation of the first timing control circuit 10. As shown in FIG. 15, in the first timing control circuit 10, the periodic pulse generation circuit 301 periodically generates the pulse signal PLS. After a rising edge of the pulse signal PLS, in a time period in which the input terminal of the first stage of the delay circuit DLY1 is at the high level and the output terminal of the final stage of the delay circuit DLY1 is at the low level, the first transmission enable signal Tx1_EN becomes high level (a value indicating the valid state to the first transmission circuit Tx1). In a time period in which the first transmission enable signal Tx1_EN is at the high level, the second reception disenable signal Rx2_DIS is at the high level (a value indicating the invalid state to the second reception circuit Rx2). After the first transmission enable signal Tx1_EN becomes low level (a value indicating the invalid state to the first transmission circuit Tx1), in a time period in which the input terminal of the first stage of the delay circuit DLY3 is at the high level and the output terminal of the final stage of the delay circuit DLY3 is at the low level, the second reception disenable signal Rx2_DIS becomes low level (a value indicating the valid state to the second reception circuit Rx2). As shown in FIG. 15, the first timing control circuit 10 set an interval time period after the first transmission enable signal Tx1_EN is switched from the high level to the low level, thereby switching the first transmission circuit Tx1 to the invalid state.

Subsequently, the second timing control circuit 20 of the second circuit CHP2 will be described. FIG. 16 shows a block diagram of the second timing control circuit 20. As shown in FIG. 16, the second timing control circuit 20 includes delay circuits (DLY4 to DLY7, a periodic pulse generation circuit 305, a set/reset latch circuit 306, and AND circuits 307 and 308 each having an inverting input.

The delay circuits DLY4 to DLY7 are a set of delay circuits connected in series with an output of the set/reset latch circuit 306. An input of the first stage of the delay circuit DLY4 is connected to an output of the set/reset latch circuit 302, and an output of the delay circuit DLY7 is connected to the reset input terminal R of the set/reset latch circuit 306. In this exemplary embodiment, the delay circuit DLY4 sets the length of a time period in which the first transmission circuit Tx1 is in the valid state, and each of the delay circuits DLY5 to DLY7 sets the length of a time period in which the first reception circuit Rx1 in the invalid state and the length of a time period in which the second transmission circuit Tx2 is in the valid state during the interval time period. More specifically, each of the delay circuits DLY5 to DLY7 sets the length of a time period in which the first reception circuit Rx1 is in the invalid state, and the delay circuit DLY6 sets the length of a time period in which the second transmission circuit Tx2 is in the valid state. The delay circuits DLY5 and DLY7 are disposed so as to prevent the second transmission enable signal Tx2_EN and the first reception disenable signal Rx1_DIS from changing simultaneously.

The periodic pulse generation circuit 305 outputs the pulse signal PLS in a predetermined cycle. Assume in this exemplary embodiment that the cycle for the periodic pulse generation circuit 305 to generate the pulse signal PLS is set so as to match the cycle of the periodic pulse generation circuit 301 of the first timing control circuit 10.

The set input terminal S of the set/reset latch circuit 306 is supplied with the pulse signal PLS output by the periodic pulse generation circuit 305. The reset input terminal. R of the set/reset latch circuit 306 is supplied with the output signal from the delay circuit DLY7. The output terminal Q of the set/reset latch circuit 306 is connected to the input terminal of the first stage of the delay circuit DLY4. When the set input terminal S receives a rising edge, the set/reset latch circuit 306 outputs the signal of the first logic level (for example, high level) from the output terminal Q, and maintains the logic level of the output terminal Q until the reset input terminal R receives a rising edge. When the reset input terminal R receives a rising edge, the set/reset latch circuit 306 switches the output terminal Q from the first logic level to the second logic level (for example, low level).

A normal logic input terminal of the AND circuit 307 having an inverting input is connected to the input terminal of the first stage of the delay circuit DLY6. An inverting logic input terminal of the AND circuit 307 having an inverting input is connected to the output terminal of the final stage of the delay circuit DLY6. The AND circuit 307 having an inverting input outputs the result of an AND operation on an inverted logical value received at the inverting logic input terminal and a logical value of a signal received at the normal logic input terminal as the second transmission enable signal Tx2_EN.

A normal logic input terminal of the AND circuit 308 having an inverting input is connected to the input terminal of the delay circuit DLY5. An inverting logic input terminal of the AND circuit 308 having an inverting input is connected to the output terminal of the delay circuit DLY7. The AND circuit 308 having an inverting input outputs the result of an AND operation on an inverted logical value of a signal received at the inverting logic input terminal and a logical value of a signal received at the normal logic input terminal as the first reception disenable signal Rx1_DIS.

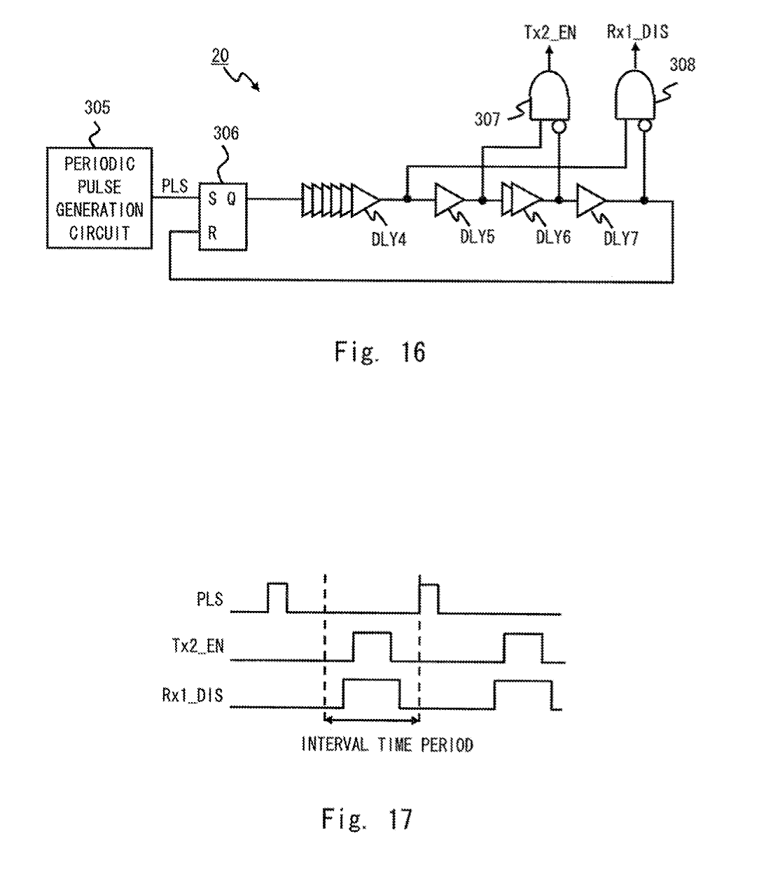

Subsequently, FIG. 17 shows a timing diagram illustrating the operation of the second timing control circuit 20. As shown in FIG. 17, in the second timing control circuit 20, the periodic pulse generation circuit 305 periodically generates the pulse signal PLS. In the second timing control circuit 20, the delay circuit DLY4 controls the logic levels of the first reception disenable signal Rx2_DIS and the second transmission enable signal Tx2_EN to remain unchanged until the operation of the first circuit CHP1 reaches the interval time period. When the operation reaches the interval time period after a rising edge of the pulse signal PLS, in a time period in which the input terminal of the delay circuit DLY5 is at the high level and the output terminal of the delay circuit DLY7 is at the low level, the first reception disenable signal Rx1_DIS becomes high level (a value indicating the invalid state to the first reception circuit Rx1). In a time period in which the input terminal of the first stage of the delay circuit DLY6 is at the high level and the output terminal of the final stage of the delay circuit DLY6 is at the low level, the second transmission enable signal Tx2_EN is at the high level (a value indicating the valid state to the second reception circuit Rx2). That is, the second timing control circuit controls the first reception circuit Rx1 to be switched to the invalid state in the interval time period, and controls the second transmission circuit Tx2 to be switched to the valid state during the time period in which the first reception circuit Rx1 is in the invalid state.

Subsequently, the transmission circuit and the reception circuit of the first circuit CHP1 and the transmission circuit and the reception circuit of the second circuit CHP2 will be described in detail. In this exemplary embodiment, a difference between the first circuit CHP1 differs from the second circuit CHP2 resides in that the signals for controlling the transmission circuit and the reception circuit are output from the first timing control circuit 10 or from the second timing control circuit 20. However, the same circuit configuration is used for each of the transmission circuit and the reception circuit. Thus, the transmission, circuit and the reception circuit of the first circuit CHP1 are herein described by way of example.

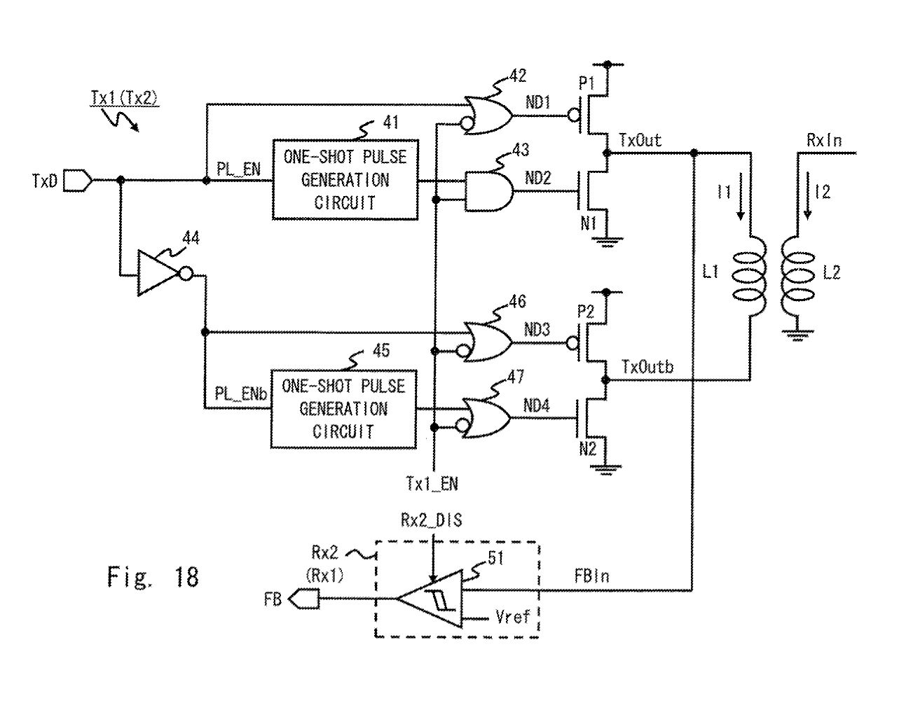

FIG. 18 shows a block diagram of each of the first transmission circuit Tx1 and the second reception circuit Rx2 which are formed on the first circuit CHP1. As shown in FIG. 18, the first transmission circuit Tx1 includes one-shot pulse generation circuits 41 and 45, OR circuits 42, 46, and 47 each having an inverting input, an AND circuit 43, an inverter 44, PMOS transistors P1 and P2, and NMOS transistors N1 and N2. The second reception circuit Rx2 includes a hysteresis comparator 51.

The first transmission circuit Tx1 includes, as output stage circuits, a first inverter circuit composed of the PMOS transistor P1 and the NMOS transistor N1 which are connected in series between a power supply terminal and a ground terminal, and a second inverter circuit composed of the PMOS transistor P2 and the NMOS transistor N2 which are connected in series between the power supply terminal and the ground terminal. An output terminal TxOut of the first inverter circuit is connected to one terminal of the first coil L1, and an output terminal TxOutb of the second inverter circuit is connected to the other terminal of the first coil L1. A node connecting the output terminal TxOut of the first inverter circuit and the first coil L1 is connected to the input terminal of the second reception circuit Rx2. In the first transmission circuit Tx1, the first and second inverter circuits output a current I1 to the first coil L1, thereby driving the first coil L1.

The one-shot pulse generation circuit 41 operates with the transmission data TxD, which is a transmission target signal, as an enable signal. The one-shot pulse generation circuit 41 in the enable state outputs a pulse signal at a predetermined interval. In this exemplary embodiment, the interval at which the one-shot pulse generation circuit 41 outputs the pulse signal is set so as to match the pulse generation cycle of the first periodic pulse generation circuit 301 of the first timing control circuit 10. The pulse signal generated by the one-shot pulse generation circuit 41 and the purse signal PLS generated by the first periodic pulse generation circuit 301 preferably have the same frequency, but may have different phases.

A normal input terminal of the OR circuit 42 having an inverting input receives the transmission data TxD, and an inverting input terminal thereof receives the first transmission enable signal Tx1_EN. The OR circuit 42 having an inverting input outputs the result of an OR operation on the value of the transmission data TxD and the inverted value of the first transmission enable signal Tx1_EN to the gate of the PMOS transistor P1.

One input terminal of the AND circuit 43 receives the output signal from the one-shot pulse generation circuit 41, and the other input terminal thereof receives the first transmission enable signal Tx1_EN. The AND circuit 43 outputs the result of an AND operation on the output signal from the one-shot pulse generation circuit 41 and the first transmission enable signal Tx1_EN to the gate of the NMOS transistor N1.

The inverter 44 outputs a signal obtained by inverting the transmission data TxD. The one-shot pulse generation circuit 45 operates with the transmission data TxD, which is inverted by the inverter 44, as an enable signal. The one-shot pulse generation circuit 45 in the enable state outputs a pulse signal at a predetermined interval. In this exemplary embodiment, the interval at which the one-shot pulse generation circuit 45 outputs the pulse signal is set so as to match the pulse generation cycle of the first periodic pulse generation circuit 301 of the first timing control circuit 10. The pulse signal generated by the one-shot pulse generation circuit 41 preferably has the same frequency and the same phase as those of the pulse signal generated by the one-shot pulse generation circuit 41.

A normal input terminal of the OR circuit 46 having an inverting input receives the transmission data TxD inverted by the inverter 44. An inverting input terminal of the OR circuit 46 having an inverting input receives the first transmission enable signal Tx1_EN. The OR circuit 46 having an inverting input outputs the result of an OR operation on the inverted value of the transmission data TxD and the inverted value of the first transmission enable signal Tx1_EN to the gate of the PMOS transistor P2.

A normal input terminal of the OR circuit 47 having an inverting input receives the output signal from the one-shot pulse generation circuit 45, and an inverting input terminal thereof receives the first transmission enable signal Tx1_EN. The OR circuit 47 having an inverting input outputs the result of an OR operation on the value of the output signal from the one-shot pulse generation circuit 45 and the inverted value of the first transmission enable signal Tx1_EN to the gate of the NMOS transistor N2.

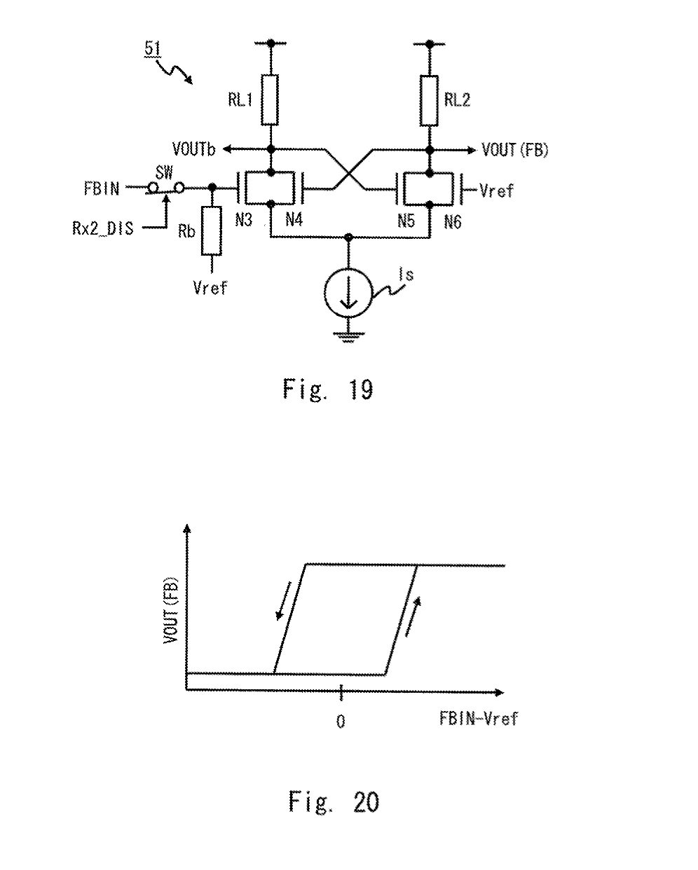

Subsequently, the second reception circuit Rx2 will be described in detail. FIG. 19 shows a block diagram of the hysteresis comparator 51 of the second reception circuit Rx2. As shown in FIG. 19, the hysteresis comparator 51 includes a switch SW, a bias resistor Rb, a current source Is, NMOS transistors N3 to N6, and load resistors RL1 and RL2.

One terminal of the current source Is is connected to the ground terminal, and the other terminal thereof supplies an operating current to each of the NMOS transistors N3 to N6. One terminal of the bias resistor Rb is supplied with a reference voltage Vref, and the other terminal thereof is connected to a node connecting one terminal of the switch SW and the gate of the NMOS transistor N3. The other terminal of the switch SW is supplied with a pulse signal FBIn supplied through the first coil L1. The switch SW is controlled by the second reception disenable signal Rx2_DIS. More specifically, the switch SW is turned on (conductive state) when the second reception disenable signal Rx2_DIS is at the low level, and is turned off (disconnected state) when the second reception disenable signal Rx2_DIS is at the high level. That is, the hysteresis comparator 51 operates (valid state) based on the pulse signal FBIn when the second reception disenable signal Rx2_DIS is at the low level, and is in a state unresponsive (invalid state) to the pulse signal FBIn when the second reception disenable signal Rx2_DIS is at the high level. In other words, in the hysteresis comparator 5 in the invalid state, the gate of the NMOS transistor N3 is supplied with the reference voltage Vref through the bias resistor Rb, and response data FB to be output maintains the previous value.

The gate of the NMOS transistor N3 is connected to one terminal of the switch SW. The gate of the NMOS transistor N4 is connected to a non-inverting output terminal VOUT. The sources of the NMOS transistors N3 and N4 are connected in common and are also connected to the other terminal of the current source Is. The drains of the NMOS transistors N3 and N4 are connected in common and are also connected to one terminal of the load resistor RL1. A node between the drains of the NMOS transistors N3 and N4 and one terminal of the load resistor RL1 serves as an inverting output terminal VOUTb. The other terminal of the load resistor RL1 is connected to the power supply terminal.

The gate of the NMOS transistor N5 is connected to the inverting output terminal VOUTb. The gate of the NMOS transistor N6 is supplied with the reference voltage Vref. The sources of the MOS transistors N5 and N6 are connected in common and are also connected to the other terminal of the current source Is. The drains of the NMOS transistors N5 and N6 are connected in common and are also connected to one terminal of the load resistor RL2. A node between the drains of the NMOS transistors N5 and N6 and one terminal of the load resistor RL2 serves as the non-inverting output terminal VOUT. The other terminal of the load resistor RL2 is connected to the power supply terminal. The response data FB, which is output by the second reception circuit Rx2, is output from the non-inverting output terminal VOUT.

Next, FIG. 20 shows an operation characteristic diagram of the hysteresis comparator 51 shown in FIG. 19. As show in FIG. 20, when a potential difference (FBIn−Vref) between the pulse signal FBIn and the reference voltage Vref is positive and is equal to or greater than a predetermined potential difference, the hysteresis comparator 51 switches the logic level of the response data FB, which is output from the non-inverting output terminal VOUT, to the high level. Meanwhile, when the potential difference (FBIn−Vref) between the pulse signal FBIn and the reference voltage Vref is negative and is equal to or greater than the predetermined potential difference, the hysteresis comparator 51 switches the logic level of the response data FB, which is output from the non-inverting output terminal VOUT, to the low level.

The first reception circuit Rx1 and the second reception circuit Rx2 maintain, in the invalid state period, the logic level of the output data output during the valid state period immediately before shifting to the invalid state. This allows the first reception circuit Rx1 and the second reception circuit Rx2 to transmit stable values to the subsequent-stage circuit also during the invalid state period, thereby increasing the stability of the communication. In order to maintain the value of the output data also in the invalid state of the first reception circuit Rx1 and the second reception circuit Rx2, a memory circuit, such as a latch circuit or a flip-flop circuit, may be provided at the output terminal VOUT of the reception circuit, for example, in addition to the example shown in FIG. 19. The load resistors RL1 and RL2 shown in FIG. 19 can also be implemented using transistors. When PMOS transistors are used for the load resistors RL1 and RL2, the gates of these PMOS transistors may be connected to the ground or drains, or may be cross-coupled with other PMOS transistors.

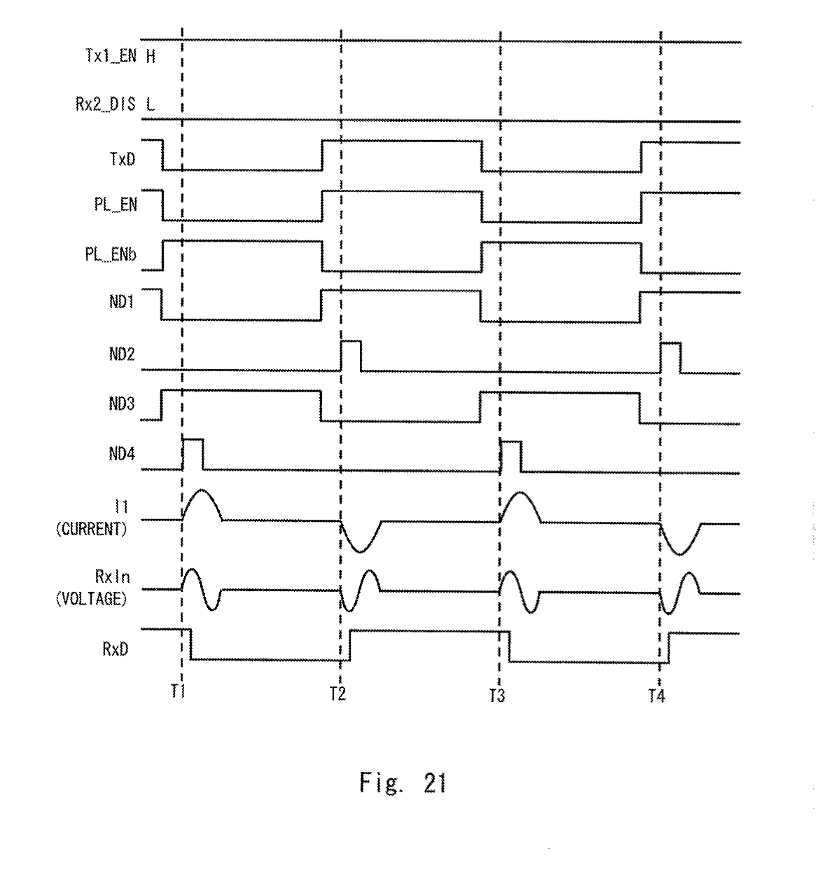

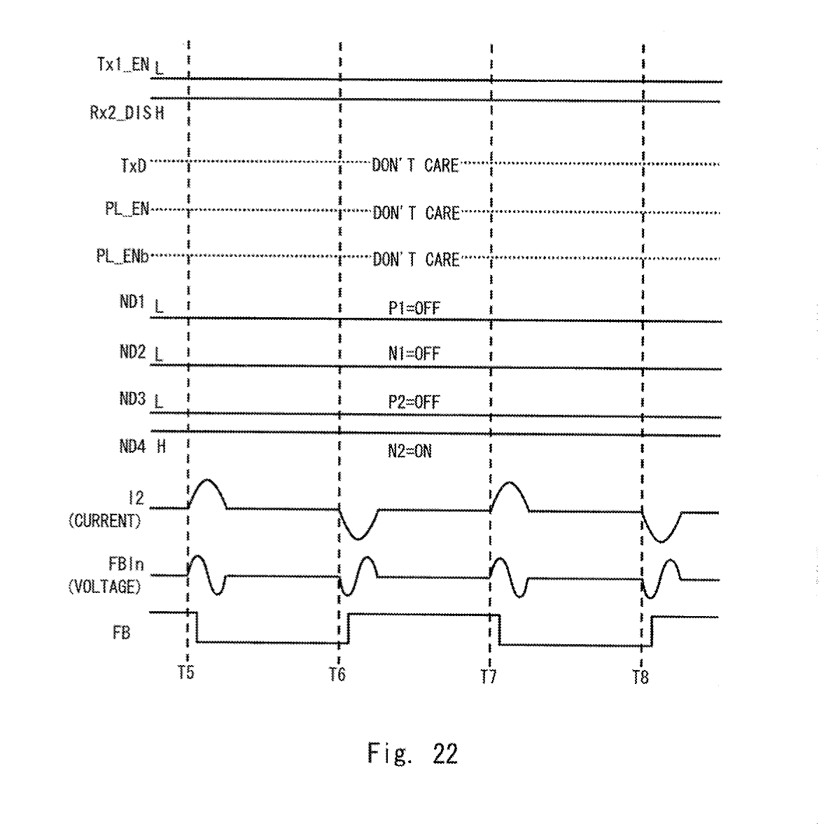

The operation of each of the first transmission circuit Tx1 and the second reception circuit Rx described above will be described. The first transmission circuit Tx1 and the second reception circuit Rx2 operate differently depending on the values of the first transmission enable signal Tx1_EN and the second reception disenable signal Rx2_DIS. FIG. 21 shows a timing diagram when the first transmission enable signal Tx1_EN has a value (for example, high level) indicating the valid state to the first transmission circuit Tx1. FIG. 22 shows a timing diagram when the first transmission enable signal Tx1_EN has a value (for example, low level) indicating the invalid state to the first transmission circuit Tx1.

First, the example shown in FIG. 21 will be described. In this case, the first transmission enable signal Tx1_EN is at the high level and the second reception disenable signal Rx2_DIS is at the low level. The one-shot pulse generation circuits 41 and 45 output pulse signals at timings T1 to T4. At this time, the transmission data TxD is at the low level at the timings T1 and T3, and the transmission data is at the high level at the timings T2 and T4.

Accordingly, at the timings T1 and T3, an enable signal PL_EN, which is input to the one-shot pulse generation circuit 41, is at the low level, and an enable signal IPL_ENb, which is input to the one-shot pulse generation circuit 45, is at the high level. A gate node ND1 of the PMOS transistor P1 and a gate node ND2 of the NMOS transistor N1 become low level, so that a high level signal is output to the output terminal TxOut. On the other hand, a gate node ND3 of the PMOS transistor P2 becomes high level, and a gate node ND4 of the NMOS transistor N2 receives pulse signals at the timings T1 and T3. As a result, at the timings T1 and T3, a positive current I1 (current flowing from the output terminal TxOut toward the output terminal TxOutb) flows through the first coil L1. Thus, at the timings T1 and T3, the first reception circuit Rx1 receives a positive pulse signal RxIn, and the output of the first reception circuit Rx1 falls.

At the timings T2 and T4, the enable signal PL_EN input to the one-shot pulse generation circuit 41 is at the high level, and the enable signal IPL_ENb input to the one-shot pulse generation circuit 45 is at the low level. The gate node ND1 of the PMOS transistor P1 becomes high level, and the gate node ND2 of the NMOS transistor N1 receives pulse signals at the timings 12 and T4. On the other hand, the gate node ND3 of the PMOS transistor P2 and the gate node ND4 of the NMOS transistor N2 become low level, so that a high level signal is output to the output terminal TxOutb. Accordingly, at the timings T2 and T4, a negative current I1 (current flowing from the output terminal TxOutb toward the output terminal TxOut) flows through the first coil L1. As a result, at the timings T2 and T4, the first reception circuit Rx1 receives the positive pulse signal RxIn, and the output of the first reception circuit Rx1 rises.

Next, the example shown in FIG. 22 will be described. In this case, the first transmission enable signal Tx1_EN becomes low level, and the second reception disenable signal Rx2_DIS becomes high level. Accordingly, the gate node ND1 of the PMOS transistor P1 is fixed at the high level, and the gate node ND pattern detection signal 2 of the NMOS transistor N1 is fixed at the low level. Further, the gate node ND3 of the PMOS transistor P2 is fixed at the high level, and the gate node ND4 of the NMOS transistor N2 is fixed at the high level. That is, the PMOS transistor P1, the NMOS transistor N1, and the PMOS transistor P2 are turned off, and the NMOS transistor N2 is turned on. As a result, one of the terminals of the first coil L1 to be connected to the second reception circuit Rx2 is switched to the high impedance state, and the other terminal is grounded. Further, in the example shown in FIG. 22, the second reception circuit Rx2 is in the valid state.

In the example shown in FIG. 22, at timings T5 to T8, the second transmission circuit Tx2 outputs pulse signals to the second coil L2. In the example shown in FIG. 22, at the timings T5 and T7, a positive current I2 flows through the second coil L2, and at the timings 16 and T8, a negative current I2 flows through the second coil L2. As a result, at the timings T5 and T7, the positive pulse signal FBIn is generated at the input terminal of the second reception circuit Rx2, and at the timings T6 and T8, the negative pulse signal FBIn is generated. Accordingly, the output of the second reception circuit Rx2 falls in response to the pulse signal FBIn generated at each of the timings T5 and T7, and the output of the second reception circuit Rx2 rises in response to the pulse signal FBIn generated at each of the timings T6 and 18.

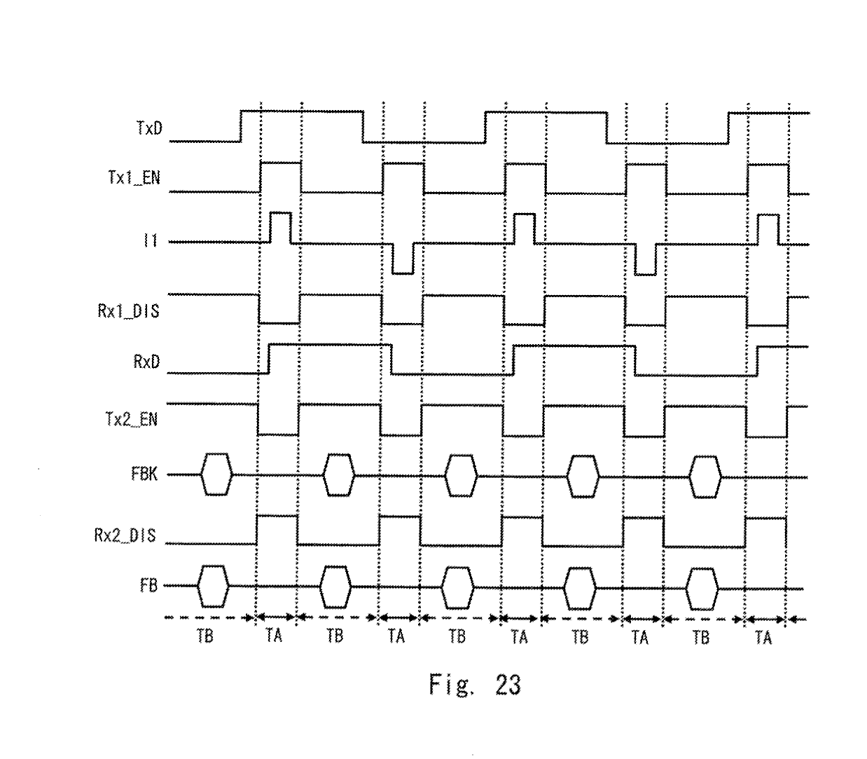

Subsequently, the overall operation of the communication system according to this exemplary embodiment will be described. FIG. 23 shows a timing diagram illustrating the overall operation of the communication system according to this exemplary embodiment. In FIG. 23, a delay time between a change in logic level of the first transmission enable signal Tx1_EN and a change in logic level of the second reception disenable signal Rx2_DIS and a delay time between a change in logic level of the first reception disenable signal Rx1_DIS and a change in logic level of the second transmission enable signal Tx2_EN are omitted for ease of illustration. As shown in FIG. 23, in the communication system according to this exemplary embodiment, bidirectional communication between the first circuit CHP2 and the second circuit CHP2 is implemented using a transmission time period TA in which the transmission data is transmitted from the first circuit CHP1 to the second circuit CHP2, and an interval time period TB which follows the transmission time period TA and in which the transmission circuit Tx1 of the first circuit CHP1 is in the invalid state.

In the transmission time period TA, the first timing control circuit 10 switches the first transmission enable signal Tx1_EN to the high level and also switches the second reception disenable signal Rx2_DIS to the high level. In the transmission time period TA, the second timing control circuit 20 switches the first reception disenable signal Rx1_DIS to the low level and also switches the second transmission enable signal Tx1_EN to the low level. As a result, in the transmission time period TA, the first transmission circuit Tx1 and the first reception circuit Rx1 are brought into the valid state, thereby transmitting signals from the first circuit CHP1 to the second circuit CHP2.

On the other hand, in the interval time period. TB, the first timing control circuit 10 sets the first transmission enable signal Tx1_EN to the low level and sets the second reception disenable signal Rx2_DIS to the low level. In the interval time period TB, the second timing control circuit 20 sets the first reception disenable signal Rx1_DIS to the high level and sets the second transmission enable signal Tx1_EN to the high level. As a result, in the interval time period TB, the second transmission circuit Tx2 and the second reception circuit Rx2 are switched to the valid state, thereby transmitting signals from the second circuit CHP2 to the first circuit CHP1.

That is, in the communication system according to this exemplary embodiment, during the transmission time period TA, the first transmission circuit. Tx1 is set to the valid state; the second reception circuit Rx2 is set to the invalid state; the second transmission circuit Tx2 is set to the invalid state; the first reception circuit Rx1 is set to the valid state; and the first transmission circuit Tx1 transmits a signal to the first reception circuit. Rx1 through the transformer. Further, during the time period after the transmission of the signal by the first transmission circuit Tx1, the first transmission circuit Tx1 is set to the invalid state; the second reception circuit Rx2 is set to the valid state; the second transmission circuit Tx2 is set to the valid state; the first reception circuit Rx1 is set to the invalid state; and the second transmission circuit Tx1 transmits a signal to the second reception circuit Rx2 through the transformer.

As described above, in the communication system according to this exemplary embodiment, the use of the first timing control circuit 10 and the second timing control circuit 20 makes it possible to implement a bidirectional communication between the first circuit CHP1 and the second circuit CHP2 without generating a crosstalk between the transmission signal and the reception signal. At this time, the first timing control circuit 10 and the second timing control circuit 20 may be composed of a set of delay circuits, a periodic pulse generation circuit, and a set/reset latch circuit. These circuits can be implemented with a smaller circuit area as compared with a conventional circuit for separating transmission/reception signals. Furthermore, the use of these circuits eliminates the need to transmit a mode switching signal for a mode switching circuit from the first circuit CHP1 to the second circuit CHP2. Accordingly, the communication system according to this exemplary embodiment can implement a bidirectional communication with a smaller circuit area as compared with a mode switching system. That is, in the communication system according to this exemplary embodiment, the circuit area of each of the first circuit and the second circuit can be reduced.

In the communication system according to this exemplary embodiment, the first timing control circuit 10 exclusively switches the valid state of the first transmission circuit Tx1 and the valid state of the second reception circuit Rx2, and the second timing control circuit 20 exclusively switches the valid state of the second transmission circuit Tx2 and the valid state of the first reception circuit Rx1. As a result, the pulse signal output by the first transmission circuit Tx1 prevents the second reception circuit Rx2 from erroneously reproducing the transmission data TxD. Additionally, the pulse signal output by the second transmission circuit Tx2 prevents the first reception circuit Rx1 from erroneously reproducing the response data FB. In the communication system according to this exemplary embodiment, the second reception circuit Rx2 is switched to the valid state upon switching of the first transmission circuit Tx1 to the invalid state, and the second transmission circuit Tx1 is switched to the valid state upon switching of the first reception circuit Rx1 to the invalid state (see FIGS. 15 and 17). Consequently, the communication system according to this exemplary embodiment effectively prevents a signal transmission error.

In the communication system according to this exemplary embodiment, the second timing control circuit 20 controls the first transmission circuit Tx1 and the second transmission circuit Tx2 so that the first transmission circuit Tx1 and the second transmission circuit Tx2 do not simultaneously turn into the valid state. Thus, the communication system according to this exemplary embodiment prevents occurrence of a malfunction in the communication system.

In the communication system according to this exemplary embodiment, switching between the valid state and the invalid state of each of the first transmission circuit Tx1 and the second reception circuit Rx2 and switching between the valid state and the invalid state of each of the second transmission circuit Tx2 and the first reception circuit Rx1 are performed in a predetermined cycle. Furthermore, in the communication system according to this exemplary embodiment, the first transmission circuit Tx1 outputs a pulse signal at predetermined intervals to the transformer. This enables bidirectional communication without control of mode switching or the like for the first circuit CHP1 and the second circuit CHP2. This cycle is set depending on the interval of the pulse signals generated by the periodic pulse generation circuit of each of the first timing control circuit 10 and the second timing control circuit 20.

In the communication system according to this exemplary embodiment, the second transmission circuit Tx2 sets an output terminal FBK, which corresponds to a node connecting the second coil L2 and the first reception circuit Rx1, to the high impedance in the transmission time period TA. Further, in the interval time period TB, the first transmission circuit Tx1 sets the output terminal TxOut, which corresponds to a node connecting the first coil L1 and the second reception circuit Rx2, to the high impedance. As a result, the pulse signals generated through the transformer reach the first reception circuit Rx1 and the second reception circuit Rx2 without being attenuated. This improves the accuracy of communication in the communication system according to this exemplary embodiment. In the first exemplary embodiment, controlling of the on/off states of the transistors constituting the output stage of the transmission circuit is used to set the output terminal of the transmission circuit to the high impedance. Alternatively, a switch element may be provided at the output terminal of the transmission circuit to thereby set the output terminal to the high impedance.

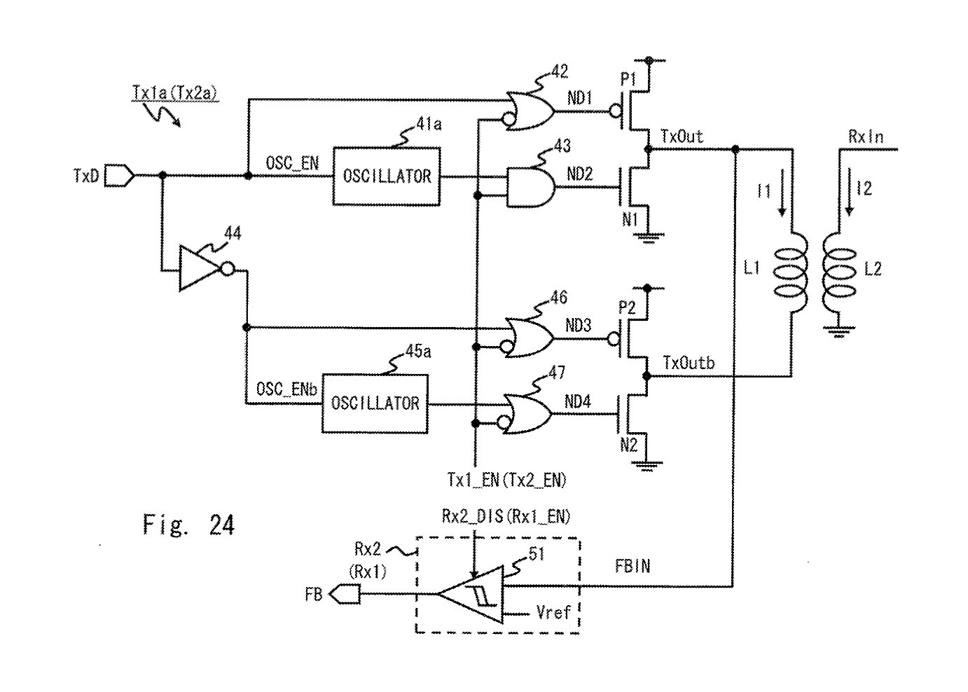

Now, a modified example of the first and second transmission circuits described above will be described. FIG. 24 shows a block diagram of a modified example of the transmission circuit (hereinafter, referred to as “transmission circuit Tx1a”). As shown in FIG. 24, the transmission circuit Tx1a has a configuration in which the one-shot pulse generation circuits 41 and 45 of the transmission circuit Tx1 shown in FIG. 18 are replaced with oscillators 41a and 45a. The operation and interruption of the oscillators 41a and 45a are determined based on enable signals OSC_EN (corresponding to the transmission data TxD) and OSC_ENb (corresponding to the inverted value of the transmission data TxD). The oscillators 41a and 45a output successive pulse signals having a predetermined frequency in the operating state.

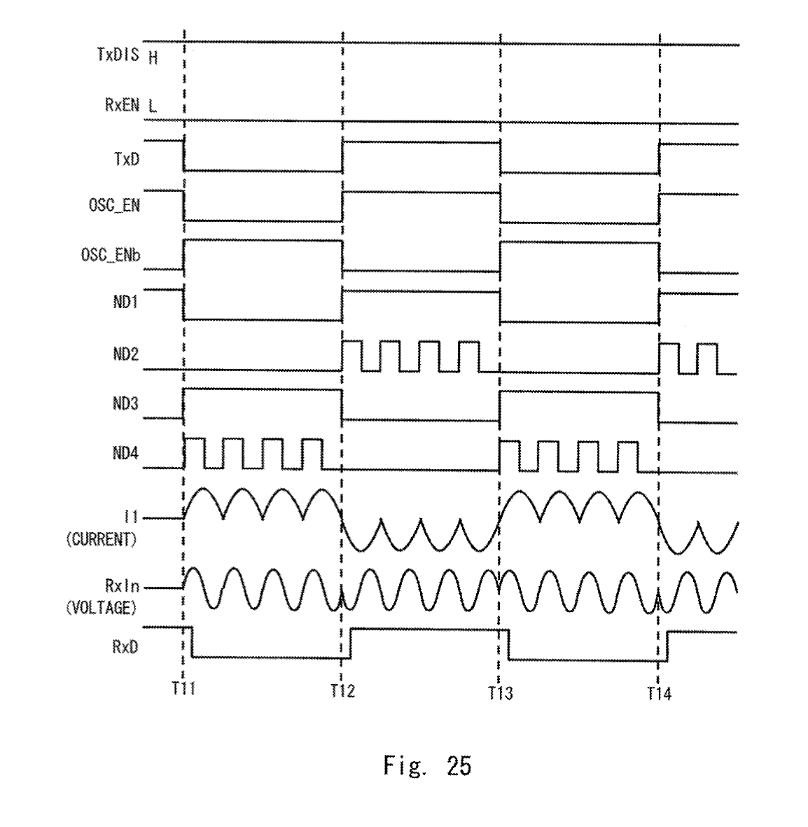

FIG. 25 shows a timing diagram illustrating the operation of the transmission circuit Tx1a. As shown in FIG. 25, in the time periods (timings T11 to T12 and timings T13 to T14) in which the transmission circuit Tx1a is at the low level, the positive current I1 is successively generated in the first coil L1. Meanwhile, the transmission circuit Tx1a successively generates the negative current I1 in the first coil L1 in the time periods (timings T12 to 113 and timing T14 and subsequent timings) in which the transmission data is at the high level. Also when such a current I1 is generated in the manner as described above, data transmission can be correctly performed by use of the hysteresis comparator 51 as the reception circuit. Not only the one-shot pulse generation circuits but also pulse generation circuits in an exemplary embodiment described below may be replaced with oscillators.

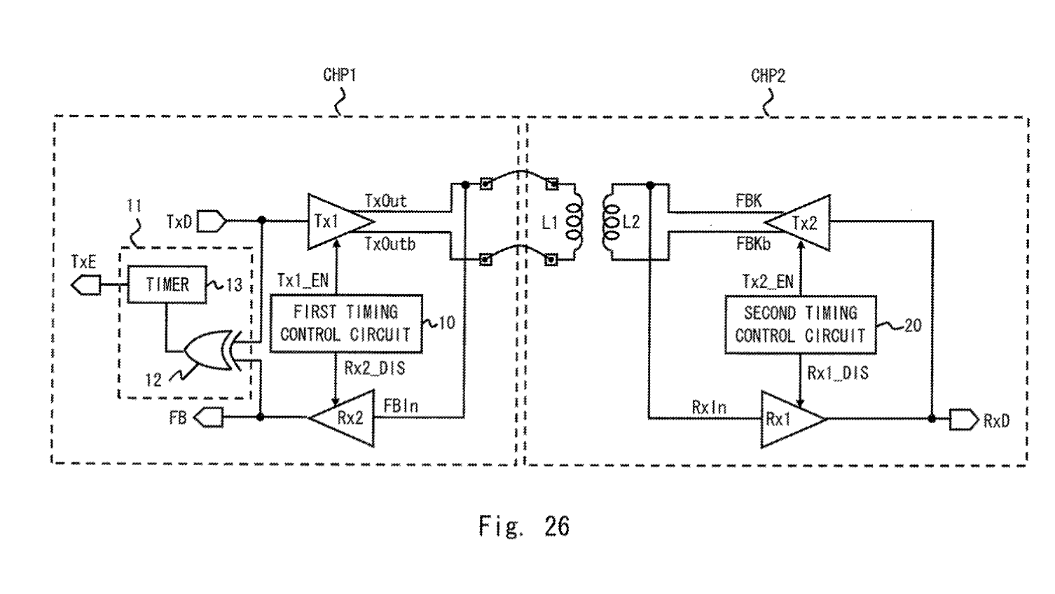

Next, a modified example of the communication system according to the first exemplary embodiment will be described. FIG. 26 shows a block diagram of a modified example of the communication system according to the first exemplary embodiment. The communication system shown in FIG. 26 has a configuration in which an error detection circuit 11 is added to the communication system shown in FIG. 13. In the communication system according to the first exemplary embodiment, the second transmission circuit Tx2 sends back the value of the reception data RxD, which is reproduced by the first reception circuit Rx1, as response data to the second reception circuit Rx1. Then, the error detection circuit 11 detects a transmission error of the transmission data TxD based on the transmission data TxD input to the first transmission circuit Tx1 and the response data FB output by the second reception circuit Tx2, and outputs a transmission error signal TxE. The error detection circuit 11 is provided in the first circuit CHP1.

More specifically, the error detection circuit 11 includes an ExOR circuit 12 and a timer 13. One input terminal of the ExOR circuit 12 receives the transmission data TxD, and the other input terminal thereof receives the response data FB. The ExOR circuit 12 outputs the result of an exclusive OR operation on the value of the transmission data TxD and the value of the response data FB. The timer 13 outputs the transmission error signal TxE when the time period in which the output signal from the ExOR circuit 12 has the first logic level (for example, high level) is longer than a predetermined determination time period.

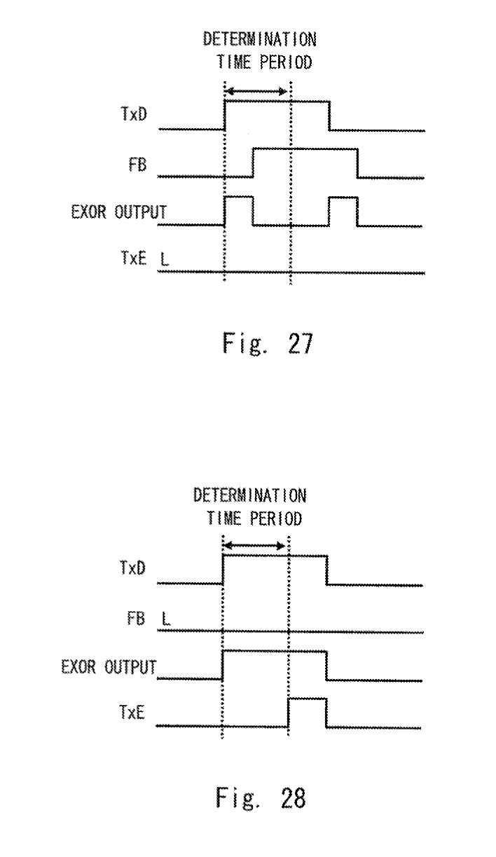

FIGS. 27 and 28 are timing diagrams each showing the operation of the error detection circuit 11. The example of FIG. 27 shows the operation of the error detection circuit 11 when the transmission data TxD is normally transmitted. The example of FIG. 28 shows the operation of the error detection circuit 11 when the transmission data TxD is not normally transmitted.

As shown in FIG. 27, when the communication is normally performed, the response data FB having the same logic as that of the transmission data TxD reaches the ExOR circuit 12 of the error detection circuit 11 with a slight delay. Accordingly, the output of the ExOR circuit becomes high level only during the time period corresponding to the response delay. In the example shown in FIG. 27, however, the time period in which the output of the ExOR circuit is maintained at the high level is shorter than the determination time period. Accordingly, the transmission error signal TxE is maintained at the low level.

Meanwhile, in the example shown in FIG. 28, the communication is not normally performed, and the response data FB and the transmission data TxD do not match. The output of the ExOR circuit 12 becomes high level during the time period in which the transmission data TxD is maintained at the high level. As a result, the output of the ExOR circuit 12 is maintained at the high level when the time period exceeds the determination time period. Accordingly, in the example shown in FIG. 28, when the time period in which the output of the ExOR circuit 12 is at the high level exceeds the determination time period, the transmission error signal TxE from the timer 13 becomes high level.

The control circuit MCU shown in FIG. 12, for example, is notified of the transmission error signal TxE output by the error detection circuit 11. This allows the control circuit MCU to resend the transmission data, which has been unsuccessfully transmitted, to the first transmission circuit Rx1. This improves the reliability of communication in the communication system shown in FIG. 26. In particular, in the case where the first circuit CHP1 and the second circuit CHP2 operate based on different power supplies, if the two power supply systems vary differently, this difference causes noise, which may result in a malfunction in the operation of the communication system. In such a case, the communication system shown in FIG. 26 can accurately check whether the transmission data TxD has been correctly transmitted, so that an especially large effect can be obtained.

### Second Exemplary Embodiment

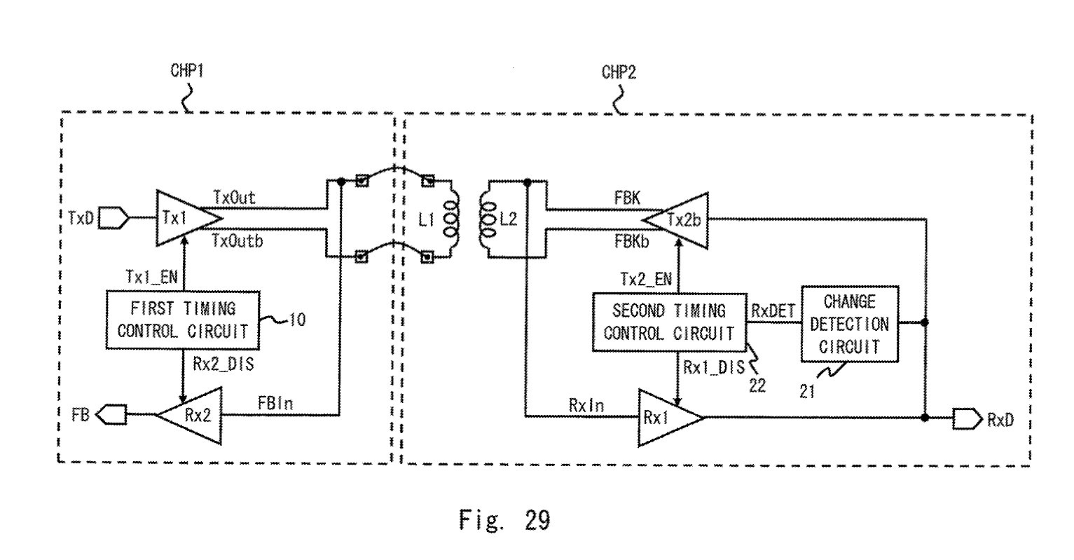

FIG. 29 shows a block diagram of a communication system according to a second exemplary embodiment. As shown in FIG. 29, the communication system according to the second exemplary embodiment differs from the communication system of the first exemplary embodiment in the configuration of the second circuit CHP2. In the communication system according to the second exemplary embodiment, a change detection circuit 21 is added to the second circuit CHP2. Further, in the communication system according to the second exemplary embodiment, a second timing control circuit 22 is used in place of the second timing control circuit 20, and a second transmission circuit Tx2b is used in place of the second transmission circuit Tx2. Hereinafter, the same elements as those of the first exemplary embodiment are denoted by the same reference numerals as those of the first exemplary embodiment, and the description thereof is omitted.

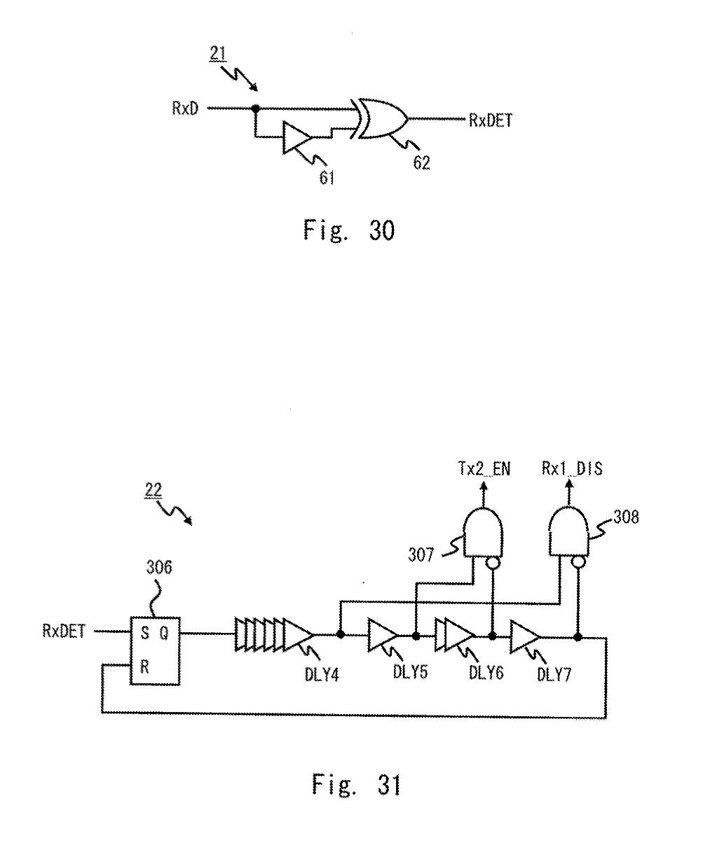

The change detection circuit 21 detects switching of the logic level of the reception data RxD output by the first reception circuit Rx1, and outputs a change detection signal RxDET. FIG. 30 shows a block diagram of the change detection circuit 21. As shown in FIG. 31, the change detection circuit 21 includes a delay circuit 61 and an ExOR circuit 62. The delay circuit 61 provides a delay to the reception data RxD and outputs it to the ExOR circuit 62. One terminal of the ExOR circuit 62 receives the reception data RxD, and the other terminal thereof receives the reception data RxD having passed through the delay circuit 61. The ExOR circuit 62 outputs the result of an exclusive OR operation on the two input signals as the change detection signal RxDET. Specifically, in the change detection circuit 21, when the logic level of the reception data RxD changes, the signal input to the ExOR circuit 62 transitions to a different logic level in the time period of the delay time set in the delay circuit 61, and the change detection signal RxDET is set to the high level (change detected state) during this time period.

The second timing control circuit 22 generates the first reception disenable signal Rx1_DIS and the second transmission enable signal Tx2_EN in response to a rising edge of the change detection signal RxDET. FIG. 31 shows a block diagram of the second timing control circuit 22. As shown in FIG. 31, the second timing control circuit 22 has a configuration in which the periodic pulse generation circuit 305 of the second timing control circuit 20 shown in FIG. 16 is omitted and the change detection signal RxDET is input to the set input terminal S of the set/reset latch circuit 306.

Specifically, in the communication system according to the second exemplary embodiment, the second timing control circuit 22 sets the reception circuit Rx1 to the invalid state and sets the second transmission circuit Tx2 to the valid state in response to a change in logic level of the reception data RxD. Also in the second exemplary embodiment, the second timing control circuit 22 sets the first reception circuit Rx1 to the invalid state and sets the second transmission circuit Tx2 to the valid state in the interval time period in which the first transmission circuit Tx1 is in the invalid state.

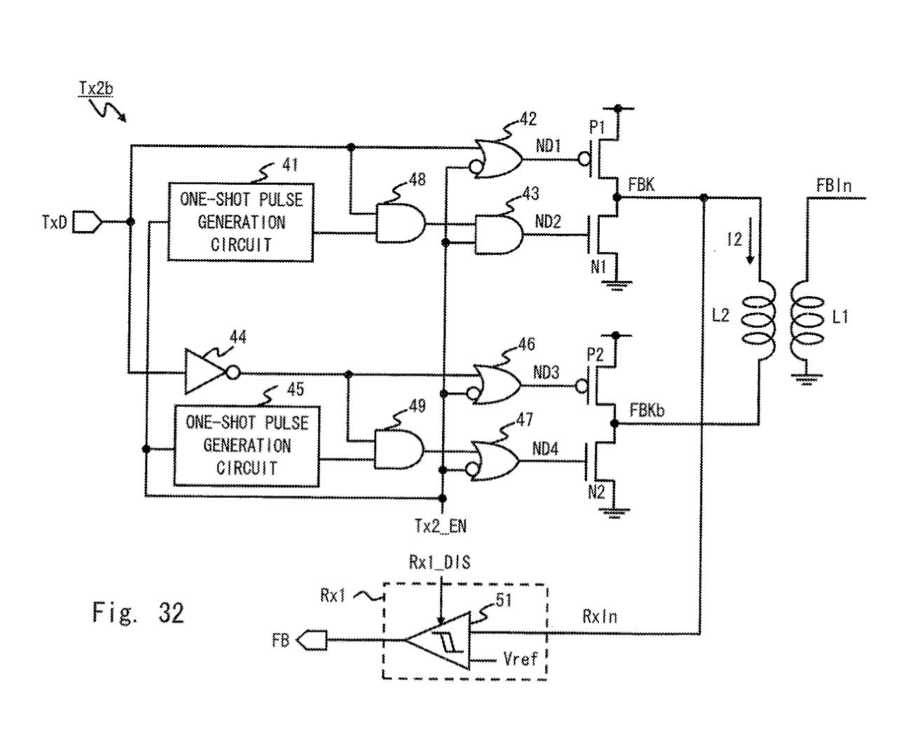

The second transmission circuit Tx2b outputs a pulse signal corresponding to the transmission data (the reception data RxD in the case of the second transmission circuit) in response to the second transmission enable signal Tx2_EN output by the second timing control circuit 22, and drives the second coil L2. FIG. 32 shows a block diagram of the second transmission circuit Tx2b. As shown in FIG. 32, the second transmission circuit Tx2b has a configuration in which AND circuits 48 and 49 are added to the second transmission circuit Tx1 (having the same circuit configuration as the transmission circuit shown in FIG. 18) of the first exemplary embodiment. The second transmission circuit Tx2b differs from the second transmission circuit Tx1 in the signal input as an enable signal to the one-shot pulse generation circuits 41 and 45.

In the second transmission circuit Tx2b, the second transmission enable signal Tx2_EN is input as the enable signal to the one-shot pulse generation circuits 41 and 45. Specifically, in the second transmission circuit Tx2b, the one-shot pulse generation circuits 41 and 45 output pulse signals during the time period in which the second transmission enable signal Tx2_EN is at the high level.

One input terminal of the AND circuit 48 receives the transmission data TxD to be transmitted, and the other input terminal thereof receives the pulse signal output by the one-shot pulse generation circuit 41. The AND circuit 48 outputs the result of an AND operation on the logical value of the transmission data TxD and the logical value of the pulse signal to one input terminal of the AND circuit 43. One input of the AND circuit 49 receives the inverted logical value of the transmission data TxD to be transmitted, and the other input terminal thereof receives the pulse signal output by the one-shot pulse generation circuit 45. The AND circuit 49 outputs the result of an AND operation on the inverted logical value of the transmission data TxD and the logical value of the pulse signal to the normal input terminal of the OR circuit 47 having an inverting input.

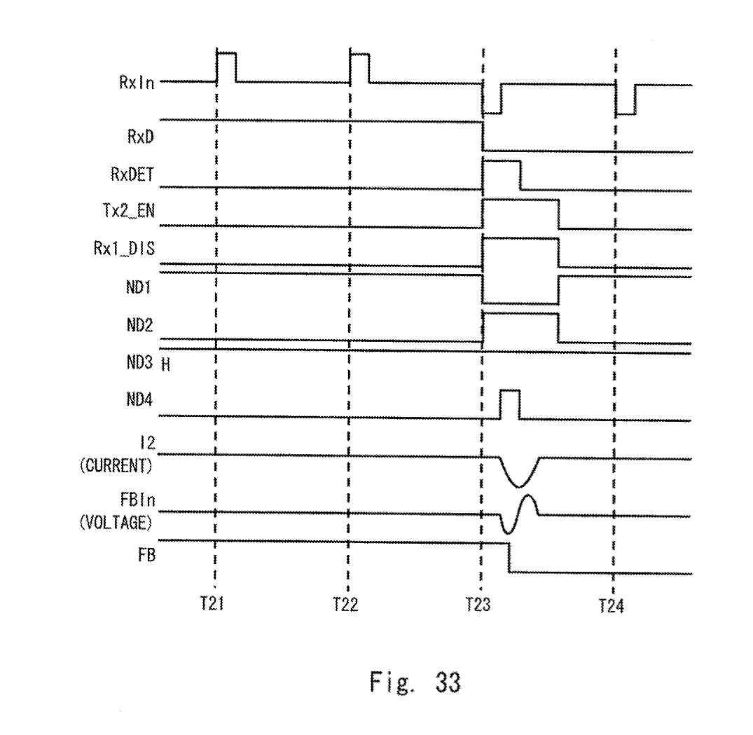

Now, the operation of the second circuit CHP2 of the communication system according to the second exemplary embodiment will be described. FIG. 33 shows a timing diagram illustrating the operation of the second circuit CHP2. In FIG. 33, a delay time between a change in logic level of the first reception disenable signal Rx1_DIS and a change in logic level of the second transmission enable signal Tx2_EN is omitted for ease of illustration. As shown in FIG. 33, at timings T21 and T22, the pulse signal RxIn is input from the first circuit to the first reception circuit Rx1 through the transformer. At the timings T21 and T22, however, the logic level of the reception data RxD is the same as the previous logic level, so the change detection, signal RxDET does not change. Accordingly, the second circuit CHP2 maintains the second transmission circuit Tx2 in the invalid state.

Then, at a timing T23, the change direction of the pulse signal RxIn, which is input to the first reception circuit Rx1, is changed from the previous direction. Thus, the first reception circuit Rx1 switches the logic level of the reception data RxD in response to the pulse signal RxIn received at the timing T23. Then, when the change detection circuit 21 detects a change in logic level of the reception data RxD, the change detection signal RxDET is switched to the high level. The second timing control circuit 22 sets the first reception disenable signal Rx1_DIS to the high level and sets the second transmission enable signal Tx2_EN to the high level in response to a rising edge of the change detection signal RxDET. As a result, the first reception circuit Rx1 comes into the invalid state and the second transmission circuit Tx2 comes into the valid state.

At the timing T23, the reception data RxD becomes low level, so that the negative current I2 flows through the second coil L2. In response to the change in the current I2, the pulse signal FBIn to be input to the second reception circuit Rx2 is generated. The second reception circuit Rx2 switches the response data. FR from the high level to the low level according to the pulse signal FBIn.

At a timing T24, the logic level of the reception data RxD is the same as the logic level at the timing T23, so the change detection signal RxDET does not change in the same way as in the timings T21 and T22. Accordingly, the second circuit CHP2 maintains the second transmission circuit Tx2 in the invalid state.

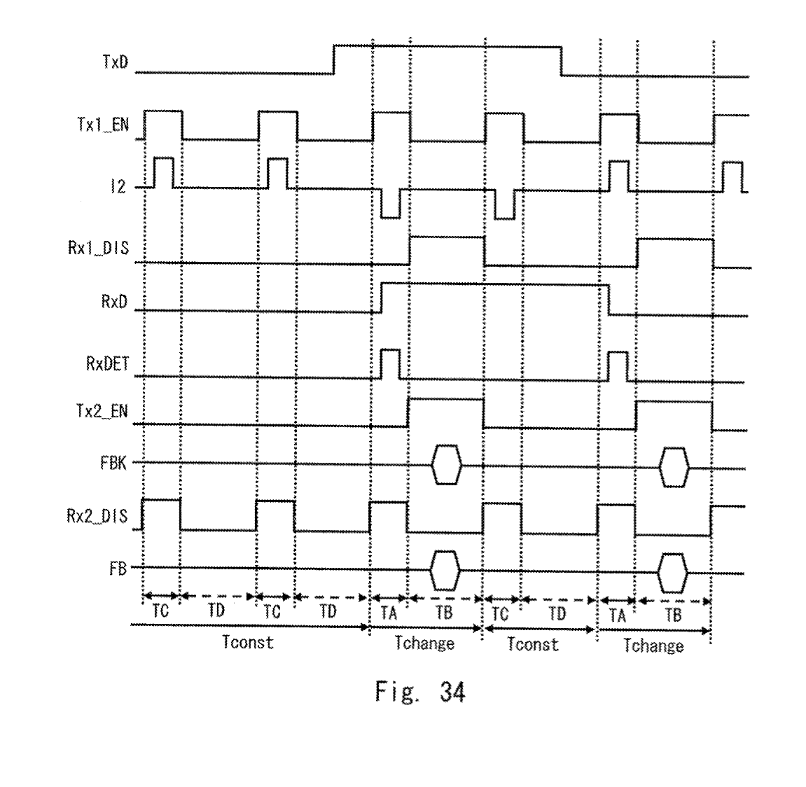

Subsequently, the overall operation of the communication system according to the second exemplary embodiment will be described. FIG. 34 shows a timing diagram illustrating the operation of the communication system according to the second exemplary embodiment. In FIG. 34, a delay time between a change in logic level of the first transmission enable signal Tx1_EN and a change in logic level of the second reception disenable signal Rx2_DIS, and a delay time between a change in logic level of the first reception disenable signal Rx1_DIS and a change in logic level of the second transmission enable signal Tx2_EN are omitted for ease of illustration.

As shown in FIG. 34, the communication system according to the second exemplary embodiment operates differently depending on whether a change occurs in the logic level of the reception data RxD. First, a description will be made of the operation of the communication system according to the second exemplary embodiment in a reception data constant time period Tconst in which the logic level of the reception data RxD does not change.

During a transmission time period TC in the reception data constant time period Tconst, the first transmission enable signal Tx1_EN and the second reception disenable signal Rx2_DIS in the first circuit CHP1 are at the high level. Accordingly, the first transmission circuit Tx1 outputs a pulse signal to the first coil, and the second reception circuit Rx2 comes into the invalid state. On the other hand, during the transmission time period TC, the first reception disenable signal Rx1_DIS and the second reception enable signal Tx2_EN in the second circuit CHP2 are at the low level. Thus, the first reception circuit Rx1 comes into the valid state, and the second transmission circuit Tx2 comes into the invalid state. However, since the signal input to the first reception circuit Rx1 has an amplitude of the same polarity as that of the pulse signal previously input, the reception data RxD does not change. The change detection signal RxDET is also maintained at the low level.

During an interval time period TD after the transmission time period TC, the change detection signal RxDET is maintained at the low level, so the second transmission enable signal Tx2_EN supplied to the second transmission circuit Tx2 is maintained at the low level. During the interval time period TD in the reception data constant time period Tconst, the response data FB is not transmitted from the second circuit CHP2 to the first circuit CHP1. In other words, in the reception data constant time period Tconst, only the communication from the first circuit CHP1 to the second circuit. CHP2 is performed during the transmission time period TC, and the communication is not performed during the interval time period TD.

Subsequently, the operation of the communication system according to the second exemplary embodiment in a reception data change time period Tchange in which the reception data RxD changes. During the transmission time period TA in the reception data change time period Tchange, the first transmission enable signal Tx1_EN and the second reception disenable signal Rx2_DIS in the first circuit CHP1 are at the high level. Accordingly, the first transmission circuit Tx1 outputs a pulse signal to the first coil, and the second reception circuit Rx2 comes into the invalid state. On the other hand, in the transmission time period TA, the first reception disenable signal Rx1_DIS and the second reception enable signal Tx2_EN in the second circuit CHP2 are at the low level. Accordingly, the first reception circuit Rx1 comes into the valid state, and the second transmission circuit Tx2 comes into the invalid state. Since the signal input to the first reception circuit Rx1 has an amplitude different from that of the pulse signal previously input, the reception data RxD changes. In response to the change in the reception data RxD, the change detection signal RxDET temporarily becomes high level.

During the interval time period TB after the transmission time period TA, the second timing control circuit controls the first reception disenable signal Rx1_DIS and the second transmission enable signal Tx2_EN in response to a rising edge of the change detection signal RxDET in the transmission time period TA. As a result, in the interval time period TB, the second transmission enable signal Tx2_EN, which is supplied to the second transmission circuit Tx2, and the first reception disenable signal Rx1_DIS, which is supplied to the first reception circuit Rx1, become high level. Accordingly, during the interval time period TB in the reception data change time period Tchange, the response data FB is transmitted from the second circuit CHP2 to the first circuit CHP1, and the second reception circuit Rx2 reproduces the response data FB in response to the received pulse signal FBIn. In other words, in the reception data change time period Tchange, the communication from the first circuit CHP1 to the second circuit CHP2 is performed during the transmission time period TA, and the communication from the second circuit CHP2 to the first circuit CHP1 is performed during the interval time period TB.

As described above, the second circuit CHP2 of the communication system according to the second exemplary embodiment includes the change detection circuit 21 that detects switching of the logic level of the reception data output by the first reception circuit Rx1, and outputs the change detection signal RxDET. The second timing control circuit 22 shifts the first reception circuit Rx1 to the invalid state and shifts the second transmission circuit Tx1 to the valid state in response to the change detection signal RxDET. After that, the second timing control circuit 22 shifts the first reception circuit Rx1 to the valid state and shifts the second transmission circuit Tx1 to the invalid state. That is, the second transmission circuit Tx2 of the communication system according to the second exemplary embodiment shifts to the valid state in response to the change in logic level of the reception data RxD output by the first reception circuit Rx1.

Thus, in the communication system according to the second exemplary embodiment, the number of unnecessary communications from the second circuit CHP2 to the first circuit CHP1 can be reduced. The reduction in the number of unnecessary communications results in a reduction in the possibility of occurrence of a malfunction in the communication from the second circuit CHP2 to the first circuit CHP1. Also in the communication system according to the second exemplary embodiment, when the reception data RxD changes differently from the transmission data TxD, a difference occurs between the response data FB output by the second reception circuit Rx2 and the transmission data TxD. This makes it possible to detect a malfunction in the second circuit CHP2 or a malfunction in the communication.

Furthermore, in the communication system according to the second exemplary embodiment, the communication from the second circuit CHP2 to the first circuit CHP1 is implemented in a mode of responding to the communication from the first circuit CHP1 to the second circuit CHP2. Therefore, in the communication system according to the second exemplary embodiment, the possibility of occurrence of a crosstalk between the transmission and reception signals can be drastically reduced as compared with the communication system according to the first exemplary embodiment.

Moreover, in the communication system according to the second exemplary embodiment, the number of communications from the second circuit CHP2 to the first circuit CHP1 is reduced to thereby achieve a reduction in power consumption of the second circuit CHP2. Generally, in the case where the transmission circuit drives a coil, the transmission circuit outputs a large drive current, which results in an increase in power consumption of the transmission circuit. In the communication system according to the second exemplary embodiment, however, the time period in which the second transmission circuit is valid is shorter than that of the second transmission circuit according to the first exemplary embodiment. This enables reduction in power consumption of the second transmission circuit.

### Third Exemplary Embodiment

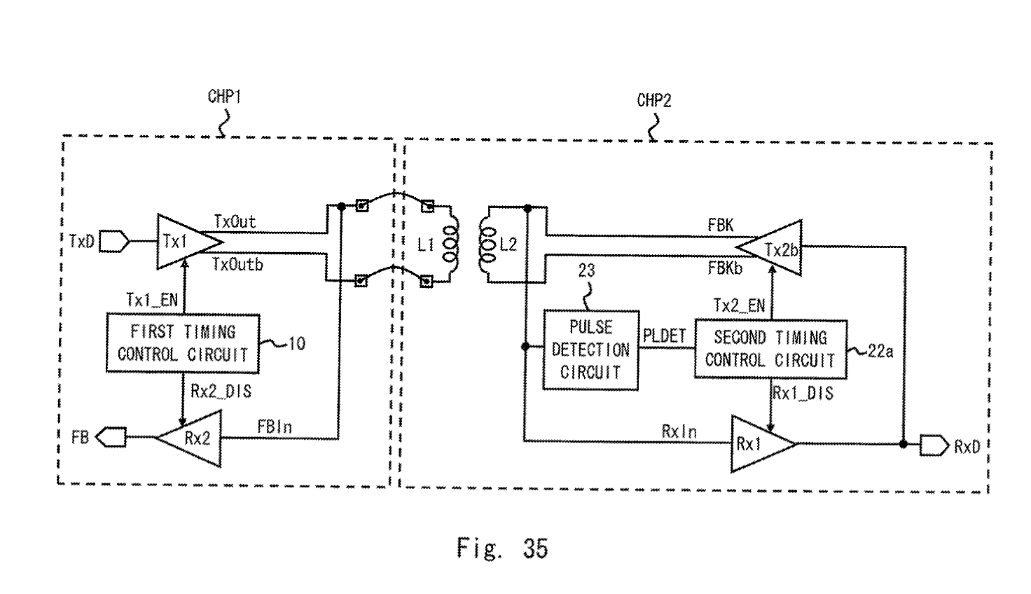

FIG. 35 shows a block diagram of a communication system according to a third exemplary embodiment. As shown in FIG. 35, the communication system of the third exemplary embodiment differs from the communication system of the first exemplary embodiment in the configuration of the second circuit CHP2. In the communication system according to the third exemplary embodiment, a pulse detection circuit 23 is added to the second circuit CHP2. Further, in the communication system according to the third exemplary embodiment, a second timing control circuit 22a is used in place of the second timing control circuit 20, and the second transmission circuit Tx2b is used in place of the second transmission circuit Tx2. Hereinafter, the same elements as those of the first and second exemplary embodiments are denoted by the same reference numerals as those of the first and second exemplary embodiments, so the description thereof is omitted.

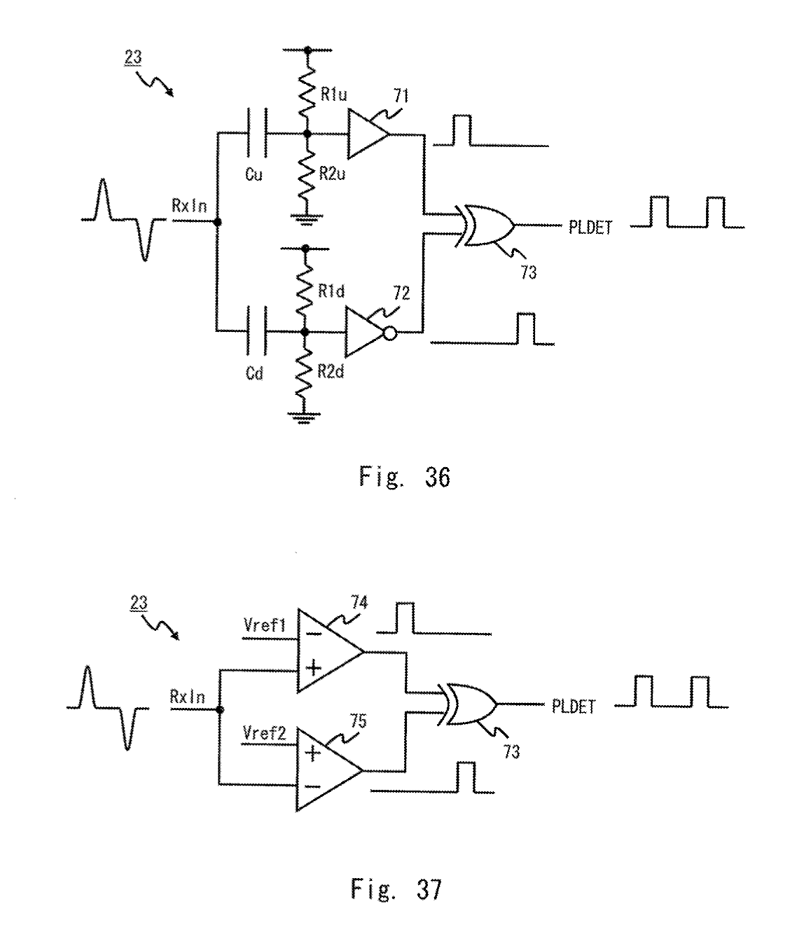

The pulse detection circuit 23 detects a pulse signal input to the first reception circuit Rx1, and outputs a pulse detection signal PLDET. FIGS. 36 and 37 each show a block diagram of the pulse detection circuit 23. The pulse detection circuit 23 shown in FIG. 37 is a modified example of the pulse detection circuit 23 shown in FIG. 36.

The pulse detection circuit 23 shown in FIG. 36 includes capacitors Cu and Cd, resistors R1u, R2u, R1d, and R2d, a buffer circuit 71, an inverter 72, and an ExOR circuit 73. One terminal of the capacitor Cu receives the pulse signal RxIn, and the other terminal thereof is connected to an input terminal of the buffer circuit 71. One terminal of the capacitor Cd receives the pulse signal RxIn, and the other terminal thereof is connected to an input terminal of the inverter 72. The resistors R1u and R2u are connected in series between the power supply terminal and the ground terminal. A node connecting the resistors R1u and R2u is connected to a node connecting the capacitor Cu and the input terminal of the buffer circuit 71. The resistors R1d and R2d are connected in series between the power supply terminal and the ground terminal. A node connecting the resistors R1d and R2d is connected to a node connecting the capacitor Cd and the input terminal of the inverter 72.

The buffer circuit 71 outputs a pulse signal having an amplitude of the same polarity as that of the input signal when the signal level of the signal received at the input terminal exceeds a threshold. An output terminal of the buffer circuit 71 is connected to one input terminal of the ExOR circuit 73. The inverter 72 outputs a pulse signal having an amplitude of a polarity inverted from that of the input signal when the signal level of the signal received at the input terminal falls below the threshold. An output terminal of the inverter 72 is connected to the other input terminal of the ExOR circuit 73. The ExOR circuit 73 outputs the result of an exclusive OR operation on the two input signals as the pulse detection signal PLDET.

The pulse detection circuit 23 shown in FIG. 37 includes the capacitors Cu and Cd and the resistors R1u, R2u, R1d, and R2d. Further, in the pulse detection circuit 23, comparators 74 and 75 are used in place of the buffer circuit 71 and the inverter 72. An inverting terminal of the comparator 74 receives a reference voltage Vref1, and a non-inverting input terminal thereof receives the pulse signal RxIn. The comparator 74 outputs a pulse signal having a positive amplitude when the signal level of the pulse signal RxIn exceeds the voltage level of the reference voltage Vref1. An output of the comparator 74 is connected to one input terminal of the ExOR circuit 73. A non-inverting terminal of the comparator 75 receives a reference voltage Vref2, and an inverting input terminal thereof receives the pulse signal RxIn. The comparator 75 outputs a pulse signal having a positive amplitude when the signal level of the pulse signal RxIn falls below the voltage level of the reference voltage Vref2. An output of the comparator 75 is connected to the other input terminal of the ExOR circuit 73.

Specifically, the pulse detection circuit 23 outputs a pulse signal corresponding to a change in signal level of the pulse signal RxIn when a positive or negative amplitude is generated in the pulse signal RxIn. At this time, the pulse detection signal PLDET output by the pulse detection circuit 23 is formed only of a pulse signal having a positive amplitude.

The second timing control circuit 22a has substantially the same configuration as the second timing control circuit 22 described with reference to FIG. 31, and the pulse detection signal PLDET is input to the set input terminal S of the set/reset latch circuit 306. As the second transmission circuit Tx2b, the circuit described with reference to FIG. 32 is used.

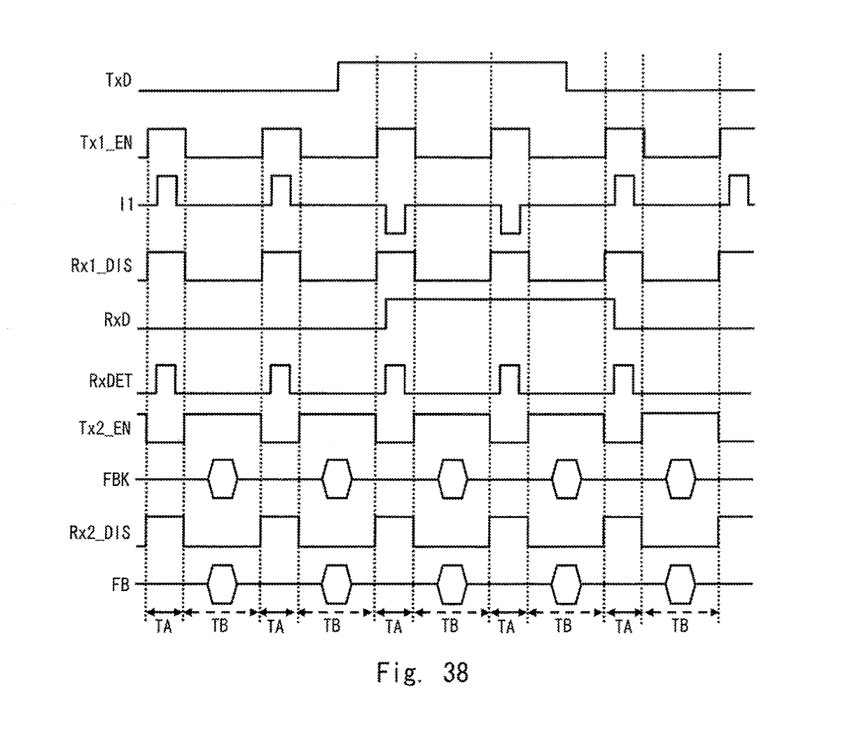

Subsequently, the overall operation of the communication system according to the third exemplary embodiment will be described. FIG. 38 shows a timing diagram illustrating the operation of the communication system according to the third exemplary embodiment. As shown in FIG. 38, in the communication system according to the third exemplary embodiment, the first transmission circuit generates the pulse detection signal PLDET (which switches from the low level to the high level) in response to the pulse signal during the transmission time period TA. During the interval time period TB, the second timing control circuit 22a operates based on the pulse detection signal PLDET and sets the first reception disenable signal Rx1_DIS and the second transmission enable signal Tx2_EN to the high level. That is, in the communication system according to the third exemplary embodiment., the second transmission circuit Tx2 comes into the valid state in response to the pulse signal RxIn.

As described above, the communication system according to the third exemplary embodiment includes the pulse detection circuit 23 that detects the pulse signal RxIn, which is input to the first reception circuit Rx1, and outputs the pulse detection signal PLDET. The second timing control circuit 22a shifts the first reception circuit Rx1 to the invalid state and shifts the second transmission circuit Tx2 to the valid state in response to the pulse detection signal PLDET. After that, the second timing control circuit 22a shifts the first reception circuit Rx1 to the valid state and shifts the second transmission circuit Tx2 to the invalid state. That is, in the communication system according to the third exemplary embodiment, the second transmission circuit Tx2 is shifted to the valid state in response to the pulse signal RxIn input to the first reception circuit Rx1 through the transformer.

Thus, in the communication system according to the third exemplary embodiment, there is no need to synchronize the timing for the first timing control circuit 10 to start the transmission time period TA with the timing for the second timing control circuit 22a to start the operation in the interval time period. In other words, in the communication system according to the third exemplary embodiment, the pulse detection circuit 23 recognizes the operation status of the first circuit CHP1 by use of the second circuit CHP2, which eliminates the need to adjust the timing for synchronizing the first timing control circuit 10 and the second timing control circuit 22a. Therefore, in the communication according to the third exemplary embodiment, highly accurate communication can be achieved as compared with the communication system according to the first exemplary embodiment.

Moreover, in the communication system according to the third exemplary embodiment, the second transmission circuit Tx1 can be shifted to the valid state in response to the pulse signal output by the first transmission circuit Tx1. Accordingly, also when the first transmission circuit Tx1 outputs pulse signals at irregular intervals, for example, the second transmission circuit Tx2 can output pulse signals to the first circuit CHP1 during the interval time period in which the first transmission circuit Tx1 is in the invalid state.

### Fourth Exemplary Embodiment

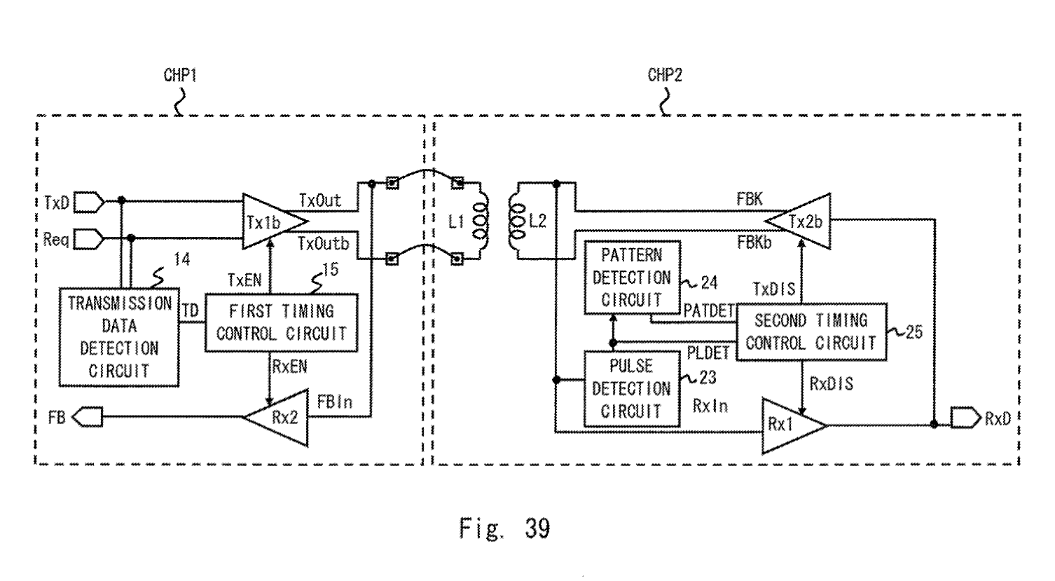

FIG. 39 shows a block diagram of a communication system according to a fourth exemplary embodiment. As shown in FIG. 39, the communication system according to the fourth exemplary embodiment differs from the communication system of the first exemplary embodiment in the configurations of the first circuit CHP1 and the second circuit CHP2. In the communication system according to the fourth exemplary embodiment, a transmission data detection circuit 14 is added to the first circuit CHP1. Further, in the communication system according to the fourth exemplary embodiment, a first timing control circuit 15 is used in place of the first timing control circuit 10, and a first transmission circuit Tx1b is used in place of the first transmission circuit Tx1. Furthermore, in the communication system according to the fourth exemplary embodiment, the pulse detection circuit 23 and a pattern detection circuit 24 are added to the second circuit CHP2. Moreover, in the communication system according to the fourth exemplary embodiment, a second timing control circuit 25 is used in place of the second timing control circuit 20, and the second transmission circuit Tx2b is used in place of the second transmission circuit Tx2. Hereinafter, the same elements as those of the first to third exemplary embodiment are denoted by the same reference numerals as those of the first to third exemplary embodiments, so the description thereof is omitted.

The first transmission circuit Tx1b used in the communication system according to the fourth exemplary embodiment receives the transmission data TxD as well as a response request signal Req. The first transmission circuit Tx1b outputs a pulse signal to the first coil L1 when one of the signal levels of the transmission data TxD and the response request signal Req changes. At this time, the first transmission circuit Tx1b outputs a pulse signal having a predetermined pattern in response to the response request signal Req. The second circuit CHP1 having receiving the pulse signal corresponding to the predetermined pattern shifts the second transmission circuit Tx2b to the valid state and outputs a pulse signal corresponding to the response data FB to the second coil L2. Hereinafter, a description will be made of each element of the communication system according to the fourth exemplary embodiments for achieving such an operation.

First, the transmission data detection circuit 14 will be described. FIG. 40 shows a block diagram of the transmission data detection circuit 14. As shown in FIG. 40, the transmission data detection circuit 14 includes delay circuits 63 and 65 and ExOR circuits 64, 66, and 67. The delay circuit 63, which receives the transmission data TxD at an input terminal, delays the transmission data TxD and outputs the transmission data to the ExOR circuit 64. One input terminal of the ExOR circuit 64 receives the transmission data TxD, and the other input terminal thereof receives the transmission data TxD having passed through the delay circuit 63. The ExOR circuit 64 outputs the result of an exclusive OR operation on the two signals received at the two input terminals. That is, the ExOR circuit 64 detects a change in logic level of the transmission data TxD, and outputs a pulse signal having a pulse width corresponding to the delay time set in the delay circuit 63.

The delay circuit 65, which receives the transmission data TxD at an input terminal, delays the transmission data TxD and outputs it to the ExOR circuit 66. One input terminal of the ExOR circuit 66 receives the transmission data TxD, and the other input terminal thereof receives the transmission data TxD having passed through the delay circuit 65. The ExOR circuit 66 outputs the result of an exclusive OR operation on the two signals received at the two input terminals. That is, the ExOR circuit 66 detects a change in logic level of the transmission data TxD, and outputs a pulse signal having a pulse width corresponding to the delay time set in the delay circuit 65.

One input terminal of the ExOR circuit 67 is connected to an output terminal of the ExOR circuit 64, and the other input terminal thereof is connected to an output terminal of the ExOR circuit 66. The ExOR circuit 67 outputs the result of an exclusive OR operation on the signals received at the two input terminals as a transmission data change detection signal TD. That is, the transmission data detection circuit 14 detects a change in each of the transmission data TxD and the response request signal Req, and outputs the transmission data change detection signal TD.

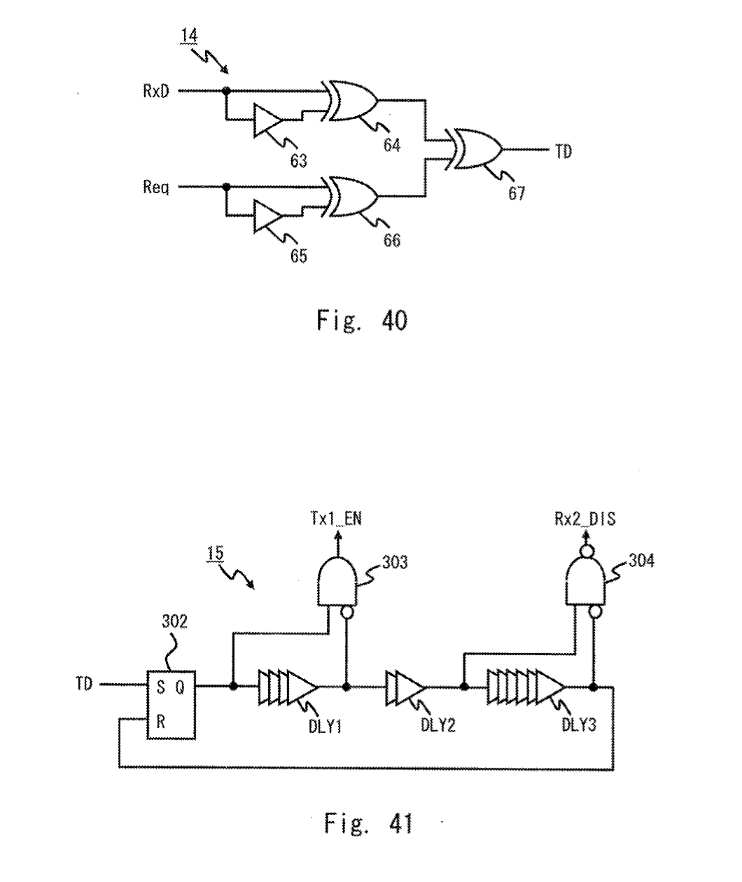

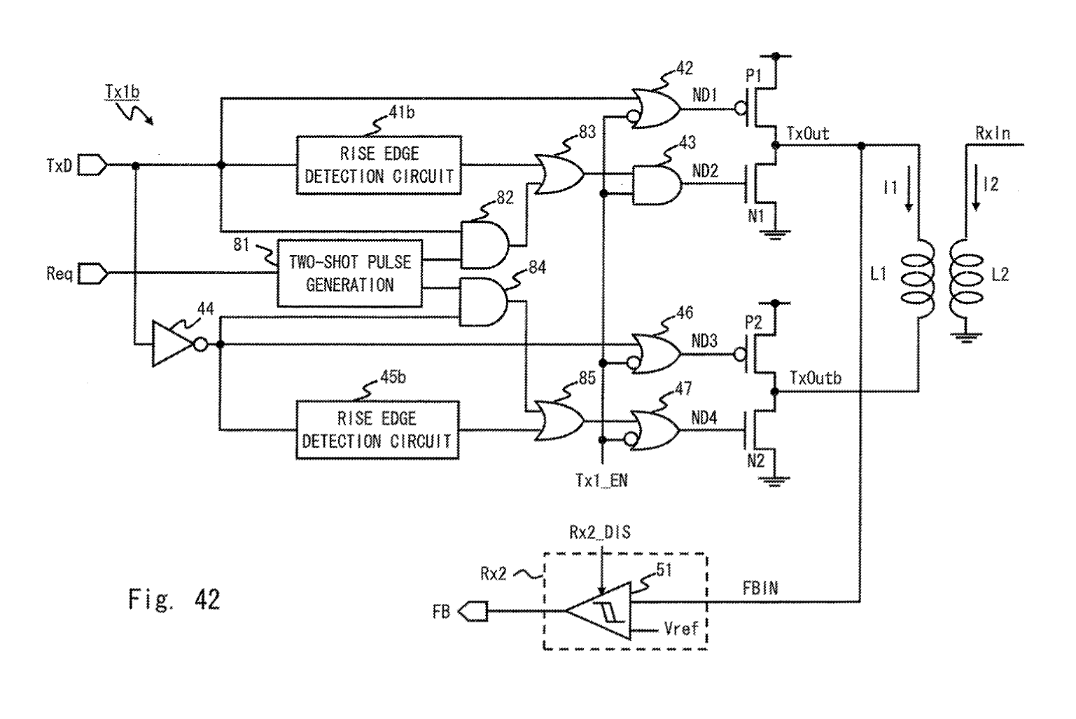

Subsequently, FIG. 41 shows a block diagram of the first timing control circuit 15. FIG. 41 shows a circuit having substantially the same configuration as the first trimming control circuit 10 described with reference to FIG. 14, and the transmission data change detection signal TD is input to the set input terminal S of the set/reset latch circuit 306.

Next, FIG. 42 shows a block diagram of the first transmission circuit Tx1b. As shown in FIG. 42, the first transmission circuit Tx1b is a modified example of the first transmission circuit Tx1 described with reference to FIG. 18. The first transmission circuit Tx1b has a configuration in which a two-shot pulse generation circuit 81, AND circuits 82 and 84, and an OR circuit 83 are added to the first transmission circuit Tx1. In the first transmission circuit Tx1b, rise edge detection circuits 41b and 45b are used in place of the one-shot pulse generation circuits 41 and 45 of the first transmission circuit Tx1.

When the response request signal Req becomes the first logic level (for example, high level), the two-shot pulse generation circuit 81 outputs a pulse signal having two successive pulses. The two-shot pulse generation circuit 81 outputs pulse signals to the AND circuits 82 and 84.

The rise edge detection circuit 41b outputs a pulse signal having one pulse in response to a rising edge when the transmission data TxD shifts from the low level to the high level. The rise edge detection circuit 45b outputs a pulse signal having one pulse in response to a rising edge when the transmission data TxD, which is inverted by the inverter 44, shifts from the low level to the high level.

One input terminal of the AND circuit 82 receives the transmission data TxD, and the other input terminal thereof receives the pulse signal output by the two-shot pulse generation circuit 81. The AND circuit 82 outputs the result of an AND operation on the two input signals to the OR circuit 83. One input terminal of the OR circuit 83 receives the pulse signal output by the rise edge detection circuit 41b, and the other input terminal thereof receives the output signal from the AND circuit 82. The OR circuit 83 outputs the result of an OR operation on the two input signals to the AND circuit 43. Specifically, the signal output by the OR circuit 83 corresponds to the pulse signal output by the rise edge detection circuit 41b when a rising edge of the transmission data TxD is received, and corresponds to the pulse signal output by the two-shot pulse generation circuit 81 when the response request signal Req is received during the time period in which the transmission data TxD is at the high level.

One input terminal of the AND circuit 84 receives the transmission data TxD, which is inverted by the inverter 44, and the other input terminal thereof receives the pulse signal output by the two-shot pulse generation circuit 81. The AND circuit 84 outputs the result of an AND operation on the two input signals to the OR circuit 85. One input terminal of the OR circuit 85 receives the pulse signal output by the rise edge detection circuit 45b, and the other input terminal thereof receives the output signal from the AND circuit 84. The OR circuit 85 outputs the result of an OR operation on the two input signals to the OR circuit 46 having an inverting input. Specifically, the signal output by the OR circuit 85 corresponds to the pulse signal output by the rise edge detection circuit 45b when a falling edge of the transmission data TxD is received, and corresponds to the pulse signal output by the two-shot pulse generation circuit 81 when the response request signal Req is received during the time period in which the transmission data TxD is at the low level.

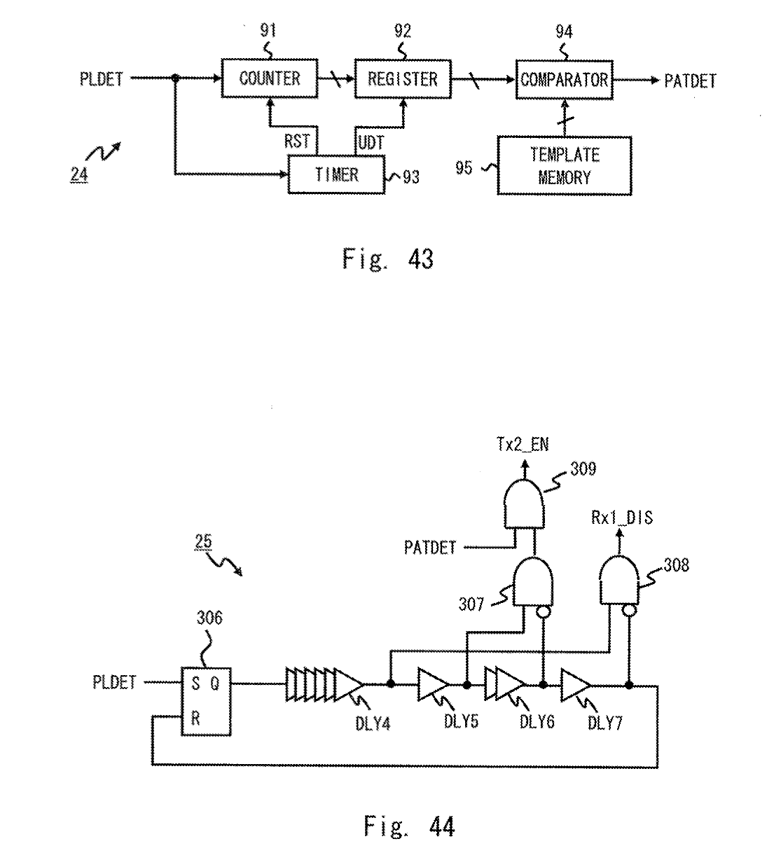

Subsequently, the elements provided on the second circuit CHP2 side will be described. First, the pattern detection circuit 24 will be described. The pattern detection circuit 24 analyzes the pattern of the pulse signal RxIn input to the first reception circuit Rx1, and detects matching between a predetermined pattern and the pattern of the pulse signal RxIn. More specifically, the pattern detection circuit 24 analyzes the pulse pattern based on the pulse detection signal PLDET output by the pulse detection circuit 23. Accordingly, the pattern detection circuit 24 can achieve a certain level of analysis regardless of the polarity of the amplitude of the pulse signal RxIn. FIG. 43 shows a block diagram of the pattern detection circuit 24. As shown in FIG. 43, the pattern detection circuit 24 includes a counter 91, a register 92, a timer 93, a comparator 94, and a template memory 95.

The counter 91 counts the number of pulses of the pulse signal received from the pulse detection signal PLDET, and outputs the count value to the register 92. The register 92 holds the count value and transmits it to the comparator at the subsequent stage. The timer 93 measures the length of a time period in which the pulses of the pulse detection signal PLDET are not input. When the measured time period exceeds a preset time period, the timer 93 outputs a reset signal RST and an update signal UDT. The reset signal RST is input to the counter 91, and the counter 91 resets the count value to an initial value in response to the reset signal RST. The update signal UDT is input to the register 92 to update the value held in the register 92. The update signal UDT and the reset signal RST reset the count value are used to reset the count value, which is held in the register 92, to the initial value. The comparator 94 compares the value corresponding to the pulse pattern held in the template memory 95 with the count value held in the register 92, and outputs a pattern detection signal PATDET when the two values match.

Subsequently, the second timing control circuit 25 will be described. The second timing control circuit 25 determines whether or not to shift the second transmission circuit Tx2 to the valid state according to the value of the pattern detection signal PATDET. Specifically, when the pulse signal output by the first transmission circuit Tx1 requires no response, the second timing control circuit 25 maintains the second transmission circuit Tx2 in the invalid state.

FIG. 44 shows a block diagram of the second timing control circuit 25. As shown in FIG. 44, the second timing control circuit 25 has a configuration in which an AND circuit 309 is added to the second timing control circuit 22 described reference to FIG. 31 and the pulse detection signal PLDET is input to the set input terminal S of the set/reset latch circuit 306. One input terminal of the AND circuit 309 receives the pattern detection signal PATDET, and the other input terminal thereof receives the output signal from the AND circuit 307 having an inverting input. The AND circuit 309 outputs the result of an AND operation on the values of the two input signals as the second transmission enable signal Tx1_EN. Specifically, the AND circuit 309 interrupts the output of the AND circuit 307 having an inverting input when the pattern detection signal PATDET is in a pattern undetected state (for example, low level), and maintains the second transmission enable signal Tx2_EN at the low level. Meanwhile, when the pattern detection signal PATDET is in a pattern detected state (for example, high level), the AND circuit 309 outputs the output signal of the AND circuit 307 having an inverting input and shifts the second transmission enable signal Tx2_EN to the high level or low level.

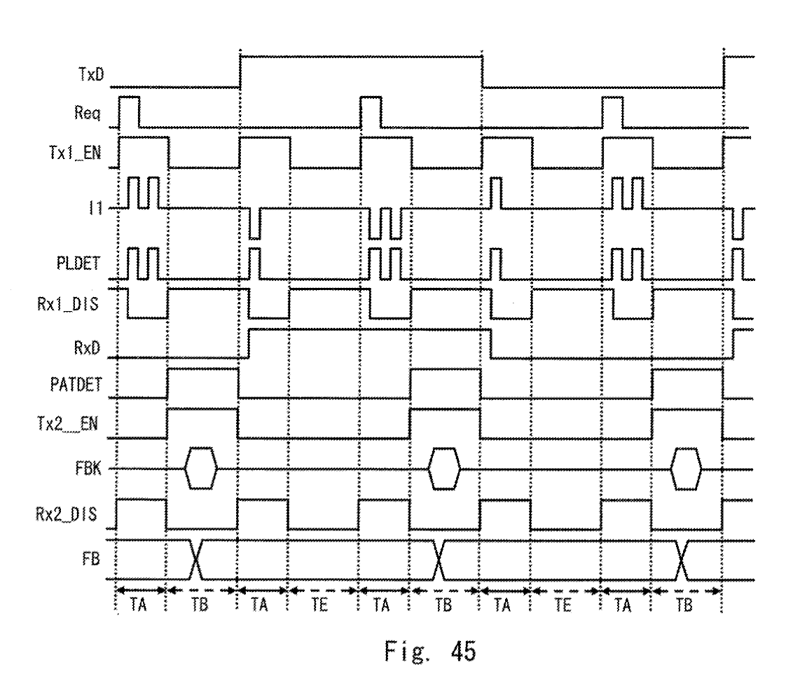

Subsequently, the overall operation of the communication system according to the fourth exemplary embodiment will be described. FIG. 45 shows a timing diagram illustrating the operation of the communication system according to the fourth exemplary embodiment. As shown in FIG. 45, in the communication system according to the fourth exemplary embodiment, the operation to be performed in the subsequent interval time period is determined depending on whether or not the first transmission circuit Tx1 performs the operation corresponding to the response request signal Req in the transmission time period TA. In FIG. 45, an interval time period immediately after the first transmission circuit Tx1 performs the operation corresponding to the response request signal Req in the transmission time period TA is represented by “TB”, and an interval time period immediately after the transmission time period TA in which the first transmission circuit Tx1 does not perform the operation corresponding to the response request signal Req is represented by “TE”.

In the transmission time period TA, data is transmitted from the first transmission circuit Tx1 to the first reception circuit Rx1 according to a change in the transmission data or a change in the response request signal Req. First, a description will be made of the case where the first transmission circuit Tx1 generates pulse signals based on the response request signal Req during the transmission time period TA. In this case, the first reception circuit Rx1 receives two successive pulse signals RxIn. The pulse signals RxIn are detected by the pulse detection circuit 23 and transmitted to the pattern detection circuit 24 as the pulse detection signal PLDET. The pattern detection signal 24 according to the third exemplary embodiment allows the pattern detection signal PATDET to shift to the high level in response to the two successive pulse signals. In the interval time period TB, the second timing control circuit 25 sets the first reception disenable signal Rx1_DIS and the second transmission enable signal Tx2_EN to the high level in response to the pulse detection signal PLDET and the pattern detection signal PATDET. As a result, the second transmission circuit Tx2 comes into the valid state, and the response data FB is transmitted from the second transmission circuit Tx2 to the second reception circuit Rx2.

Next, a description will be made of the case where in the transmission time period TA, the first transmission circuit Tx1 generates pulse signals based on the transmission data TxD. In this case, the first reception circuit Rx1 receives the pulse signal RxIn having one pulse. This pulse signal RxIn is detected by the pulse detection circuit 23 and is transmitted to the pattern detection circuit 24 as the pulse detection signal PLDET. However, the pattern detection signal 24 of the third exemplary embodiment allows the pattern signal PATDET to shift to the low level for pulse patterns other than two successive pulse signals. Accordingly, in the interval time period TE, the second timing control circuit 25 sets the first reception disenable signal Rx1_DIS to the high level and sets the second transmission enable signal Tx2_EN to the low level in response to the pulse detection signal PLDET and the pattern detection signal PATDET. Thus, in the interval time period TE, the second transmission circuit Tx2 comes into the invalid state, and the communication from the second transmission circuit Tx2 to the second reception circuit Rx2 is not performed.

As described above, in the communication system according to the fourth exemplary embodiment, the second circuit CHP2 includes the pattern detection circuit 24 that analyzes the pattern of the pulse signal RxIn input to the first reception circuit Rx1, detects matching between the predetermined pattern and the pattern of the pulse signal RxIn, and outputs the pattern detection signal. PATDET. The second timing control circuit 25 determines whether or not to shift the second transmission circuit Tx2b to the valid state according to the pattern detection signal PATDET. In other words, the second transmission circuit Tx2b shifts to the valid state according to the pattern of the pulse signal RxIn input through the transformer. Further, the first transmission circuit Tx1 outputs a pulse signal to the transformer in response to at least one of a change in logic level of the transmission data TxD and a change in the request response signal Req. Accordingly, in the communication system according to the fourth exemplary embodiment, the second circuit can obtain the response data from the second circuit CHP2 only when the first circuit CHP1 requires response data from the second circuit CHP2. In short, in the communication system according to the fourth exemplary embodiment, the degree of freedom of the timing for transmitting and receiving data in the system can be increased as compared with the first to third exemplary embodiments.

### Fifth Exemplary Embodiment

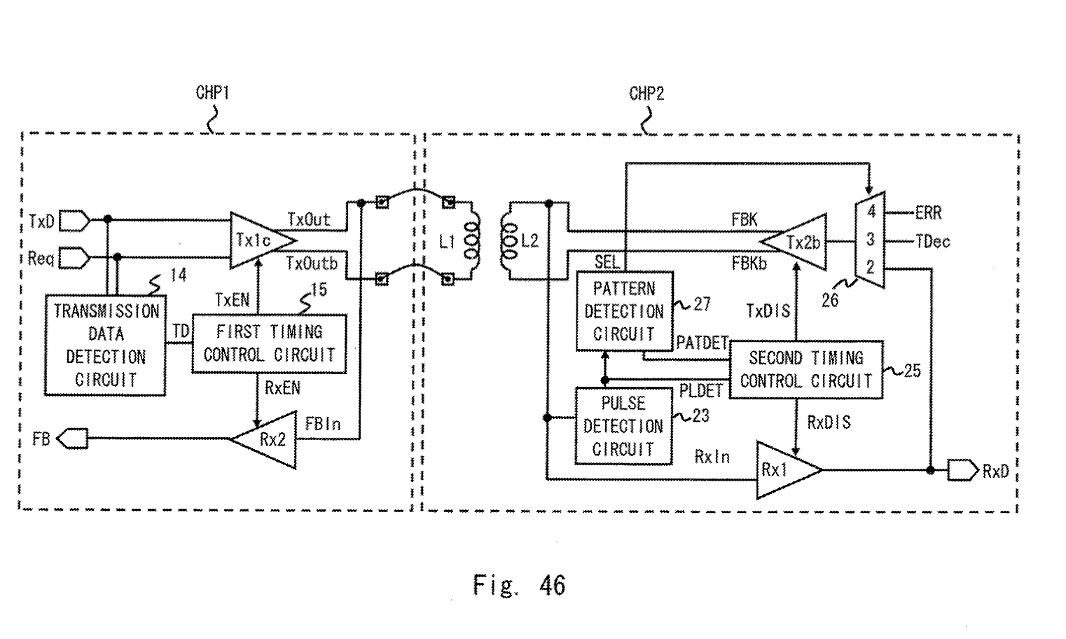

FIG. 46 shows a block diagram of a communication system according to a fifth exemplary embodiment. As shown in FIG. 46, the communication system according to the fifth exemplary embodiment has a configuration in which the functions of the communication system according to the fourth exemplary embodiment are expanded. In the communication system according to the fifth exemplary embodiment, the first transmission circuit Tx1 generates a pulse signal having a plurality of pulse patterns in response to the response request signal Req. The second circuit CHP2 selects one of a plurality of response data items according to the type of the pulse pattern, and transmits the response data FB to the first circuit CHP1.

As shown in FIG. 46, in the communication system according to the fifth exemplary embodiment, a second transmission circuit Tx1c is used in place of the first transmission circuit Tx1b of the communication system according to the fourth exemplary embodiment. Further, in the communication system according to the fifth exemplary embodiment, a selector 26 is added to the second circuit CHP2 of the communication system according to the fourth exemplary embodiment, and a pattern detection circuit 27 is used in place of the pattern detection circuit 24. Hereinafter, the same elements as those of the first to fourth exemplary embodiments are denoted by the same reference numerals as those of the first to fourth exemplary embodiments, so the description thereof is omitted.

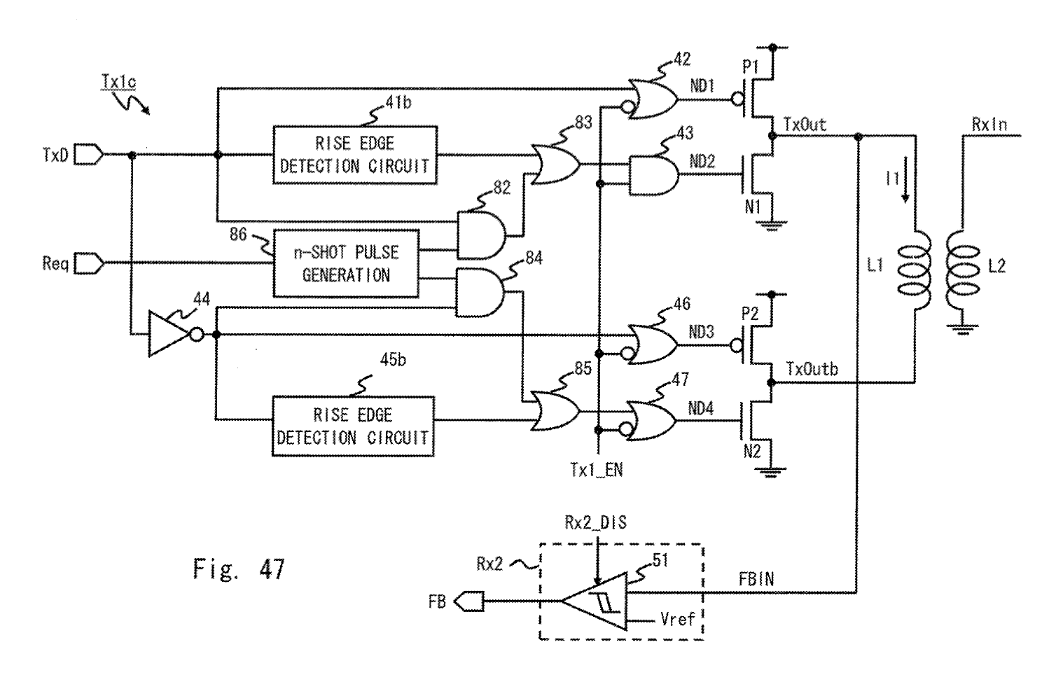

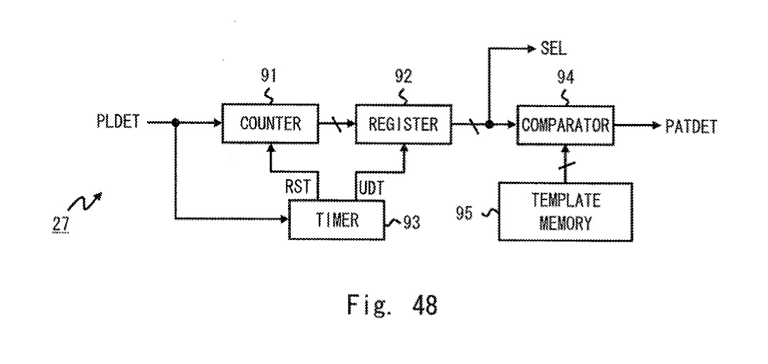

First, the first transmission circuit Tx1c will be described. FIG. 47 shows a block diagram of the first transmission circuit Tx1c. As shown in. FIG. 47, in the first transmission circuit Tx1c, an n-shot pulse generation circuit 86 is used in place of the one-shot pulse generation circuit 81 of the first transmission circuit Tx1b. The n-shot pulse generation circuit 86 generates a pulse signal having a number of successive pulses corresponding to the value represented by the response request signal Req. That is, although the first transmission circuit Tx1b is capable of generating only a pulse signal having a single pattern in response to the response request signal Req, the first transmission circuit Tx1c is capable of generating a pulse signal having a plurality of patterns.

Subsequently, the pattern detection circuit 27 will be described. FIG. 27 shows a block diagram of the pattern detection circuit 27. As shown in FIG. 27, the pattern detection circuit 27 obtains a selection signal SEL from the output of the register 92 of the pattern detection circuit 24.

The selector 26, which is added to the communication system according to the fifth exemplary embodiment, selects one of a plurality of response data candidates according to the value represented by the selection signal SEL and outputs the selected candidate to the second transmission circuit Tx2b.

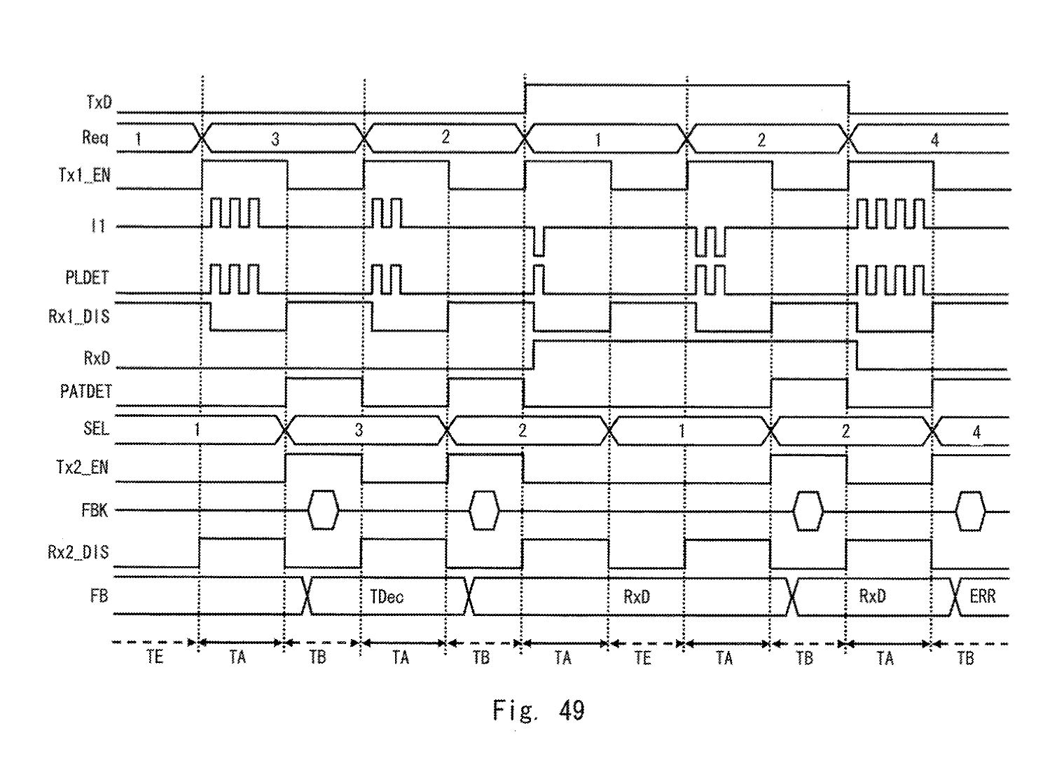

Next, the overall operation of the communication system according to the fifth exemplary embodiment will be described. FIG. 49 shows a timing diagram illustrating the operation of the communication system according to the fifth exemplary embodiment. As shown in FIG. 49, in the communication system according to the fifth exemplary embodiment, the response request signal Req represents one of the values 1 to 4. The first transmission circuit Tx1c outputs a pulse signal having a number of successive pulses corresponding to the value of the response request signal Req during the transmission time period TA. The pulse detection circuit 23 generates the pulse detection signal PLDET corresponding to the pulse signal output by the first transmission circuit Tx1c. The pulse detection signal PLDET is transmitted to the pattern detection circuit 27. The pattern detection circuit 27 outputs the selection signal SEL having a value corresponding to the number of successive pulses of the pulse detection signal PLDET. The selection signal SEL is supplied to the selector 26. The selector 26 selects response data according to the value of the selection signal SEL, and outputs the selected response data to the second transmission circuit Tx2b.

In the fifth exemplary embodiment, when the value of the selection signal SEL is “2”, the selector 26 selects the reception data RxD as the response data. When the value of the selection signal SEL is “3”, the selector 26 selects the temperature detection circuit TDec (described with reference to FIG. 12) as the response data. When the value of the selection signal SEL is “4”, the selector 26 selects the error signal ERR (described with reference to FIG. 12) as the response data. Further, when the selection signal SEL indicates “1”, the pattern detection circuit 27 sets the pattern detection signal PATDET to the low level, so that the second transmission circuit Tx2b comes into the invalid state. Accordingly, the second transmission circuit Tx2b transmits the response data selected by the selector 26 to the second reception circuit Rx2 during the interval time period TB.

As described above, in the communication system according to the fifth exemplary embodiment, the first transmission circuit Tx1c generates a pulse signal having a plurality of pulse patterns in response to the response request signal Req. Further, in the communication system according to the fifth exemplary embodiment, the second circuit CHP2 includes the pattern detection circuit that generates the selection signal SEL based on the pattern of the pulse signal RxIn input to the first reception circuit Rx1, and also generates the pattern detection signal PATDET representing a result of comparison between the predetermined pattern and the pattern of the pulse signal RxIn; and the selection circuit that selects one of a plurality of response data items according to the selection signal SEL and outputs the selected response data to the second transmission circuit Tx2b. The second timing control circuit 25 determines whether or not to shift the second transmission circuit Tx2b to the valid state according to the pattern detection signal PATDET. That is, the second transmission circuit Tx2 is capable of transmitting the response data selected according to the pulse pattern to the first circuit CHP1.

This allows the communication system according to the fifth exemplary embodiment to determine the response data necessary for the first circuit CHP1 and to obtain the necessary response data from the second circuit CHP2 based on this determination. In other words, in the communication system according to the fifth exemplary embodiment, the number of types of response data to be handled can be increased as compared with the communication system according to the fourth exemplary embodiment. Moreover, in the communication system according to the fifth exemplary embodiment, the flexibility of the system to be installed can be increased.

### Sixth Exemplary Embodiment

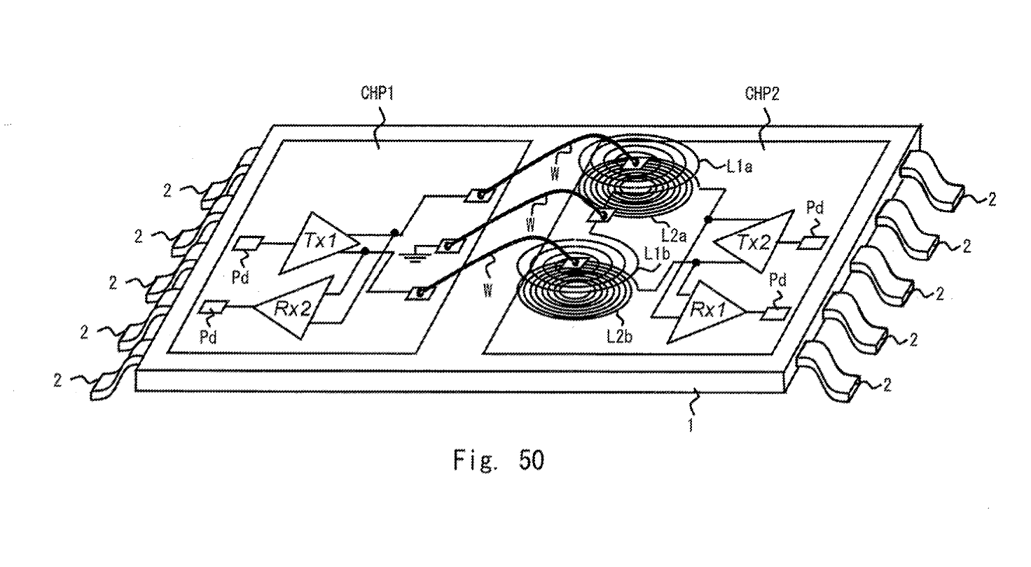

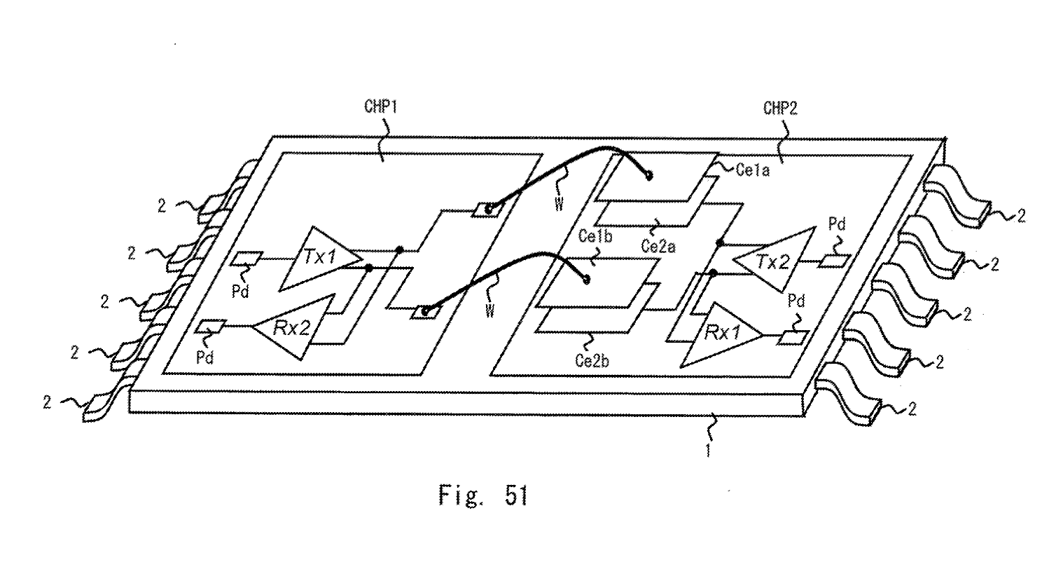

A communication system according to a sixth exemplary embodiment can perform communication using a differential signal through two transformers. FIGS. 50 and 51 each show a schematic view of a mounted state of the communication system according to the sixth exemplary embodiment.

In the example shown in FIG. 50, first coils L1a and L1b and second coils L2a and L2b are provided on the side of the second circuit CHP2. In the sixth exemplary embodiment, two pairs of first and second coils are provided to perform communication using a differential signal. The first coils L1a and L1b provided on the second circuit CHP2 side are connected to the first transmission circuit Tx1 and the second reception circuit Rx2, which are provided on the first circuit CHP1, via the bonding wires W. The second coils L2a and L2b are connected to the first reception circuit Rx1 and the second transmission circuit Tx2 via lines formed on the second circuit CHP2.

In the example shown in FIG. 51, the transformers shown in FIG. 50 are replaced with capacitors. These capacitors have the same configuration as that described with reference to FIG. 11. In the sixth exemplary embodiment, however, the capacitors are composed of four electrodes (Ce1a, Ce1b, Ce2a, and Ce2b as shown in FIG. 51) to perform communication using a differential signal. At this time, a first capacitor is composed of the electrodes Ce1a and Ce2a, and a second capacitor is composed of the electrodes Ce1b and Ce2b. The electrodes Ce1a and Ce1b are connected to the first transmission circuit Tx1 and the second reception circuit Rx2 through the bonding wires. The electrodes Ce2a and Ce2b are connected to the first reception circuit Rx1 and the second transmission circuit Tx2 through the lines formed on the second circuit CHP2.

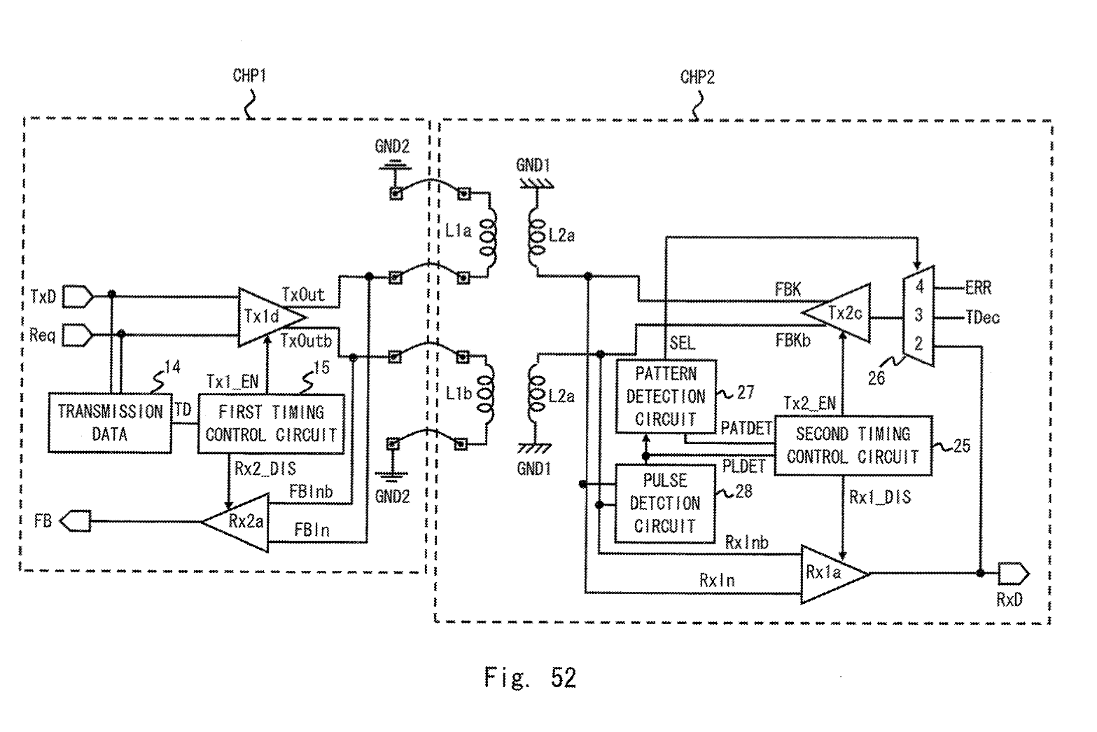

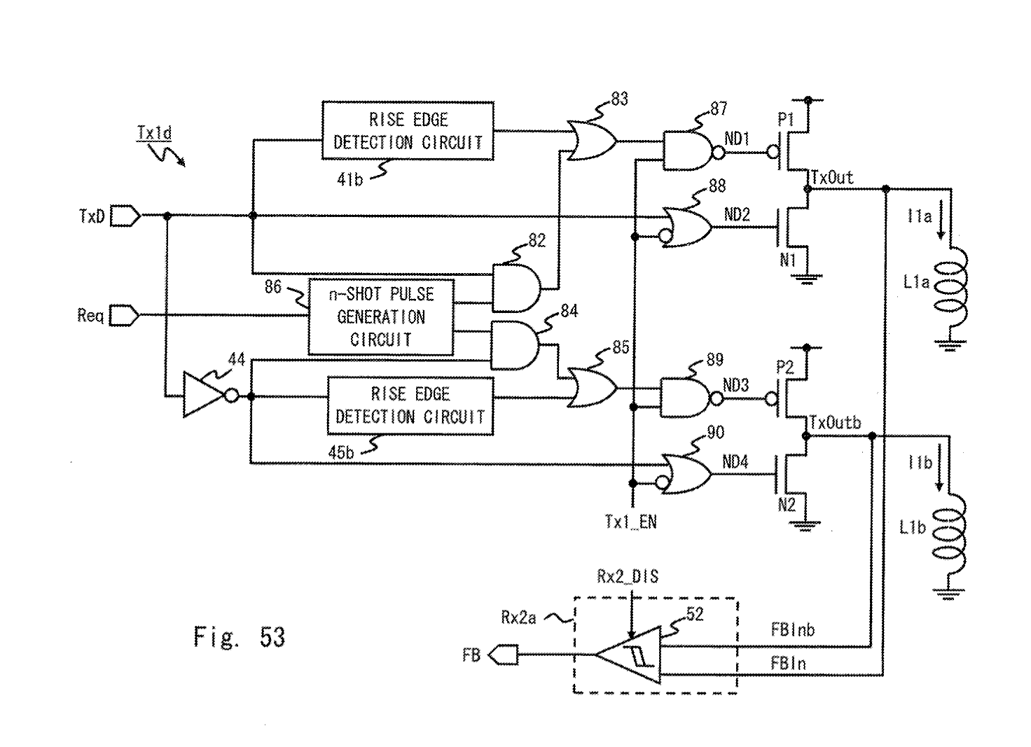

Subsequently, FIG. 52 shows a block diagram of the communication system according to the sixth exemplary embodiment. As shown in FIG. 52, the communication system according to the sixth exemplary embodiment enables communication using a differential signal in the communication system according to the fifth exemplary embodiment. In other words, the communication system according to the sixth exemplary embodiment has a configuration in which one transformer of the communication system according to the fifth exemplary embodiment is replaced with two transformers.

Further, in the communication system according to the sixth exemplary embodiment, a first transmission circuit Tx1d, a second transmission circuit Tx2c, a first reception circuit Rx1a, and a second reception circuit Rx2a are used to implement communication using a differential signal. Additionally, a pulse detection circuit 28 that is compatible with differential signals is used as the pulse detection circuit.

First, FIG. 53 shows a block diagram of each of the first transmission circuit Tx1d and the second reception circuit Rx2a. As shown in FIG. 53, the first transmission circuit Tx1d has a configuration in which NAND circuits 87 and 89 and OR circuits 88 and 90 each having an inverting input are used in place of the OR circuits 42, 46, and 47 each having an inverting input and the AND circuit 43 of the first transmission circuit Tx1c shown in FIG. 47.

One input terminal of the NAND circuit 87 receives an output signal from the OR circuit 83, and the other input terminal thereof receives the first transmission enable signal Tx1_EN. The NAND circuit 87 outputs the inverted value of the result of an AND operation on the two input signals to the gate of the PMOS transistor P1.

A normal input terminal of the OR circuit 88 having an inverting input receives the transmission data TxD, and an inverting input terminal thereof receives the first transmission enable signal Tx1_EN. The OR circuit 88 having an inverting input outputs the result of an OR operation on the logical value of the transmission data TxD and the inverted logical value of the first transmission enable signal Tx1_EN to the gate of the NMOS transistor N1.

One input terminal of the NAND circuit 89 receives an output signal from the OR circuit 85, and the other input terminal thereof receives the first transmission enable signal Tx1_EN. The NAND circuit 89 outputs the inverted value of the result of an AND operation on the two received signals to the gate of the PMOS transistor P2.

A normal input terminal of the OR circuit 90 having an inverting input receives the transmission data TxD inverted by the inverter 44, and an inverting input terminal thereof receives the first transmission enable signal Tx1_EN. The OR circuit 88 having an inverting input outputs the result of an OR operation on the inverted logical value of the transmission data TxD and the inverted logical value of the first transmission enable signal Tx1_EN to the gate of the NMOS transistor N2.

Specifically, when the first transmission enable signal Tx1_EN is at the high level (representing the valid state of the first transmission circuit Tx1d) and when the transmission data TxD is at the high level, the first transmission circuit Tx1d sets the output terminal TxOut to the low level and outputs a pulse signal to the output terminal TxOutb. When the first transmission enable signal Tx1_EN is at the high level and when the transmission data TxD is at the low level, the first transmission circuit Tx1d outputs a pulse signal to the output terminal TxOut and sets the output terminal TxOutb to the low level. When the first transmission enable signal Tx1_EN is at the low level (representing the invalid state of the first transmission circuit Tx1d), the first transmission circuit Tx1d sets the output terminals TxOut and TxOutb to the high impedance state.

As shown in FIG. 53, the second reception circuit Rx2a includes a differential input hysteresis comparator 52. The hysteresis comparator 52 inverts the value of the response data FB to be output depending on a potential difference between pulse signals FBIn and FBInb.

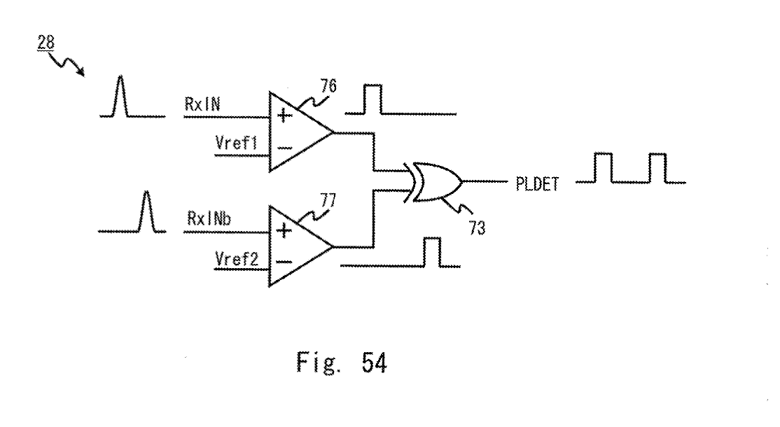

Subsequently, FIG. 54 shows a block diagram of the pulse detection circuit 28. The pulse detection circuit 28 includes comparators 76 and 77 and an ExOR circuit 73. A non-inverting input terminal of the comparator 76 receives the pulse signal RxIn, and an inverting input terminal thereof receives the reference voltage Vref1. The comparator 76 outputs a pulse signal having a pulse width corresponding to a time period in which the signal level of the pulse signal RxIn exceeds the value of the reference voltage Vref1. A non-inverting input terminal of the comparator 77 receives the pulse signal RxIn, and an inverting input terminal thereof receives the reference voltage Vref2. The comparator 77 outputs a pulse signal having a pulse width corresponding to a time period in which the signal level of the pulse signal RxIn exceeds the value of the reference voltage Vref2. The ExOR circuit 73 outputs the result of an exclusive OR operation on the output signals from the comparators 76 and 77 as the pulse detection signal PLDET. That is, the pulse detection circuit 28 performs an operation equivalent to that of the pulse detection circuit 23 on the differential signal.

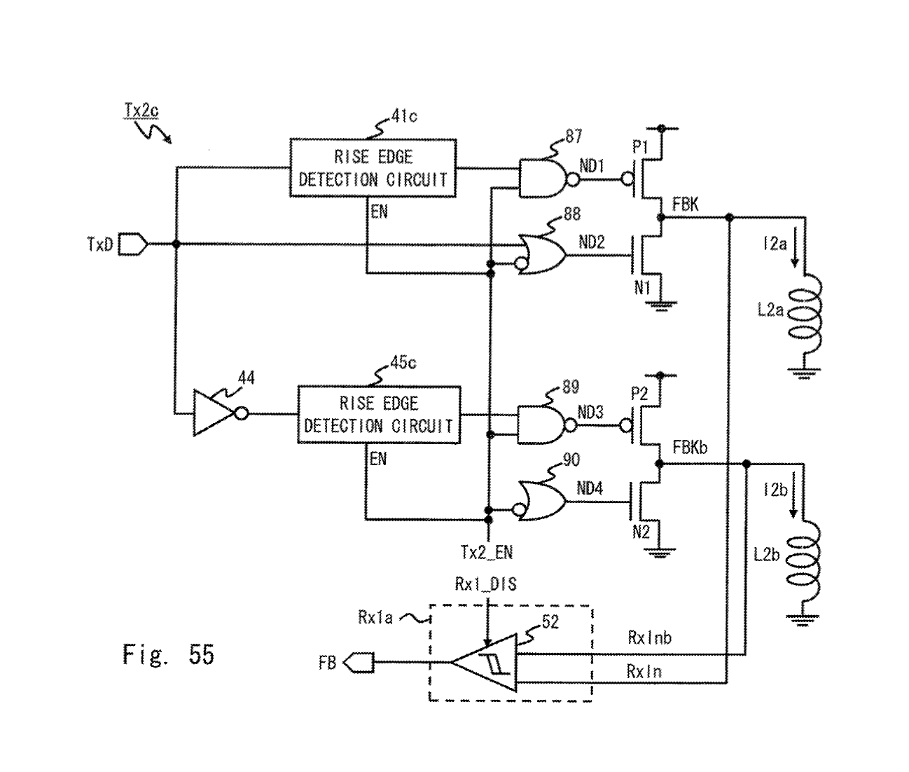

Subsequently, FIG. 55 shows a block diagram of the second transmission circuit Tx2c. As shown in FIG. 55, the second transmission circuit Tx2c has a configuration in which the AND circuits 82 and 84, the OR circuits 83 and 85, and the n-shot pulse generation circuit 86 are omitted from the first transmission circuit Tx1d, and rise edge detection circuits 41c and 45c are used in place of the rise edge detection circuits 41b and 45b.

When the second transmission enable signal Tx1_EN is at the high level (representing the valid state of the second transmission circuit Tx2c), the rise edge detection circuit 41c outputs a pulse signal upon receiving a rising edge of the transmission data TxD. The pulse signal output by the rise edge detection circuit 41c is supplied to one input terminal of the NAND circuit 87.

When the second transmission enable signal Tx1_EN is at the high level (representing the valid state of the second transmission circuit Tx2c), the rise edge detection circuit 45c outputs a pulse signal upon receiving a rising edge of the transmission data TxD inverted by the inverter 44. The pulse signal output by the rise edge detection circuit 45c is supplied to one input terminal of the NAND circuit 89.

In short, the second transmission circuit Tx2c in the valid state outputs a pulse signal corresponding to a rising edge or a falling edge of the transmission data (data corresponding to the response data in the case of the second transmission circuit Tx2c). At this time, the pulse signal is output from an output terminal FBKb when the response data is at the high level, and the pulse signal is output from the output terminal FBK when the response data is at the low level. Further, a low level signal is output from the output terminal from which the pulse signal is not output. The second transmission circuit Tx2c in the invalid state sets each of the output terminals FBK and FBKb to the high impedance state.

As shown in FIG. 55, in the first reception circuit Rx1a, the hysteresis comparator 52 having the same configuration as that of the second reception circuit Rx2a is used.

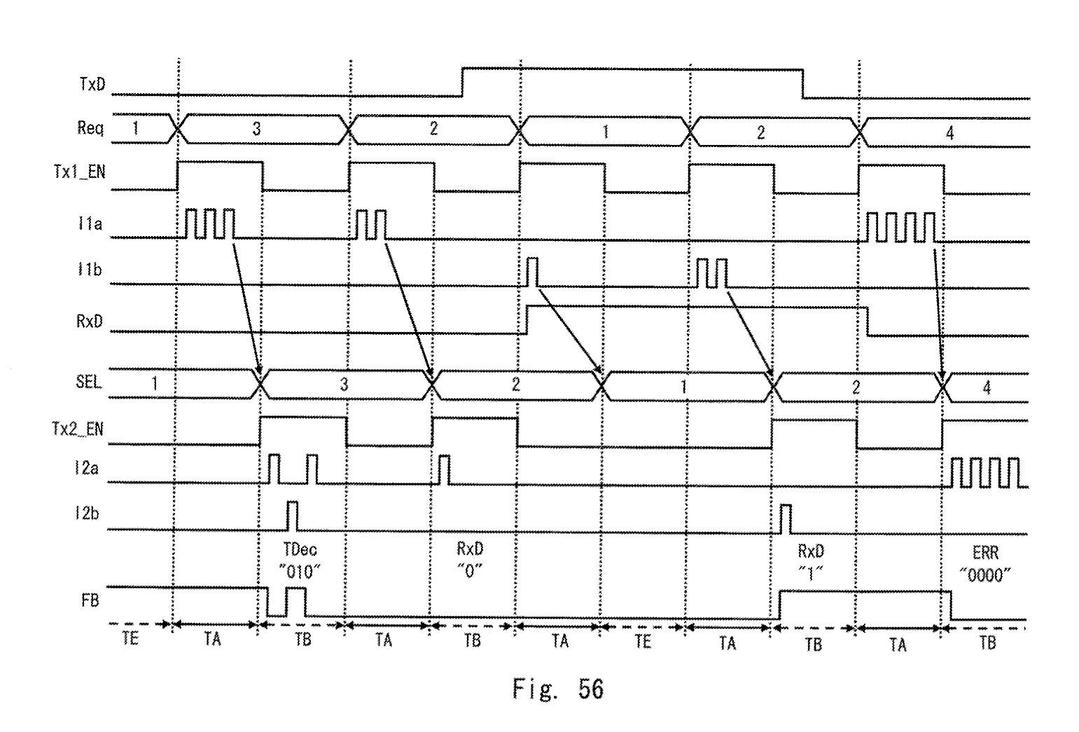

Subsequently, the operation of the communication system according to the sixth exemplary embodiment will be described. FIG. 56 shows a timing diagram illustrating the operation of the communication system according to the sixth exemplary embodiment. As shown in FIG. 56, the basic operation of the communication system according to the sixth exemplary embodiment is the same as that of the communication system according to the fifth exemplary embodiment, except that the communication system according to the sixth exemplary embodiment transmits and receives data using a differential signal.

In this way, the communication using a differential signal enables stable communication even in the case where noise is superimposed on the communication data due to external noise. This is because when a differential signal is used for communication, noise such as external noise is evenly superimposed on two signals constituting the differential signal, so that the superimposed noise component can be cancelled by various signal processings based on a difference in signal level between the two signals of the differential signal. In summary, the communication system according to the sixth exemplary embodiment can enhance the reliability in communication as compared with the other exemplary embodiments.

Note that the present invention is not limited to the above exemplary embodiments, but can be modified as appropriate without departing from the scope of the present invention. The present invention can be modified in configuration and details in various manners which can be understood by those skilled in the art within the scope of the present invention.

This application is based upon and claims the benefit of priority from Japanese patent application No. 2009-076089, filed on Mar. 26, 2009, the disclosure of which is incorporated herein in its entirety by reference.

### INDUSTRIAL APPLICABILITY

The present invention is applicable to a system in which signals are transmitted and received between a circuit that operates in a first power supply system and a circuit that operates in a second power supply system to which a power supply voltage different from that of the first power supply system is set.

### REFERENCE SIGNS LIST

CHP1 FIRST CIRCUIT
CHP2 SECOND CIRCUIT
CHP3 THIRD CIRCUIT
CHP4 SEMICONDUCTOR SUBSTRATE (FOURTH CIRCUIT)

### Cd CAPACITOR

Cu CAPACITOR
Ce1, Ce1a, Ce1b ELECTRODE
Ce1, Ce2a, Ce2b ELECTRODE
DLY1-DLY7 DELAY CIRCUIT
Drv GATE DRIVER
FBK, FBKb OUTPUT TERMINAL
L1, L1a, L1b COIL
L2, L2a, L2b COIL
MCU CONTROL CIRCUIT
N1-N6 NMOS TRANSISTOR
P1, P2 TRANSISTOR
Pd PAD
R1d, R1u, R2d, R2u RESISTOR
RL1, RL2 LOAD RESISTOR
Rb BIAS RESISTOR
Rshunt CURRENT DETECTION RESISTOR
Rx1, Rx1a, Rx2, Rx2a RECEPTION CIRCUIT
SW SWITCH
Tx1-Tx1d, Tx2-Tx2c TRANSMISSION CIRCUIT
TxOut, TxOutb OUTPUT TERMINAL
W BONDING WIRE
1, 100 SEMICONDUCTOR PACKAGE
2 LEAD TERMINAL
10, 15, 20, 22, 22a, 25 TIMING CONTROL CIRCUIT
11 ERROR DETECTION CIRCUIT
13 TIMER
14 TRANSMISSION DATA DETECTION CIRCUIT
21 Change Detection Circuit
23, 28 PULSE DETECTION CIRCUIT
24, 27 PATTERN DETECTION CIRCUIT
25 TIMING CONTROL CIRCUIT
26 SELECTOR
28 PULSE DETECTION CIRCUIT
41, 45 ONE-SHOT PULSE GENERATION CIRCUIT
41a OSCILLATOR
41a OSCILLATOR
41a OSCILLATOR
41b, 41c, 45b, 45c EDGE DETECTION CIRCUIT
51 HYSTERESIS COMPARATOR
61, 63, 65 DELAY CIRCUIT
71 BUFFER CIRCUIT
72 INVERTER
74-77 COMPARATOR
81 TWO-SHOT PULSE GENERATION CIRCUIT
86 n-SHOT PULSE GENERATION CIRCUIT
91 COUNTER
92 REGISTER
93 TIMER
94 COMPARATOR
95 TEMPLATE MEMORY
110 FIRST CHIP (FIRST CIRCUIT)
121-126 SECOND CHIP (SECOND CIRCUIT)
110 CHIP
200 MOTOR
201 MOTOR DRIVE CIRCUIT
202 CURRENT DETECTION CIRCUIT
203 TEMPERATURE SENSOR
301, 305 PERIODIC PULSE GENERATION CIRCUIT
302, 306 SET/RESET LATCH CIRCUIT

1. A communication control method for a communication system comprising: a first circuit including a first transmission circuit and a second reception circuit; and a second circuit including a second transmission circuit and a first reception circuit, the communication system using an AC coupling element commonly used for transmitting and receiving signals between the first and second circuits, the communication control method comprising:
setting the first transmission circuit to a valid state and setting the second reception circuit to an invalid state;
setting the second transmission circuit to the invalid state and setting the first reception circuit to the valid state;
transmitting a signal from the first transmission circuit to the first reception circuit through the AC coupling element;
setting the first transmission circuit to the invalid state and setting the second reception circuit to the valid state during an interval time period after the transmission of the signal by the first transmission circuit;
setting the second transmission circuit to the valid state and setting the first reception circuit to the invalid state during the interval time period; and
transmitting a signal from the second transmission circuit to the second reception circuit through the AC coupling element during the interval time period.

2. The communication control method according to claim 1, wherein the valid state of the first transmission circuit and the valid state of the second reception circuit are exclusively switched, and the valid state of the second transmission circuit and the valid state of the first reception circuit are exclusively switched.

3. The communication control method according to claim 1, wherein switching between the valid state and the invalid state of the first transmission circuit and the second reception circuit and switching between the valid state and the invalid state of the second transmission circuit and the first reception circuit are performed in a predetermined cycle.

4. The communication control method according to claim 1, wherein
the second reception circuit is switched to the valid state upon switching of the first transmission circuit to the invalid state, and
the second transmission circuit is switched to the valid state upon switching of the first reception circuit to the invalid state.

5. The communication control method according to claim 1, wherein the first transmission circuit and the second transmission circuit are controlled not to be simultaneously switched to the valid state.

6. The communication control method according to claim 1, wherein the first transmission circuit in the invalid state sets an output terminal corresponding to a node connecting the AC coupling element and the second reception circuit to a high impedance state, and the second transmission circuit in the invalid state sets an output terminal corresponding to a node connecting the AC coupling element and the first reception circuit to the high impedance state.

7. The communication control method according to claim 1, wherein the first transmission circuit outputs a pulse signal to the AC coupling element at a predetermined interval.

8. The communication control method according to claim 1, wherein the first transmission circuit outputs a pulse signal to the AC coupling element according to a change in a logic level of transmission data.

9. The communication control method according to claim 8, wherein the first transmission circuit outputs successive pulse signals to the AC coupling element in response to a response request signal.

10. The communication control method according to claim 9, wherein the number of pulses of the successive pulse signals is determined depending on a value of the response request signal.

11. The communication control method according to claim 1, wherein each of the first reception circuit and the second reception circuit in the invalid state maintains a logic level of output data output during a time period of the valid state immediately before shifting to the invalid state.

12. The communication control method according to claim 1, wherein the second transmission circuit shifts to the valid state according to a change in a logic level of reception data output by the first reception circuit.

13. The communication control method according to claim 1, wherein the second transmission circuit shifts to the valid state in response to a pulse signal input through the AC coupling element.

14. The communication control method according to claim 1, wherein the second transmission circuit shifts to the valid state according to a pattern of a pulse signal input through the AC coupling element.

15. The communication control method according to claim 1, wherein the second transmission circuit selects one of a plurality of response data candidates according to a pattern of the pulse signal, and outputs a pulse signal corresponding to the response data selected.

16. The communication control method according to claim 1, wherein a transmission error signal is generated when a time period in which response data output by the second reception circuit does not match transmission data input to the first transmission circuit is equal to or longer than a preset determination time period.

17. The communication control method according to claim 16, wherein the first transmission circuit outputs a pulse signal corresponding to the transmission data again to the AC coupling element in response to the transmission error signal.

18. A communication system comprising:
a first circuit including:
an AC coupling element commonly used for transmitting and receiving signals;
a first transmission circuit that outputs a pulse signal corresponding to transmission data to the AC coupling element;
a second reception circuit that reproduces response data in response to the pulse signal obtained from the AC coupling element; and
a first timing control circuit that switches a valid state and an invalid state of each of the first transmission circuit and the second reception circuit; and
second circuit including:
a first reception circuit that reproduces reception data in response to the pulse signal obtained from the AC coupling element;
a second transmission circuit that outputs a pulse signal corresponding to the response data to the AC coupling element; and
a second timing control circuit that switches the valid state and the invalid state of each of the first reception circuit and the second transmission circuit,
wherein the second timing control circuit sets the second transmission circuit to the valid state during an interval time period in which the first transmission circuit is in the invalid state.

19. The communication system according to claim 18, wherein the first timing control circuit exclusively switches the valid state of the first transmission circuit and the valid state of the second reception circuit.

20. The communication system according to claim 18, wherein the first transmission circuit outputs successive pulse signals to the AC coupling element in response to a response request signal.

21. The communication system according to claim 20, wherein the first transmission circuit determines the number of successive pulse signals to be output according to a value of the response request signal.

22. The communication system according to claim 18, wherein the first timing control circuit switches the valid state of the first transmission circuit and the valid state of the second reception circuit at a predetermined interval.

23. The communication system according to claim 18, wherein the first timing control circuit sets the first transmission circuit to the valid state during a predetermined time period according to at least one of a change in a logic level of transmission data input to the first transmission circuit and a change in a value of a response request signal, and sets the second reception circuit to the valid state after shifting the first transmission circuit to the invalid state.

24. The communication system according to claim 18, wherein the second reception circuit in the invalid state maintains a logic level of output data output during a time period of the valid state immediately before shifting to the invalid state.

25. The communication system according to claim 18, wherein the first circuit includes an error detection circuit that detects a transmission error of the transmission data based on transmission data input to the first transmission circuit and on response data output by the second reception circuit, and outputs a transmission error signal.

26. The communication system according to claim 25, wherein the first transmission circuit resends the transmission data in response to the transmission error signal.

27. The communication system according to claim 18, wherein the first transmission circuit in the invalid state sets, to a high impedance state, an output terminal corresponding to a node connecting the AC coupling element and the second reception circuit.

28. The communication system according to claim 27, wherein the first transmission circuit in the invalid state supplies a ground potential to a terminal of the AC coupling element, the terminal being not connected to the second reception circuit.

29. The communication system according to claim 18, wherein the second timing control circuit exclusively switches the valid state of the first transmission circuit and the valid state of the second reception circuit.

30. The communication system according to claim 18, wherein the second timing control circuit switches the valid state of the first transmission circuit and the valid state of the second reception circuit at a predetermined interval.

31. The communication system according to claim 18, wherein
the second circuit includes a change detection circuit that detects switching of a logic level of the reception data output by the first reception circuit, and outputs a change detection signal, and
the second timing control circuit shifts the first reception circuit to the invalid state and shifts the second transmission circuit to the valid state in response to the change detection signal, and subsequently shifts the first reception circuit to the valid state and shifts the second transmission circuit to the invalid state.

32. The communication system according to claim 18, wherein
the second circuit includes a pulse detection circuit that detects a pulse signal is input to the first reception circuit, and outputs a pulse detection signal, and
the second timing control circuit shifts the first reception circuit to the invalid state and shifts the second transmission circuit to the valid state in response to the pulse detection signal, and subsequently shifts the first reception circuit to the valid state and shifts the second transmission circuit to the invalid state.

33. The communication system according to claim 32, wherein
the second circuit includes a pattern detection circuit that analyzes a pattern of a pulse signal input to the first reception circuit, detects matching between a predetermined pattern and the pattern of the pulse signal, and outputs a pattern detection signal, and
the second timing control circuit determines whether or not to shift the second transmission circuit to the valid state according to the pattern detection signal.

34. The communication system according to claim 32 wherein
the second circuit includes:
a pattern detection circuit that generates a selection signal based on a pattern of the pulse signal input to the first reception circuit, and a pattern detection signal representing a result of comparison between a predetermined pattern and the pattern of the pulse signal; and
a selection circuit that selects one of a plurality of response data items according to the selection signal, and outputs the response data selected to the second transmission circuit, and
the second timing control circuit determines whether or not to shift the second transmission circuit to the valid state according to the pattern detection signal.

35. The communication system according to claim 18, wherein the second transmission circuit in the invalid state sets, to a high impedance state, an output terminal corresponding to a node connecting the AC coupling element and the first reception circuit.

36. The communication system according to claim 35, wherein the first transmission circuit in the invalid state supplies a ground potential to a terminal of the AC coupling element, the terminal being not connected to the first reception circuit.
